(19) United States
(12) Patent Application Publication
(10) Pub. No.: US 2013/0285035 A1
(43) Pub. Date: Oct. 31, 2013

(54) ORGANIC ELECTROLUMINESCENT ELEMENT, LIGHTING DEVICE, AND DISPLAY DEVICE

(71) Applicants: Hideo Taka, Inagi-shi (JP); Rie Katakura, Hino-shi (JP); Hidekane Ozeki, Hachioji-shi (JP); Maiko Kondo, Hino-shi (JP)

(72) Inventors: Hideo Taka, Inagi-shi (JP); Rie Katakura, Hino-shi (JP); Hidekane Ozeki, Hachioji-shi (JP); Maiko Kondo, Hino-shi (JP)

(73) Assignee: Konica Minolta, Inc., Tokyo (JP)

(21) Appl. No.: 13/979,086

(22) PCT Filed: Jan. 10, 2012
(86) PCT No.: PCT/JP2012/050216

§ 371 Date: Jul. 10, 2013

(30) Foreign Application Priority Data
Jan. 12, 2011 (JP) 2011-003766

(51) Int. Cl. H01L 51/00

(52) U.S. Cl. CPC H01L 51/0084
USPC 257/40

(57) ABSTRACT

Provided is an organic electroluminescent element that maintains higher hole injection characteristics than conventional organic EL elements. This organic electroluminescent element has an organic compound layer sandwiched between a positive electrode and negative electrode. The organic compound layer contains at least a light emitting layer and charge generating layer and is characterized by (1) having a charge generating layer formed from at least one layer between the positive electrode and the light emitting layer and (2) containing an organic metal complex in at least one of the charge generating layer.

### CROSS REFERENCE TO RELATED APPLICATIONS

This is the U.S. national stage of application No. PCT/JP2012/050216, filed on 10 Jan. 2012. Priority under 35 U.S.C. §119(a) and 35 U.S.C. §365(b) is claimed from Japanese Application No. 2011-003766, filed 12 Jan. 2011, the disclosure of which is also incorporated herein by reference.

### TECHNICAL FIELD

The present invention relates to an organic electroluminescent element a lighting device and a display device.

### BACKGROUND ART

An organic electroluminescent element (hereinafter also referred to as an organic EL element) is an all solid-state element composed of electrodes and an organic material film having a thickness of only about 0.1 μm between the electrodes and can emit light at a relatively low voltage of about 2 to 20 V. The organic EL element is therefore a promising technology as a next-generation flat display or lighting device.

Organic EL elements utilizing phosphorescence emission have been found, and such organic EL elements can achieve efficiencies of light emission of about four times larger in principle than those of known elements utilizing fluorescence emission. Researches and developments regarding layer configurations and materials of light-emitting elements, as well as the developments of materials for the elements, have been extensively conducted (see Patent document 1 and Non-Patent documents 1 to 3, for example). There are high expectations of creating novel materials for improving element performance. For example, triarylamine materials have been known for a long time to be useful as electron hole-transporting materials, and many inventions for improving performance of triarylamine materials have been made. As for a non-triarylamine material, use of an iridium complex from the viewpoint of its electron blocking function has been reported (Patent document 2). However, this material has an insufficient electron hole-injection property, and thus further improvements have been required.

### PRIOR ART DOCUMENTS

### Patent Documents

[Patent document 1] U.S. Pat. No. 6,097,147
[Patent document 2] U.S. Patent Publication No. 2004/0048101

### Non-Patent Documents

[Non-Patent document 1] M. A. Baldo, et al., Nature, Vol. 395, pp. 151-154 (1998)
[Non-Patent document 2] M. A. Baldo, et al., Nature, Vol. 403, No. 17, pp. 750-753 (2000)
[Non-Patent document 3] “Device physics, material chemistry, and device application of organic light emitting diodes”, supervised by Chihaya Adachi, CMC Publishing Co., Ltd. (2007)

### SUMMARY OF INVENTION

### Problem to be solved by Invention

It is an object of the present invention to provide an organic electroluminescent element retaining high electron hole-injection properties compared to those of known organic EL elements.

### Means for Solving Problem

The object of the present invention can be achieved by the following configurations.

1. An organic electroluminescent element comprising an anode, a cathode, and an organic compound layer sandwiched by the anode and the cathode, wherein

the organic compound layer at least comprises a light-emitting layer and a charge-generating layer;

(1) the charge-generating layer is composed of at least one layer and provided between the anode and the light-emitting layer; and

(2) the at least one layer of the charge-generating layer comprises an organic metal complex.

2. The organic electroluminescent element of the above 1, wherein the at least one layer of the charge-generating layer comprises an electron-extracting material.

3. The organic electroluminescent element of the above 2, wherein the electron-extracting material has an LUMO level of −6.0 to −3.0 eV.

4. The organic electroluminescent element of any one of the above 1 to 3, wherein the organic metal complex is represented by General Formula (1):

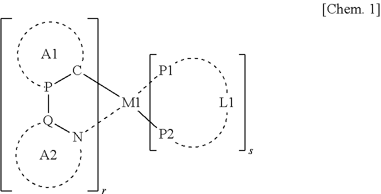

wherein P and Q each represents a carbon atom or a nitrogen atom; A1 represents an atomic group that forms an aromatic hydrocarbon ring or an aromatic heterocycle together with P—C; A2 represents an atomic group that forms an aromatic hydrocarbon ring or an aromatic heterocycle together with Q-N; P1-L1-P2 represents a bidentate ligand; P1 and P2 each independently represents a carbon atom, a nitrogen atom, or an oxygen atom; L1 represents an atomic group that forms a bidentate ligand together with P1 and P2; r represents an integer of 1 to 3; represents an integer of 0 to 2, provided that r+s is 2 or 3; and M1 represents a metal element belonging to Groups 8 to 10 on the periodic table.

5. The organic electroluminescent element of any one of the above 2 to 4, wherein the charge-generating layer is composed of a layer comprising the electron-extracting material and a layer comprising the organic metal complex and adjoining the layer comprising the electron-extracting material.

6. The organic electroluminescent element of any one of the above 2 to 5, wherein an absolute difference value between the LUMO level of the electron-extracting material and a HOMO level of the organic metal complex adjoining the electron-extracting material is 0.0 eV or more and 1.0 eV or less.

7. The organic electroluminescent element of any one of the above 1 to 6, wherein the light-emitting layer comprises a phosphorescence-emitting material represented by General Formula (2):

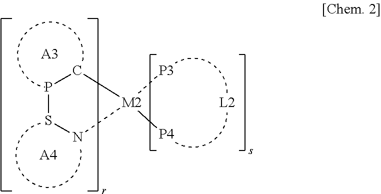

wherein, R and S each represents a carbon atom or a nitrogen atom; A3 represents an atomic group that forms an aromatic hydrocarbon ring or an aromatic heterocycle together with R—C; A4 represents an atomic group that forms an aromatic hydrocarbon ring or an aromatic heterocycle together with S—N; P3-L2-P4 represents a bidentate ligand; P3 and P4 each independently represents a carbon atom, a nitrogen atom, or an oxygen atom; L2 represents an atomic group that forms a bidentate ligand together with P3 and P4; r represents an integer of 1 to 3; represents an integer of 0 to 2, provided that r+s is 2 or 3; and M2 represents a metal element belonging to Groups 8 to 10 on the periodic table.

8. The organic electroluminescent element of any one of the above 1 to 7, wherein an absolute difference value between the HOMO level of the organic metal complex constituting the charge-generating layer and a HOMO level of an organic metal complex in the light-emitting layer is 0.0 eV or more and 1.0 eV or less.

9. The organic electroluminescent element of any one of the above 1 to 8, wherein the organic metal complex constituting the charge-generating layer and the organic metal complex in the light-emitting layer are the same organic metal complex.

10. The organic electroluminescent element of any one of the above 1 to 8, wherein the organic metal complex constituting the charge-generating layer is a non-phosphorescence emitting complex.

11. The organic electroluminescent element of any one of the above 1 to 10, wherein the organic electroluminescent element emits white light.

12. A lighting device comprising the organic electroluminescent element of any one of the above 1 to 11.

13. A display device comprising the organic electroluminescent element of any one of the above 1 to 11.

### Effects of the Invention

The organic EL element material of the present invention can provide an organic electroluminescent element that shows a controlled increase in voltage during driving compared to increases in voltages in known organic EL elements.

### BRIEF DESCRIPTION OF THE DRAWINGS

FIG. 1 This is a schematic diagram illustrating an example of a display device composed of organic EL elements.

FIG. 2 This is a schematic diagram of a display unit A.

FIG. 3 This is a schematic diagram of a pixel.

FIG. 4 This is schematic diagrams of a full-color display device of a passive-matrix system.

FIG. 5 This is a schematic diagram of a lighting device.

FIG. 6 This is a cross-sectional view of a lighting device.

FIG. 7 this shows schematic diagrams illustrating configurations of a full-color organic EL display device.

### EMBODIMENTS FOR CARRYING OUT THE INVENTION

Details of individual components according to the present invention will now be described in turn.

<<Definition of Highest Occupied Molecular Orbital (HOMO) Level and Lowest Unoccupied Molecular Orbital (LUMO) Level>>

In the present invention, the levels of the HOMO and LUMO refer to the values of energy levels of the highest occupied molecular orbital (HOMO) and the lowest unoccupied molecular orbital (LUMO), respectively, of a molecule. These are levels calculated with molecular orbital calculation software, Gaussian 98 (Gaussian 98, Revision A.11.4, M. J. Frisch, et al., Gaussian, Inc., Pittsburgh Pa., 2002) manufactured by Gaussian, Inc. in U.S.A. and are defined as values each obtained by rounding off the value (eV unit conversion value) calculated by structural optimization using B3LYP/6-31G* as a keyword to the first decimal place. This calculated value is valid because of a high correlation between the calculated values determined by such a method and experimental values.

<<Constituent Layer and Organic Compound Layer of Organic EL Element>>

Layers such as constituent layers and an organic compound layer of the organic EL element of the present invention will be described. Unlimited preferred examples of the layer configuration of the organic EL element of the present invention are shown below.

(i) anode/charge-generating layer/light-emitting layer/electron-transporting layer/cathode

(ii) anode/charge-generating layer/light-emitting layer/electron hole-blocking layer/electron-transporting layer/cathode

(iii) anode/charge-generating layer/light-emitting layer/electron hole-blocking layer/electron-transporting layer/cathode buffer layer/cathode

(iv) anode/anode buffer layer/charge-generating layer/light-emitting layer/electron hole-blocking layer/electron-transporting layer/cathode buffer layer/cathode

(v) anode/charge-generating layer 1/light-emitting layer 1/electron-transporting layer/charge-generating layer 2/light-emitting layer 2/electron-transporting layer/cathode buffer layer/cathode

<<Organic Compound Layer (Also Referred to as Organic Layer)>>

The organic compound layer according to the present invention will be described. The organic EL element of the present invention preferably includes a plurality of organic compound layers as constituent layers. For example, among the layer configurations mentioned above, the organic compound layers are the electron hole-transporting layer, the light-emitting layer, the electron hole-blocking layer and the electron-transporting layer. If other layers, such as the electron hole-injecting layer and the electron-injecting layer, contain any organic compound that is contained in the constituent layers of the organic EL element, these layers can also be defined as the organic compound layers according to the present invention.

Furthermore, for example, if the anode buffer layer and the cathode buffer layer each contains an organic compound, it is understood that the anode buffer layer and the cathode buffer layer are the organic compound layers.

Examples of the organic compound layer also include layers containing “organic EL element materials that can be used in constituent layers of an organic EL element”.

In the organic EL element of the present invention, a blue light-emitting layer, a green light-emitting layer and a red light-emitting layer are preferably monochromatic light-emitting layers emitting light of a maximum wavelength in the range of 430 to 480 nm, 510 to 550 nm and 600 to 640 nm, respectively. The display device preferably includes these layers.

In the organic EL element, at least these three light-emitting layers may be laminated into a white light-emitting layer. Furthermore, non-light-emitting intermediate layer(s) may be disposed between these light-emitting layers.

The organic EL element of the present invention is preferably a white light-emitting layer. The lighting device preferably includes these layers.

Each layer of the organic EL element of the present invention will be described.

<<Electron-Extracting Layer>>

The electron-extracting layer according to the present invention contains an electron-extracting material and has a function for extracting electrons from an adjacent layer. The electron-extracting material constituting this layer is a compound having high electron affinity, in other words, a compound having a deep LUMO level. For example, a well-known electron acceptor (acceptor molecule) is suitably used, and the LUMO level is preferably −6.0 to −3.0 eV, and more preferably −5.0 to −4.0 eV.

A compound having a LUMO level of −6.0 or more has a stability suitable for common use without difficulty and can achieve the advantages of the present invention. A compound having a LUMO level of larger than −3.0 functions as a material constituting a charge-generating layer without any problem; however, a difference from the energy level of the adjacent layer involved in charge transfer, in particular, a difference from the energy level of a light-emitting layer is important in order to suitably achieve the functions of the organic EL element intended by the present invention. The LUMO level is therefore desirably −3.0 or less. Furthermore, a LUMO level close to the HOMO level of an adjacent material is desirable, and the absolute difference value between the both materials is preferably 0.0 eV or more and 2.0 eV or less, and more preferably 0.0 eV or more and 1.0 eV or less. Specific examples of the compound serving as the electron-extracting material that can be suitably used in the present invention include, but not limited to, multi-fluorinated compounds, multi-cyano substituted compounds, condensed aromatic rings substituted with multi-electron-extracting groups and condensed heteroaromatic rings substituted with multi-electron-extracting groups, and compounds described in Japanese Patent No. 4315874 and Japanese Patent Laid-Open Application Publications Nos. 2006-135144 and 2006-135145.

<<Charge-Generating Layer (CGL)>>

### <Layers Constituting Charge-Generating Layer>

The charge-generating layer in the present invention is formed of at least one layer and has functions for injecting electron holes in the direction toward the cathode of the element and injecting electrons in the direction toward the anode when a voltage is applied.

A layer that generates electron holes and electrons and has the interface with an organic EL layer electrically connecting a plurality of light emission units in series is also referred to as a charge-generating layer.

In order to achieve a possible maximum effect of the present invention, the charge-generating layer is composed of at least two layers.

The layer configuration of the charge-generating layer of the present invention will be described. The p-type and n-type layers (1) to (11) described below can be used alone or in combination as needed, as the charge-generating layer of the present invention. The n-type layer is a transporting layer whose majority carriers are electrons and preferably has electroconductivity that is equal to or higher than that of a semiconductor. The p-type layer is a transporting layer whose majority carriers are electron holes and preferably has electroconductivity that is equal to or higher than that of a semiconductor. Examples of the p-type layer and the n-type layer are shown below, but not limited thereto:

(1) electron-transporting material layer

(2) electron-extracting layer (organic acceptor material/inorganic acceptor material),

(3) layer of a mixture of an electron-transporting material and an alkali (alkaline earth) metal salt (or alkali (alkaline earth) metal precursor)

(4) n-type semiconductor layer (organic material, inorganic material)

(5) n-type electroconductive polymer layer

(6) single electron hole-injecting/transporting material layer

(7) layer of a mixture of electron hole-injecting/transporting materials

(8) organic metal complex layer

(9) layer of a mixture of an electron hole-transporting material and a metal oxide

(10) p-type semiconductor layer (organic material, inorganic material)

(11) p-type electroconductive polymer layer

In order to achieve a possible maximum advantage of the present invention, the charge-generating layer is composed of at least two layers one of which is the layer (8). A preferred combination of the two layers is a combination of the layer (8) and the layer (9) or a combination of the layer (8) and the layer (2). The combination of the layer (8) and the layer (2) is more preferred.

The charge generation site may be inside the charge-generating layer or may be the interface between the charge-generating layer and an adjacent layer or its vicinity. For example, when the charge-generating layer is composed of a single layer, the charge of electrons or electron holes may be generated in the charge-generating layer or may be generated at the interface between the charge-generating layer and a layer adjacent thereto.

In the present invention, the charge-generating layer is more preferably composed of two or more layers, and more preferably includes one or both of p-type semiconductor layer(s) and n-type semiconductor layer(s).

In such a case, each layer interface of the charge-generating layer composed of two or more layers may have an interface (heterointerface or homointerface) or may form a multi-dimensional interface such as a bulk heterostructure, an island structure or a segregated phase structure.

The two layers each preferably has a thickness of 1 nm or more and 100 nm or less, and more preferably 10 nm or more and 50 nm or less.

The charge-generating layer of the present invention desirably has a high transmittance of light emitted by the light-emitting layer. In order to sufficiently extract light and provide sufficient luminance, the transmittance at a wavelength of 550 nm is preferably 50% or more, and more preferably 80% or more.

The materials usable for each layer constituting the charge-generating layer of the present invention are the above-mentioned organic compounds (organic acceptors, organic donors), organic metal complex compounds, aromatic hydrocarbon compounds and derivatives thereof, and heteroaromatic hydrocarbon compounds and derivatives thereof and the like, and metals and inorganic compounds such as inorganic oxides and inorganic salts. These compounds can be used alone or as a mixture.

<<Light-Emitting Layer>>

The light-emitting layer according to the present invention emits light by recombination of electrons and electron holes injected from electrodes or an electron-transporting layer and electron hole-transporting layer. The light emission site may be inside the light-emitting layer or may be the interface between the light-emitting layer and an adjacent layer thereof.

The total thickness of the light-emitting layer(s) is not particularly limited, but is preferably controlled within a range of 2 nm to 5 μm, more preferably 2 to 200 nm, and most preferably 10 to 20 nm from the viewpoints of homogeneity of the film, prevention of application of unnecessary high voltage during light emission and an improvement in stability of color(s) of light based on the driving current.

The light-emitting layer can be produced by forming a thin film with a light-emitting dopant or host compound described below by a known film forming method such as vacuum deposition, spin coating, casting, LB method or ink jetting.

The light-emitting layer of the organic EL element of the present invention preferably contains a light-emitting host compound and at least one light-emitting dopant (such as a phosphorescence-emitting dopant (also referred to as a phosphorescence-emitting dopant) or a fluorescent dopant). The light-emitting layer may further contain an electron hole-transporting material or electron-transporting material described later.

(Host Compound (Also Referred to as Light-Emitting Host or the Like))

The host compound used in the present invention will be described. The host compound in the present invention is defined as a compound that is contained in the light-emitting layer in a mass ratio of 20% or more based on the compound(s) contained in the layer and that has a phosphorescence quantum yield of phosphorescence emission of less than 0.1, and preferably less than 0.01 at room temperature (25° C.). The mass ratio of the compound in the light-emitting layer is preferably 20% or more based on the compound(s) contained in the layer.

The preferred host compound has a 0-0 band whose wavelength is shorter than that of the 0-0 band of the phosphorescence of the light-emitting dopant. The host compound is characterized in that the 0-0 band of the phosphorescence is 460 nm or less. The 0-0 band of the phosphorescence is preferably 450 nm or less, more preferably 440 nm or less, and most preferably 430 nm or less.

A method for measuring the 0-0 band of the phosphorescence in the present invention will be described. First, a method for measuring a phosphorescence spectrum will be described. A light-emitting host compound to be measured is dissolved in a sufficiently deoxygenated solvent mixture of ethanol/methanol=4/1 (vol/vol). The solution is put in a cell for phosphorescence measurement, followed by irradiation with exciting light at a liquid nitrogen temperature of 77K to measure the light emission spectrum 100 ms after the irradiation with the exciting light. Since the lifetime of phosphorescence emission is longer than that of fluorescence emission, it is believed that most of the light remaining after 100 ms is phosphorescence. Though a compound having a phosphorescence lifetime shorter than 100 ms may be measured by shortening the delay time, phosphorescence cannot be distinguished from fluorescence if the delay time is excessively shortened to the extend that phosphorescence cannot be distinguished from fluorescence. It is therefore necessary to select an appropriate delay time for allowing distinguishing between phosphorescence and fluorescence.

If a compound cannot be dissolved in the above-mentioned solvent system, an appropriate solvent that can dissolve the compound may be used (substantially, in the above-mentioned method, the effect of the solvent on the phosphorescence wavelength is significantly low and therefore does not cause any problem). Next, the determination of the 0-0 band is described. In the present invention, the maximum wavelength of emitted light appearing on the shortest wavelength side in the phosphorescence spectrum chart obtained in the above-described method is defined as the 0-0 band. Since the strength of a phosphorescence spectrum is usually low, the magnification of the spectrum makes the distinguishing between noises and peaks difficult in some cases. In such cases, the peak wavelength derived from a phosphorescence spectrum can be determined by magnifying the emission spectrum immediately after irradiation with exciting light (this is referred to as ambient light spectrum, for convenience), superimposing the magnified light emission spectrum on a light emission spectrum 100 ms after the irradiation with exciting light (this is referred to as phosphorescence spectrum, for convenience) and reading the peak wavelength derived from the phosphorescence spectrum from the ambient light spectrum portion. The peak wavelength can also be read by separating peaks from noises by smoothing the phosphorescence spectrum. The smoothing process can be performed by a Savitzky-Golay smoothing method and the like.

The host compound may be used together with any other known host compound in combination, or multiple types of host compound may be used. The use of multiple types of host compound facilitates the control of the transportation of charge and the increase in the efficiency of the organic EL element. Furthermore, use of a plurality of light-emitting dopants described later allows mixing of different light and thereby allows the generation of any intended light color.

The conventionally known host compound that can be used in combination is preferably a compound having electron hole-transporting property and electron-transporting property, preventing the shift of light emission to the longer wavelength side, and having a high glass transition temperature (Tg).

Specific examples of the conventionally known host compound include the compounds described in the following documents:

Japanese Patent Laid-Open Application Publications Nos. 2001-257076, 2002-308855, 2001-313179, 2002-319491, 2001-357977, 2002-334786, 2002-8860, 2002-334787, 2002-15871, 2002-334788, 2002-43056, 2002-334789, 2002-75645, 2002-338579, 2002-105445, 2002-343568, 2002-141173, 2002-352957, 2002-203683, 2002-363227, 2002-231453, 2003-3165, 2002-234888, 2003-27048, 2002-255934, 2002-260861, 2002-280183, 2002-299060, 2002-302516, 2002-305083, 2002-305084, and 2002-308837.

Preferred specific examples of the host compound are as follows:

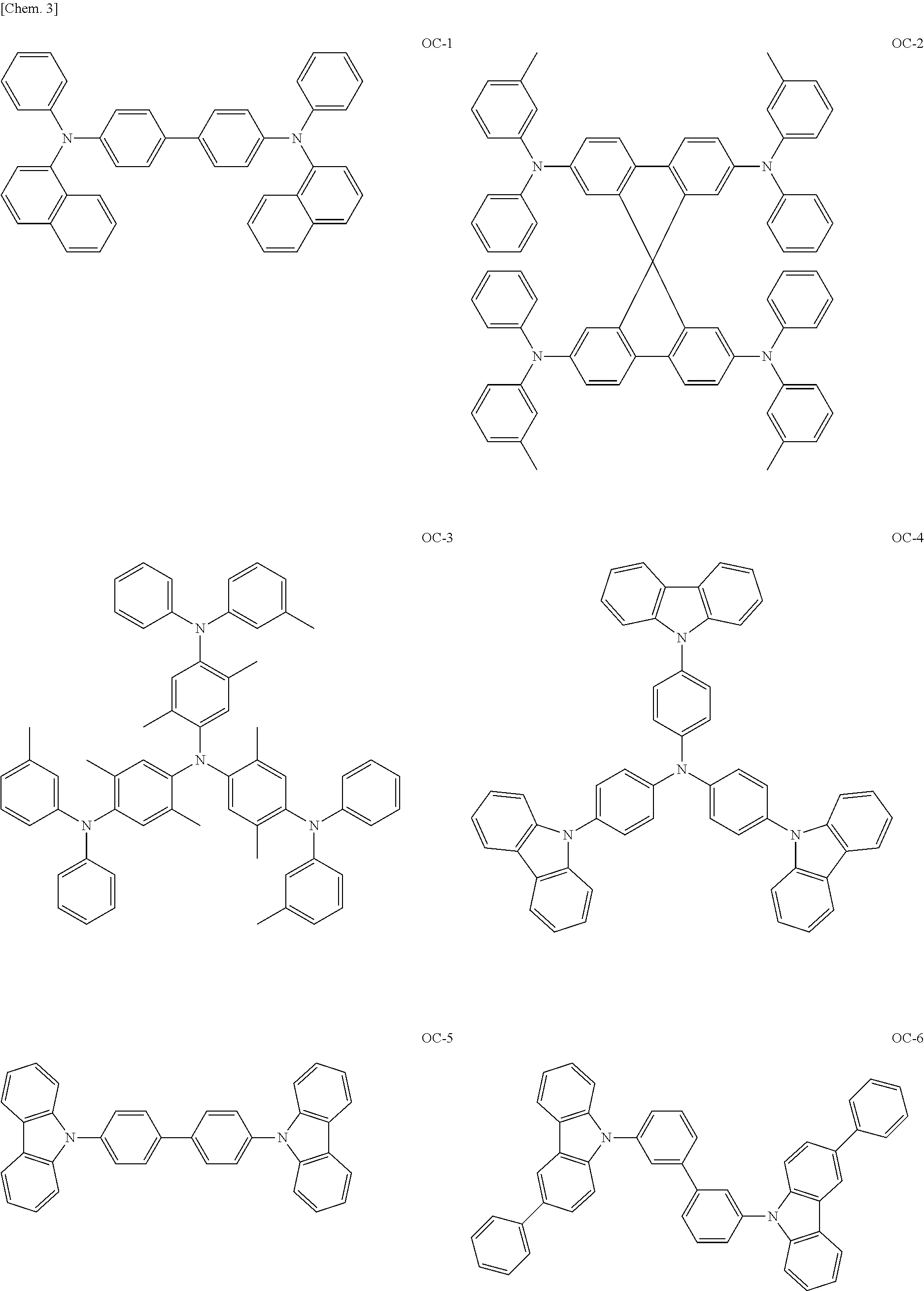

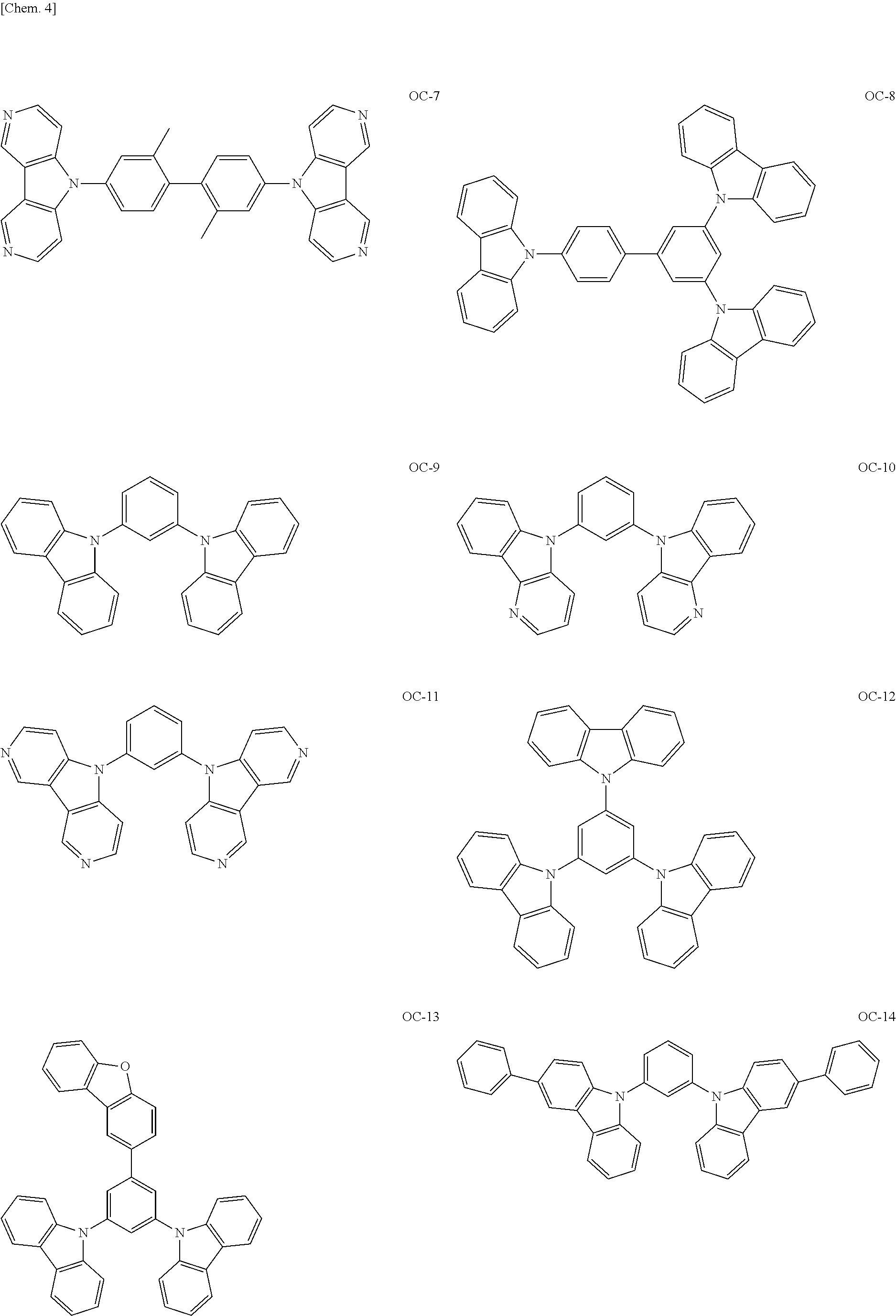

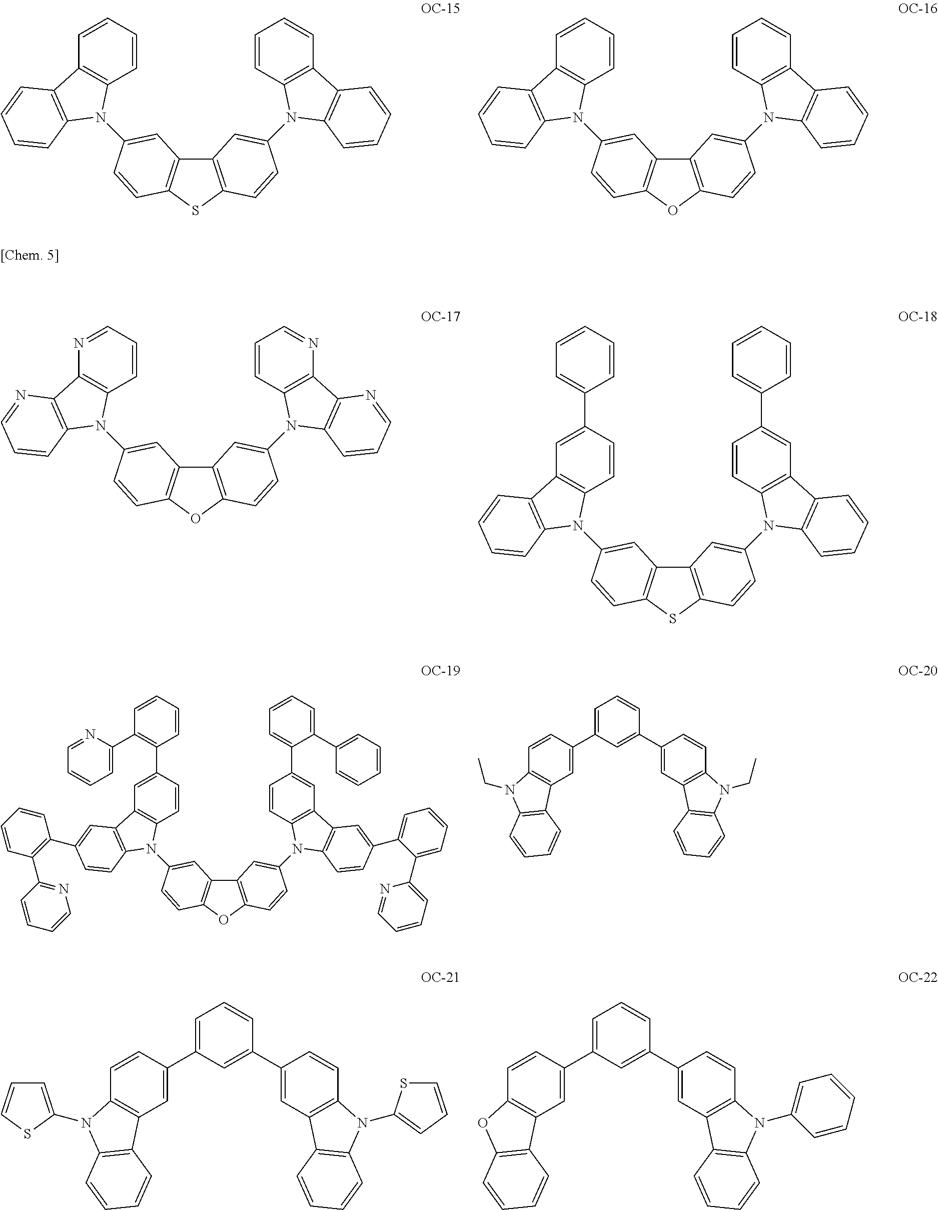

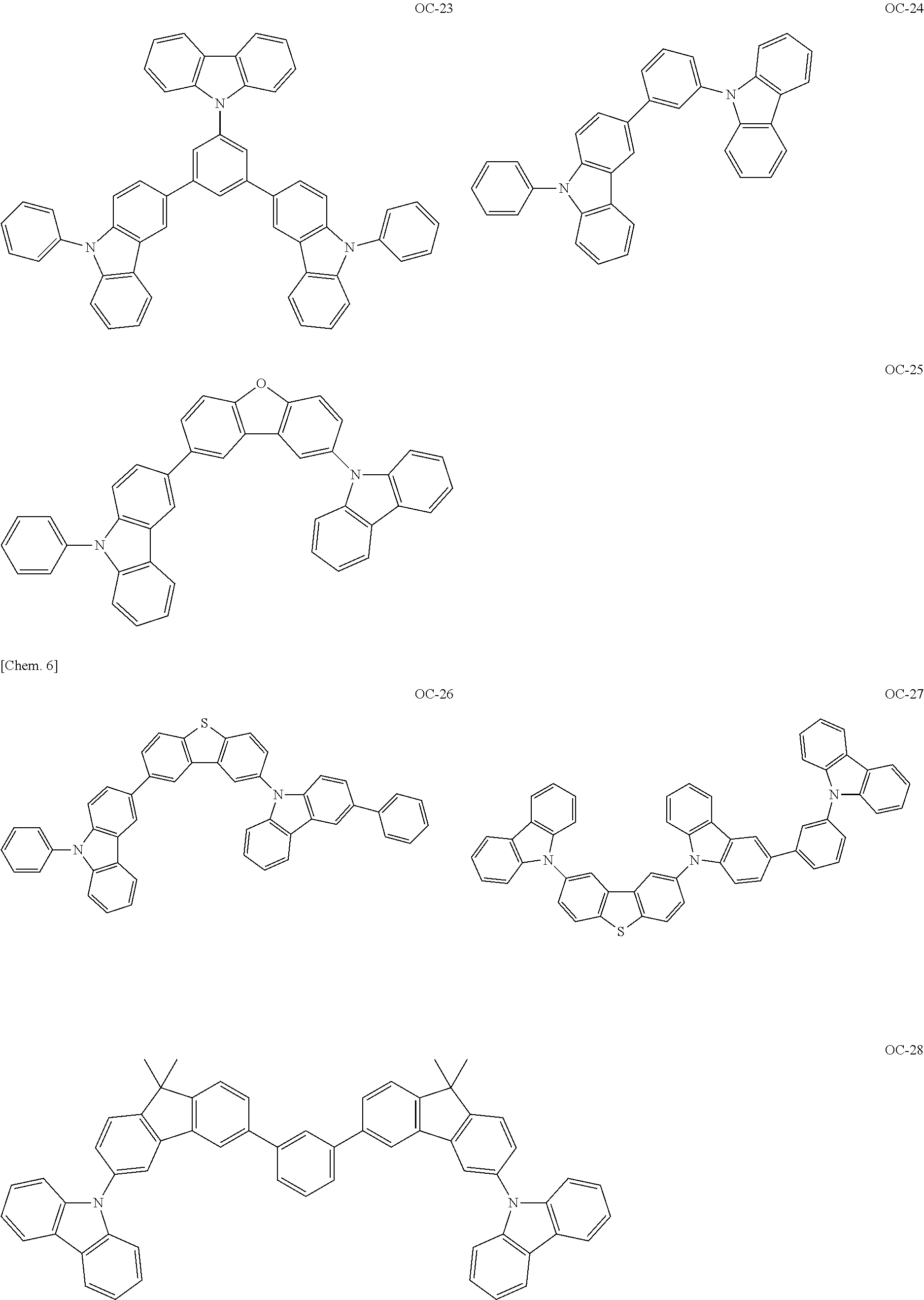

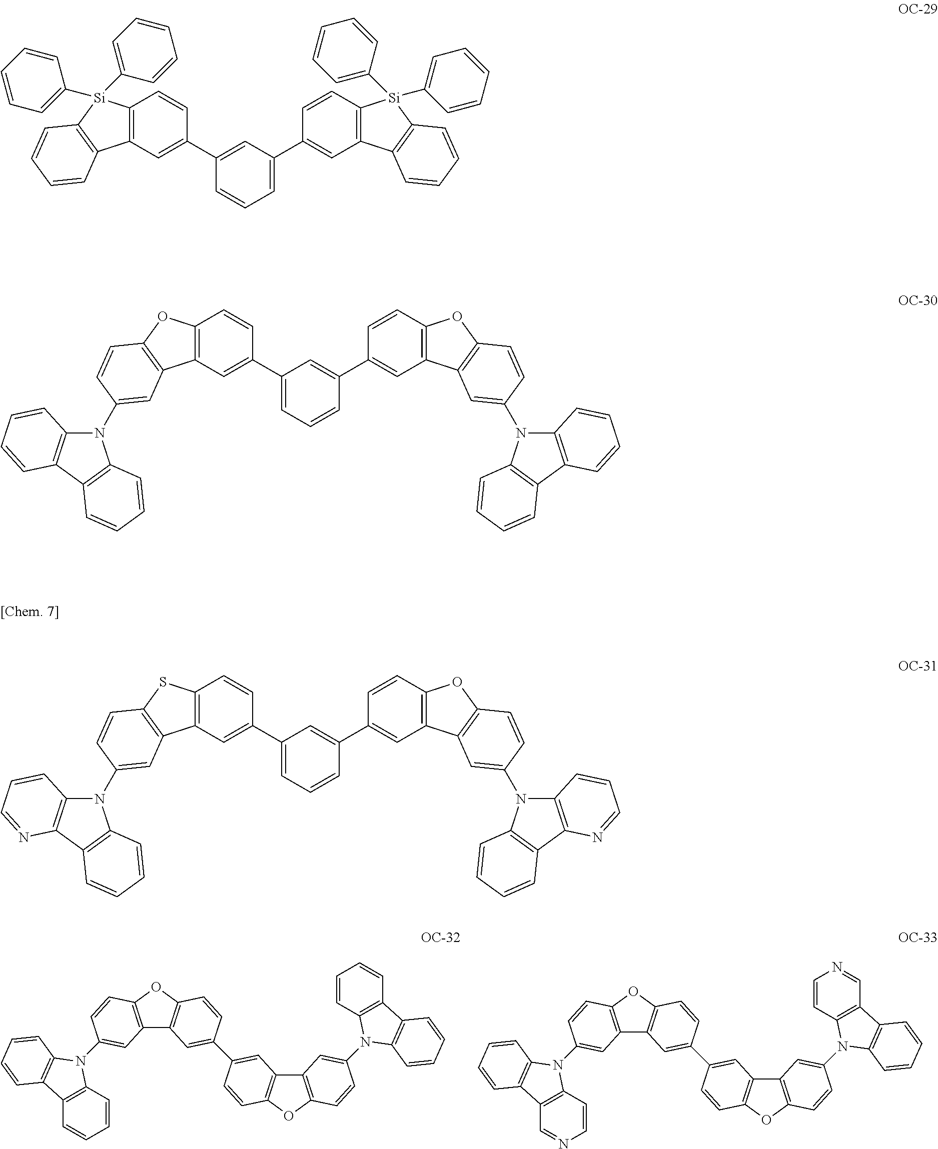

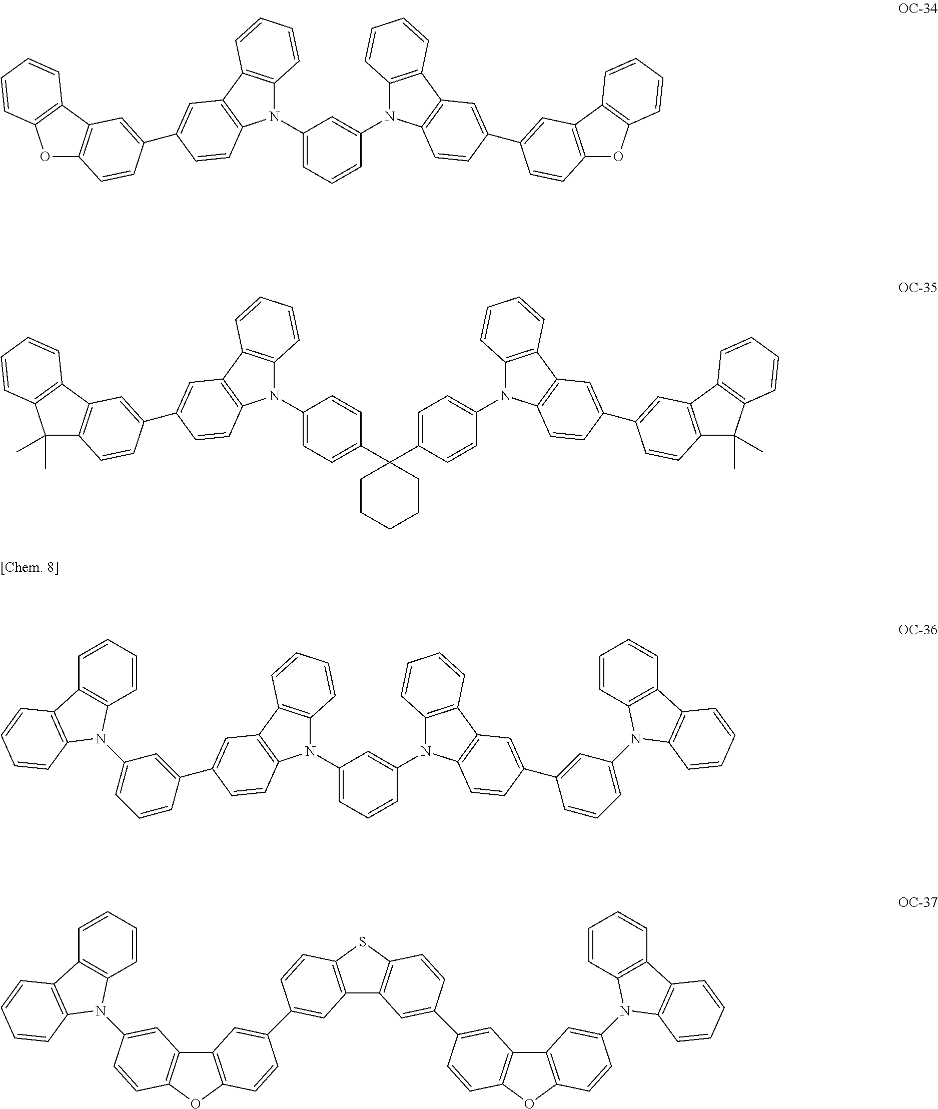 [SMILES: c1cc(-n2c3ccccc3c3cc(-c4ccc5oc6ccccc6c5c4)ccc32)cc(-n2c3ccccc3c3cc(-c4ccc5oc6ccccc6c5c4)ccc32)c1 ; CC1(C)c2ccccc2-c2cc(-c3ccc4c(c3)c3ccccc3n4-c3ccc(C4(c5ccc(-n6c7ccccc7c7cc(-c8ccc9c(c8)-c8ccccc8C9(C)C)ccc76)cc5)CCCCC4)cc3)ccc21 ; c1cc(-c2ccc3c(c2)c2ccccc2n3-c2cccc(-n3c4ccccc4c4cc(-c5cccc(-n6c7ccccc7c7ccccc76)c5)ccc43)c2)cc(-n2c3ccccc3c3ccccc32)c1 ; c1ccc2c(c1)c1ccccc1n2-c1ccc2oc3ccc(-c4ccc5sc6ccc(-c7ccc8oc9ccc(-n%10c%11ccccc%11c%11ccccc%11%10)cc9c8c7)cc6c5c4)cc3c2c1]

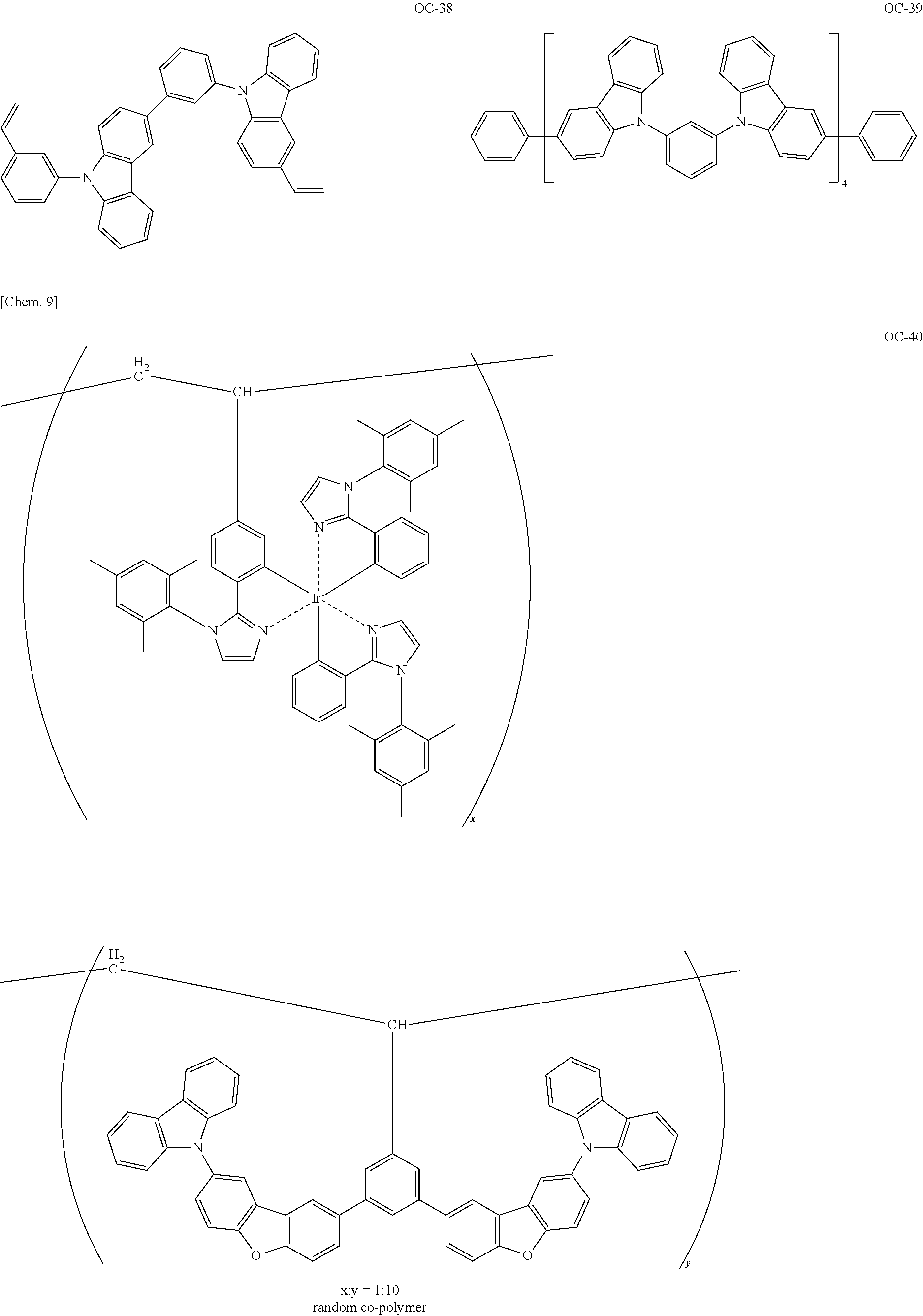

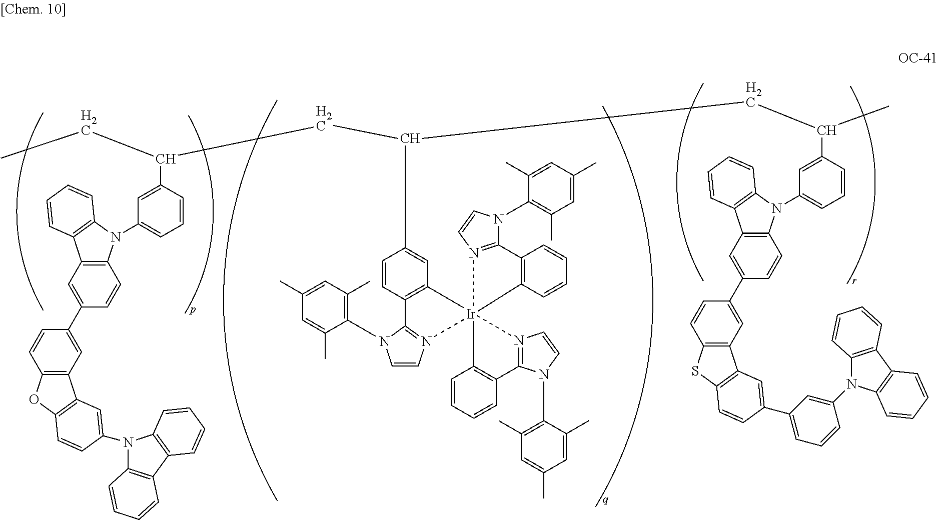

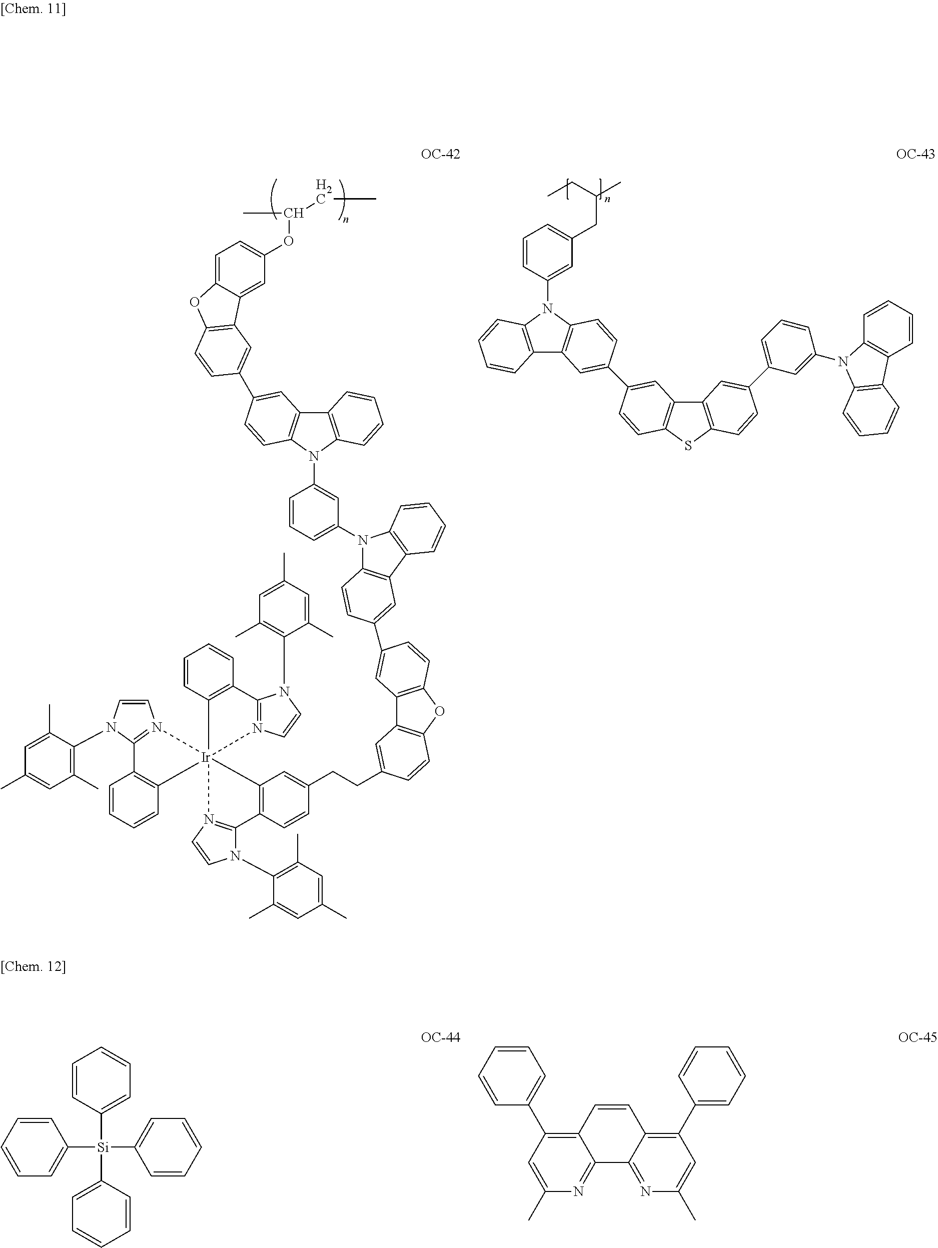

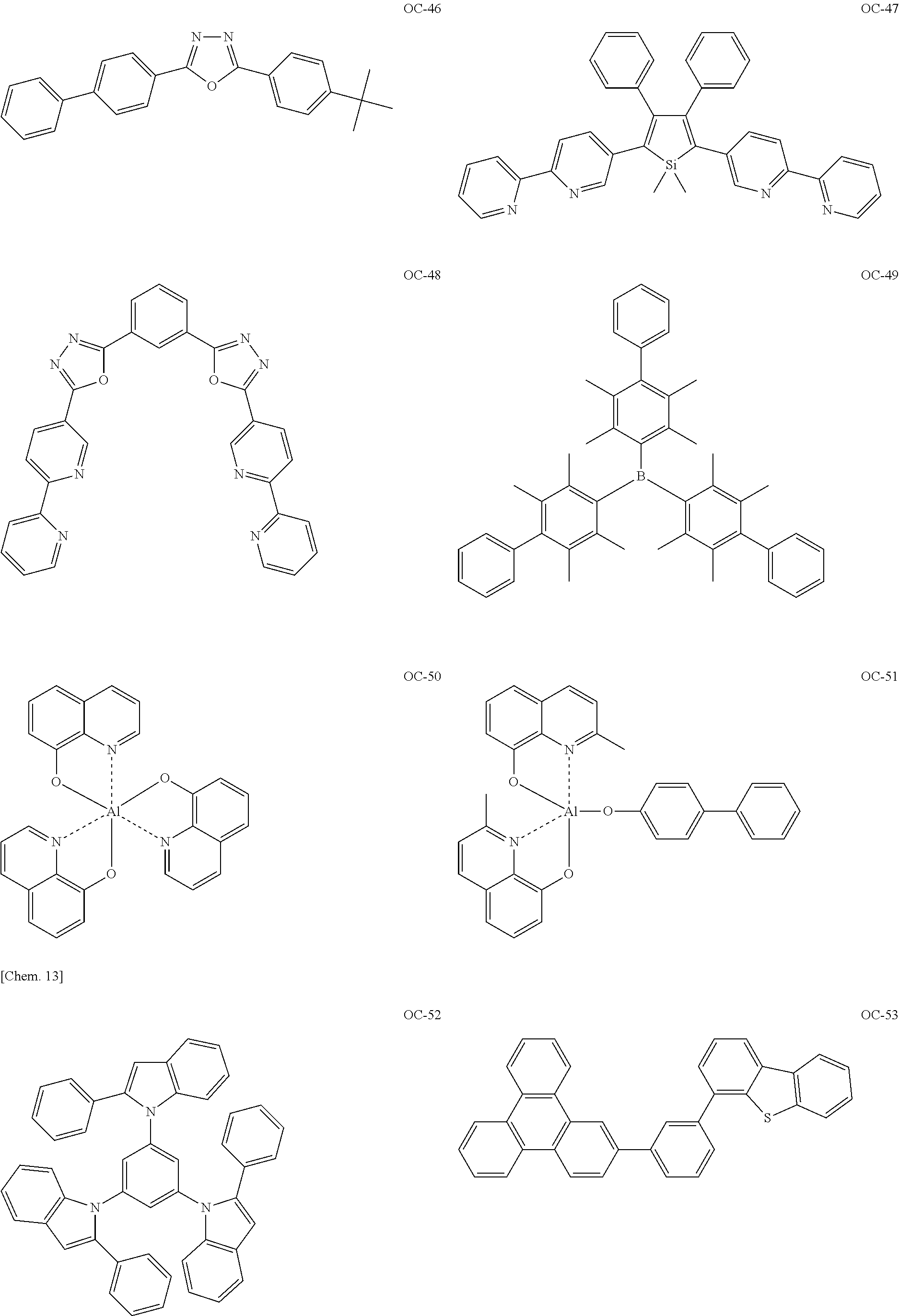

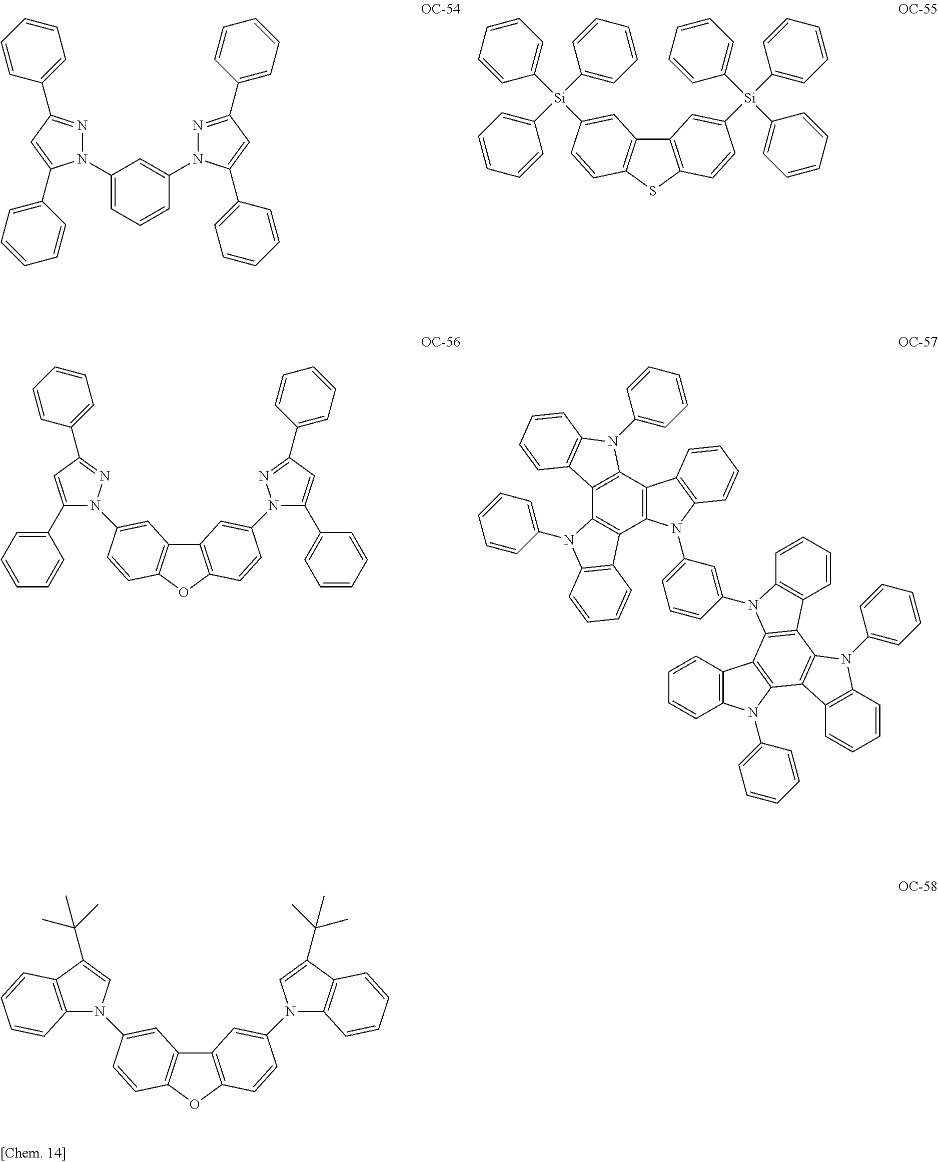 [SMILES: c1ccc(-c2cc(-c3ccccc3)n(-c3cccc(-n4nc(-c5ccccc5)cc4-c4ccccc4)c3)n2)cc1 ; c1ccc([Si](c2ccccc2)(c2ccccc2)c2ccc3sc4ccc([Si](c5ccccc5)(c5ccccc5)c5ccccc5)cc4c3c2)cc1 ; c1ccc(-c2cc(-c3ccccc3)n(-c3ccc4oc5ccc(-n6nc(-c7ccccc7)cc6-c6ccccc6)cc5c4c3)n2)cc1 ; c1ccc(-n2c3ccccc3c3c2c2c4ccccc4n(-c4cccc(-n5c6ccccc6c6c7c(c8ccccc8n7-c7ccccc7)c7c(c8ccccc8n7-c7ccccc7)c65)c4)c2c2c4ccccc4n(-c4ccccc4)c32)cc1 ; CC(C)(C)c1cn(-c2ccc3oc4ccc(-n5cc(C(C)(C)C)c6ccccc65)cc4c3c2)c2ccccc12]

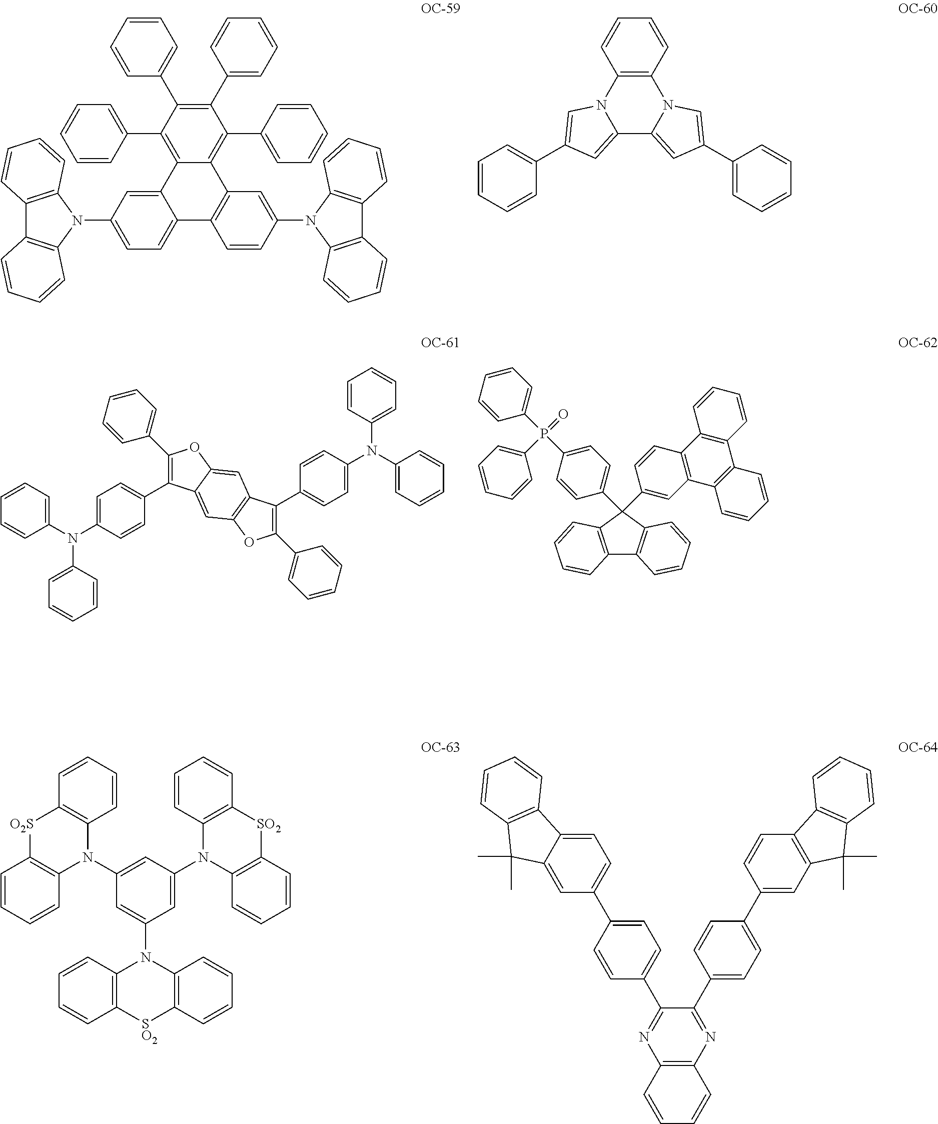

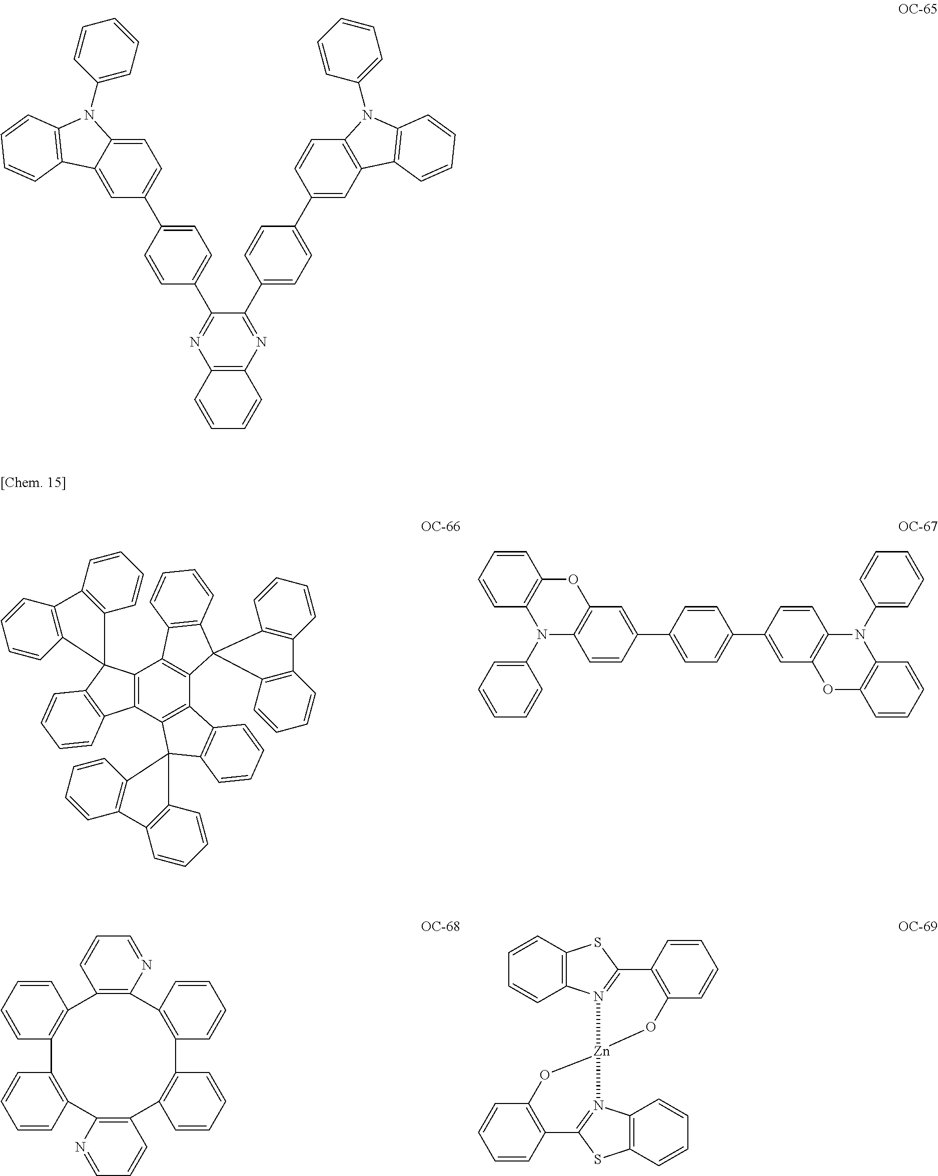

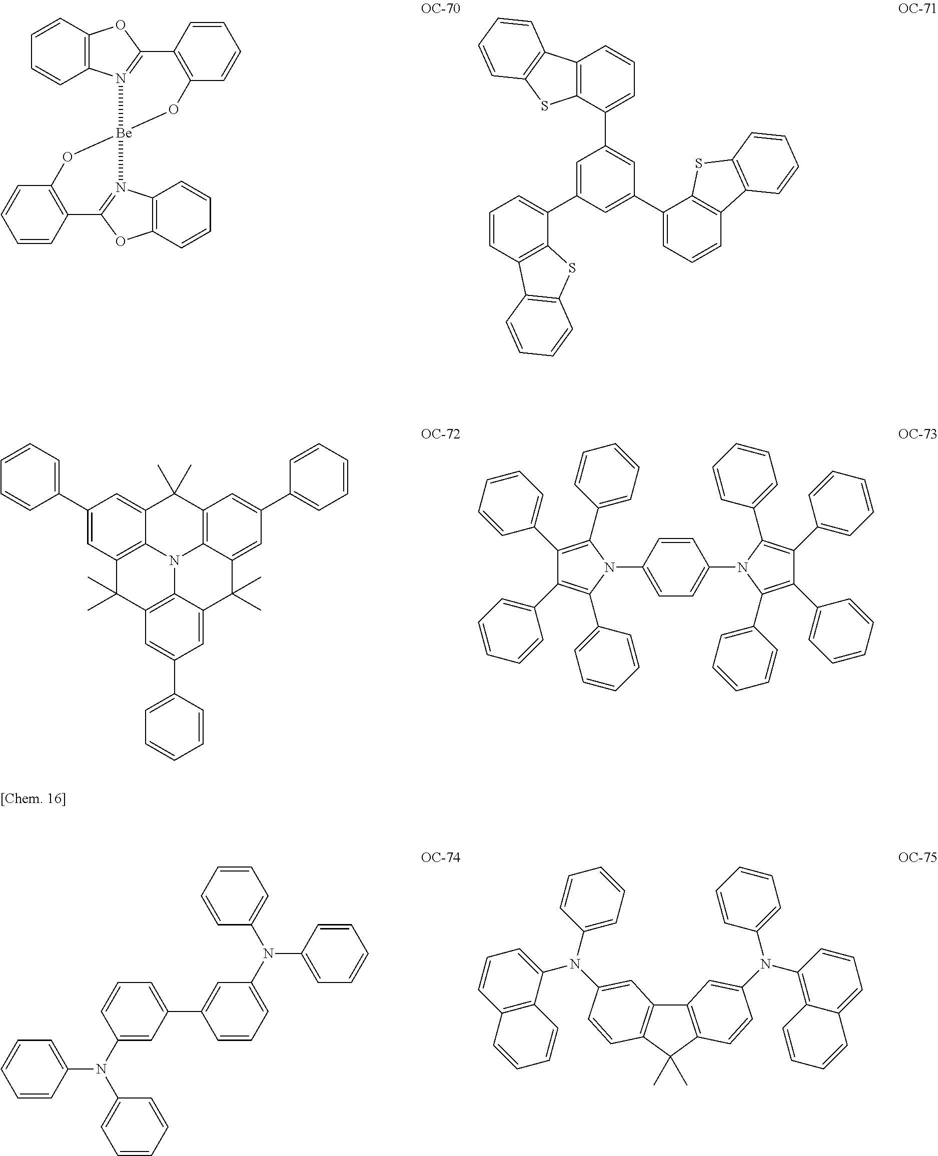

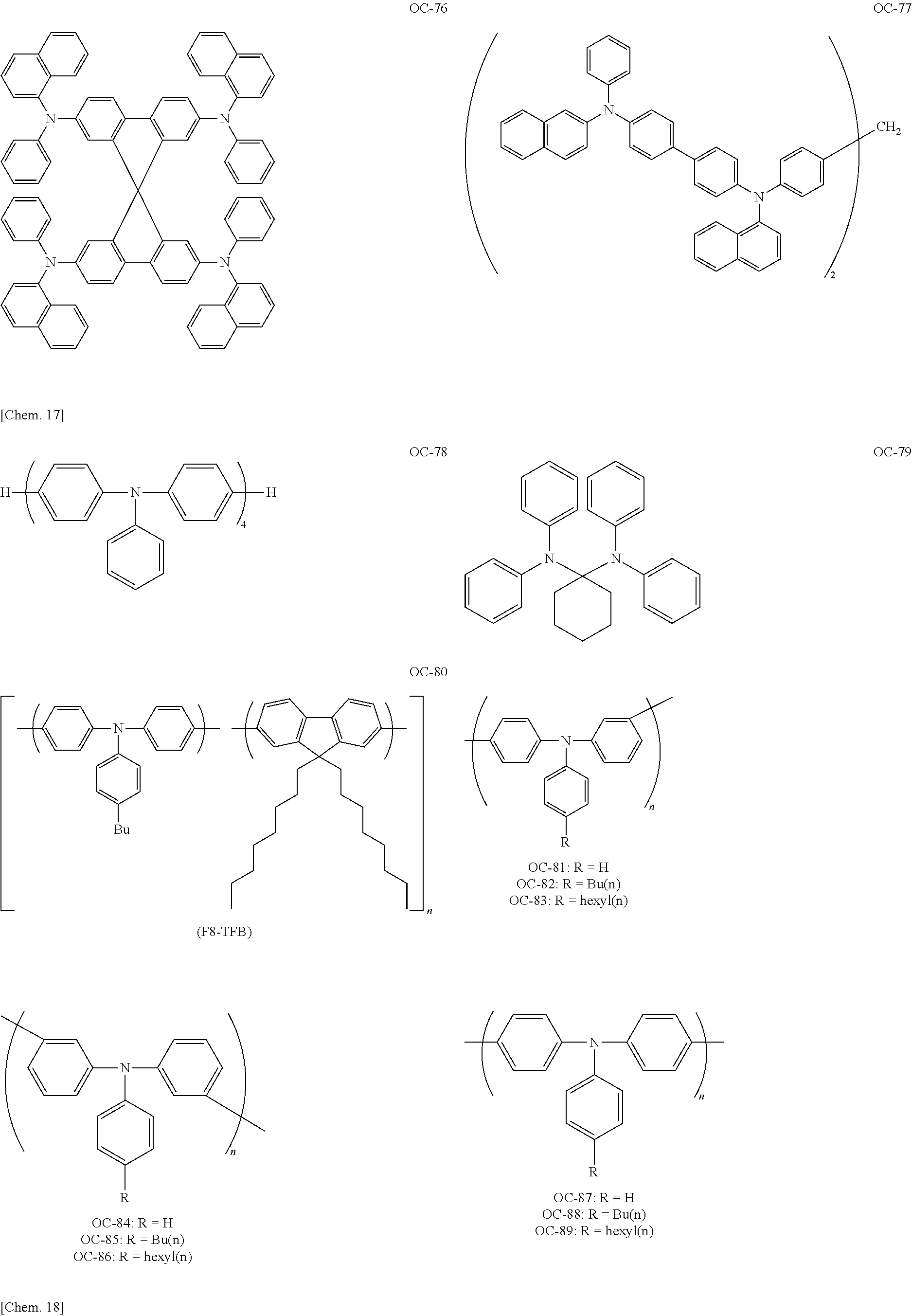

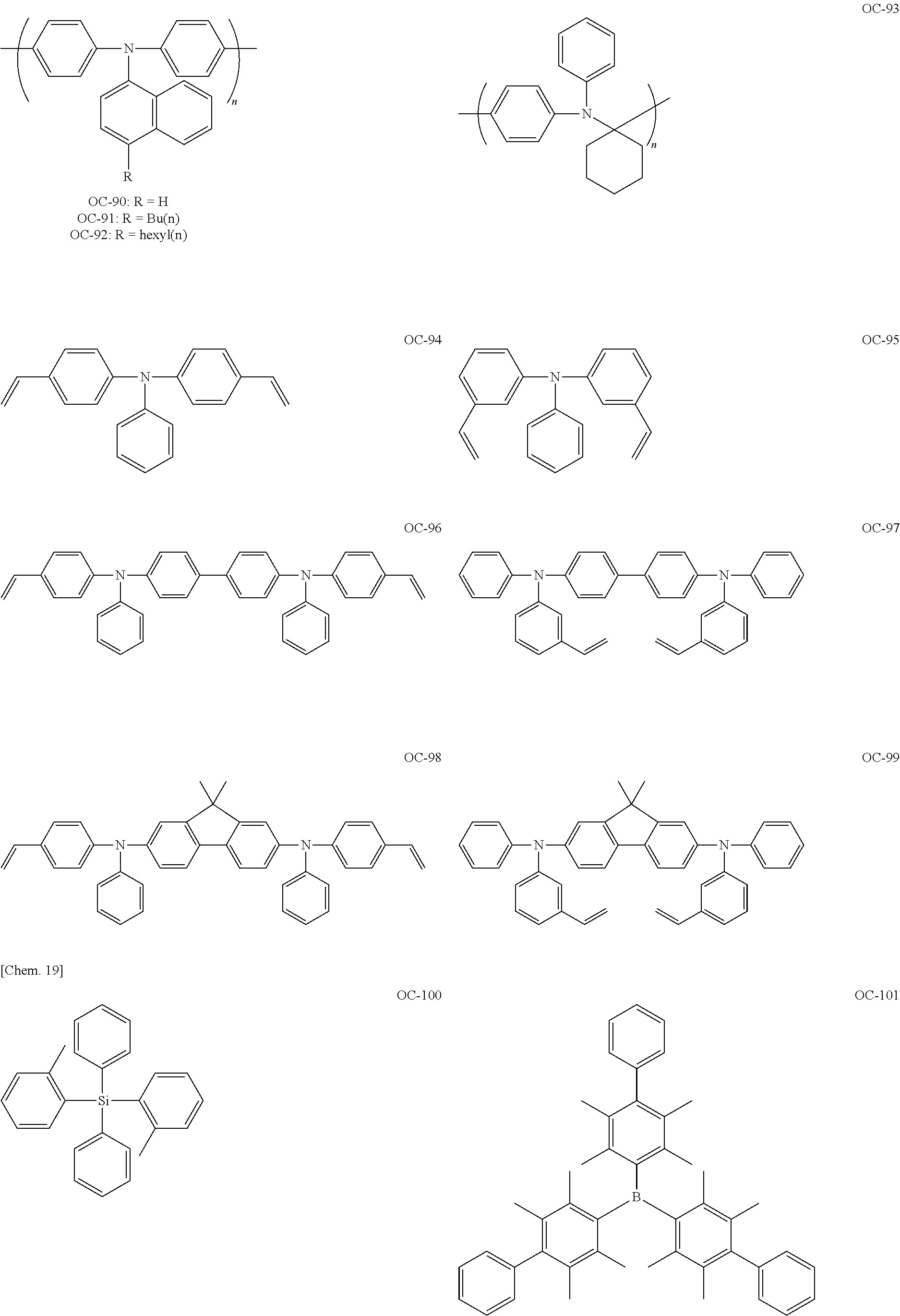

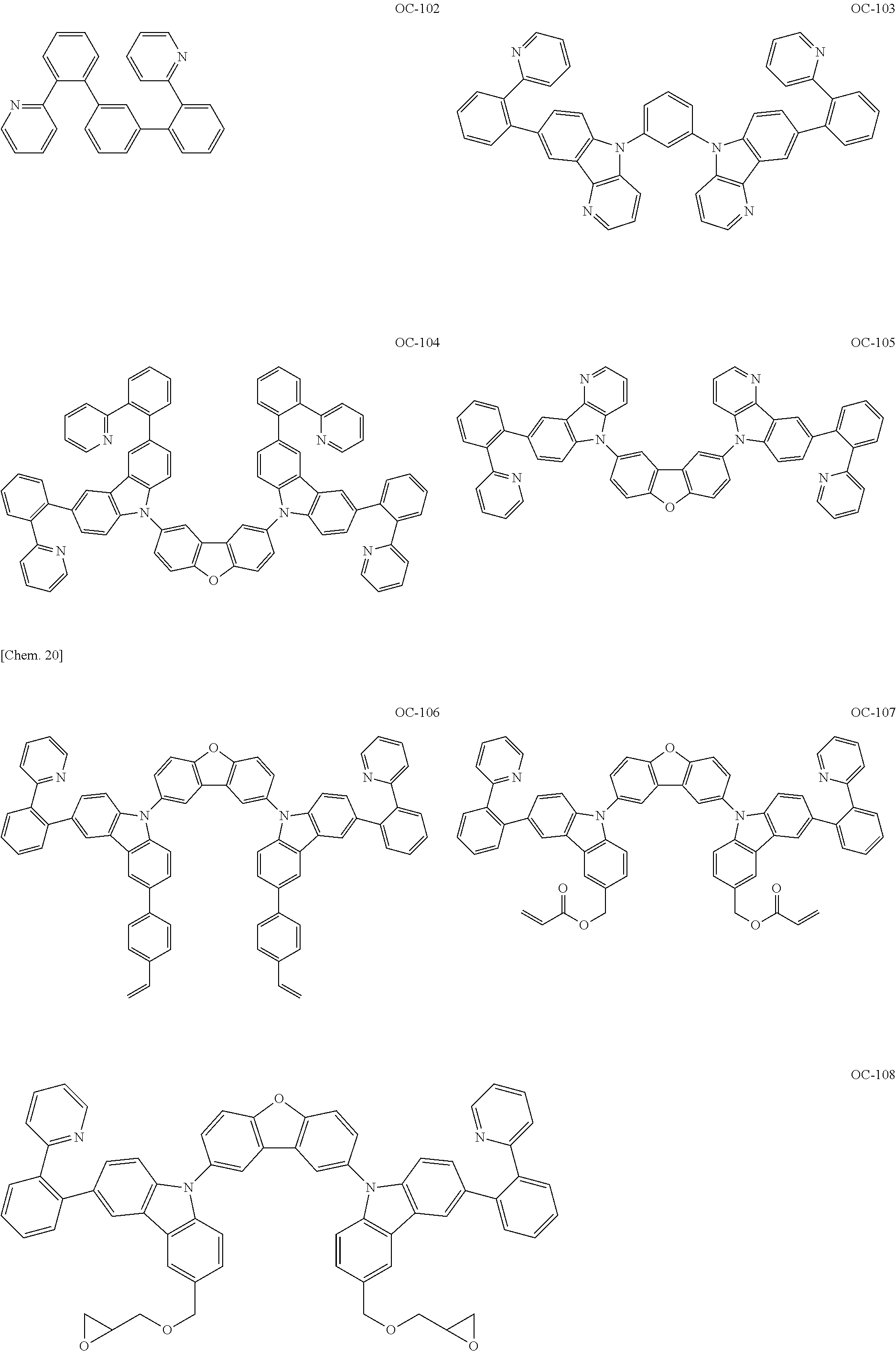

(Light-Emitting Dopant)

The light-emitting dopant according to the present invention will be described.

The light-emitting dopant according to the present invention may be a fluorescent dopant (also referred to as a fluorescent compound) or a phosphorescene-emitting dopant (also referred to as a phosphorescence-emitting body, phosphorescent compound, or phosphorescence-emitting compound), but from the viewpoint of providing an organic EL element having a high efficiency of light emission, the light-emitting dopant (simply, may be referred to as the light-emitting material) that is contained together with the host compound in the light-emitting layer or the light-emitting unit of the organic EL element of the present invention is preferably a phosphorescence-emitting dopant.

(Phosphorescence-Emitting Compound (Phosphorescence-Emitting Dopant))

A phosphorescence-emitting compound (phosphorescence-emitting dopant) according to the present invention will be described.

The phosphorescence-emitting compound according to the present invention is a compound that emits light from the excited triplet, specifically, a compound that emits phosphorescence at room temperature (25° C.) and is defined as a compound having a phosphorescence quantum yield of 0.01 or more at 25° C. The phosphorescence quantum yield is preferably 0.1 or more. On the other hand, a compound having a phosphorescence quantum yield of less than 0.01 at 25° C. is defined as a non-phosphorescence emitting compound.

The phosphorescence quantum yield can be measured by a method described in page 398 of Spectroscopy II of The 4th Series of Experimental Chemistry 7 (1992, published by Maruzen Co., Ltd.). The phosphorescence quantum yield in a solution can be measured using various solvents. Only requirement for the phosphorescence-emitting compound according to the present invention is to achieve the above-mentioned phosphorescence quantum yield (0.01 or more) in any solvent.

There are two principles of light emission by a phosphorescence-emitting compound. One is an energy transfer-type, wherein the recombination of carriers occurs on a host compound onto which the carriers are transferred to produce an excited state of the host compound, and then via transfer of this energy to a phosphorescence-emitting compound, light emission from the phosphorescence-emitting compound occurs. The other is a carrier trap-type, wherein a phosphorescence-emitting compound serves as a carrier trap to cause recombination of carriers on the phosphorescence-emitting compound, and thereby light emission from the phosphorescence-emitting compound occurs.

In each type, the energy in the excited state of the phosphorescence-emitting compound is required to be lower than that in the excited state of the host compound.

The phosphorescence-emitting compound can be appropriately selected from known compounds that are used in light-emitting layers of organic EL elements.

The phosphorescence-emitting compound according to the present invention is preferably a complex compound containing a metal of Groups 8 to 10 on the periodic table, more preferably an iridium compound (Ir complex), an osmium compound, a platinum compound (platinum complex type compound) or a rare earth complex, and most preferably an iridium compound (Ir complex).

In the present invention, the phosphorescence-emitting dopant contained in the light-emitting layer is preferably represented by the above General Formula (2), i.e., correspond to the organic metal complex represented by the above General Formula (1) preferably contained in at least one layer of the charge-generating layer.

These organic metal complexes will now be described.

<<Organic Metal Complex Represented by General Formula (1)>>

The organic metal complex according to the present invention is preferably a compound represented by General Formula (1).

In General Formula (1), examples of the aromatic hydrocarbon ring formed in A1 include a benzene ring, biphenyl ring, naphthalene ring, azulene ring, anthracene ring, phenanthrene ring, pyrene ring, chrysene ring, naphthacene ring, triphenylene ring, o-terphenyl ring, m-terphenyl ring, p-terphenyl ring, acenaphthene ring, coronene ring, fluorene ring, fluoranthrene ring, naphthacene ring, pentacene ring, perylene ring, pentaphene ring, picene ring, pyrene ring, pyranthrene ring and anthranthrene ring. These rings may also have substituents described below.

In General Formula (1), examples of the aromatic heterocycle formed in A1 include a furan ring, thiophene ring, oxazole ring, pyrrole ring, pyridine ring, pyridazine ring, pyrimidine ring, pyrazine ring, triazine ring, benzimidazole ring, oxadiazole ring, triazole ring, imidazole ring, pyrazole ring, triazole ring, indole ring, indazole ring, benzoimidazole ring, benzothiazole ring, benzoxazole ring, quinoxaline ring, quinazoline ring, cinnoline ring, quinoline ring, isoquinoline ring, phthalazine ring, naphthyridine ring, carbazole ring, carboline ring and diazacarbazole ring (indicating a carboline ring in which one of carbon atoms constituting the carboline ring is further replaced with a nitrogen atom). These rings may also have substituents described below.

<<Substituent>>

Examples of the substituent that may be possessed by the aromatic hydrocarbon ring or the aromatic heterocycle formed in A1 include alkyl groups (such as a methyl group, ethyl group, propyl group, isopropyl group, tert-butyl group, pentyl group, hexyl group, octyl group, dodecyl group, tridecyl group, tetradecyl group and pentadecyl group); cycloalkyl groups (such as a cyclopentyl group and cyclohexyl group); alkenyl groups (such as a vinyl group and allyl group); alkynyl groups (such as an ethynyl group and propargyl group); aromatic hydrocarbon groups (also referred to as aromatic hydrocarbon ring groups, aromatic carbon ring groups or aryl groups, such as a phenyl group, p-chlorophenyl group, mesityl group, tolyl group, xylyl group, naphthyl group, anthryl group, azulenyl group, acenaphthenyl group, fluorenyl group, phenanthryl group, indenyl group, pyrenyl group and biphenyryl group); aromatic heterocyclic groups (such as a pyridyl group, pyrimidinyl group, furyl group, pyrrolyl group, imidazolyl group, benzoimidazolyl group, pyrazolyl group, pyrazinyl group, triazolyl group (1,2,4-triazol-1-yl group, 1,2,3-triazol-1-yl group or the like), oxazolyl group, benzoxazolyl group, triazolyl group, isooxazolyl group, isothiazolyl group, furazanyl group, thienyl group, quinolyl group, benzofuryl group, dibenzofuryl group, benzothienyl group, dibenzothienyl group, indolyl group, carbazolyl group, carbolinyl group, diazacarbazolyl group (a carbolinyl group in which one of the carbon atoms constituting the carboline ring is replaced with a nitrogen atom), quinoxalinyl group, pyridazinyl group, triazinyl group, quinazolinyl group and phthalazinyl group); heterocyclic groups (such as a pyrrolidyl group, imidazolidyl group, morpholyl group and an oxazolidyl group); alkoxy groups (such as a methoxy group, ethoxy group, propyloxy group, pentyloxy group, hexyloxy group, octyloxy group and dodecyloxy group); cycloalkoxy groups (such as a cyclopentyloxy group and cyclohexyloxy group); aryloxy groups (such as a phenoxy group and naphthyloxy group); alkylthio groups (such as a methylthio group, ethylthio group, propylthio group, pentylthio group, hexylthio group, octylthio group and dodecylthio group); cycloalkylthio groups (such as a cyclopentylthio group and cyclohexylthio group); arylthio groups (such as a phenylthio group and naphthylthio group); alkoxycarbonyl groups (such as a methyloxycarbonyl group, ethyloxycarbonyl group, butyloxycarbonyl group, octyloxycarbonyl group and dodecyloxycarbonyl group); aryloxycarbonyl groups (such as a phenyloxycarbonyl group and naphthyloxycarbonyl group); sulfamoyl groups (such as an aminosulfonyl group, methylaminosulfonyl group, dimethylaminosulfonyl group, butylaminosulfonyl group, hexylaminosulfonyl group, cyclohexylaminosulfonyl group, octylaminosulfonyl group, dodecylaminosulfonyl group, phenylaminosulfonyl group, naphthylaminosulfonyl group and 2-pyridylaminosulfonyl group); acyl groups (such as an acetyl group, ethylcarbonyl group, propylcarbonyl group, pentylcarbonyl group, cyclohexylcarbonyl group, octylcarbonyl group, 2-ethylhexylcarbonyl group, dodecylcarbonyl group, phenylcarbonyl group, naphthylcarbonyl group and pyridylcarbonyl group); acyloxy groups (such as an acetyloxy group, ethylcarbonyloxy group, butylcarbonyloxy group, octylcarbonyloxy group, dodecylcarbonyloxy group and phenylcarbonyloxy group); amido groups (such as a methylcarbonylamino group, ethylcarbonylamino group, dimethylcarbonylamino group, propylcarbonylamino group, pentylcarbonylamino group, cyclohexylcarbonylamino group, 2-ethylhexylcarbonylamino group, octylcarbonylamino group, dodecylcarbonylamino group, phenylcarbonylamino group and naphthylcarbonylamino group); carbamoyl groups (such as an aminocarbonyl group, methylaminocarbonyl group, dimethylaminocarbonyl group, propylaminocarbonyl group, pentylaminocarbonyl group, cyclohexylaminocarbonyl group, octylaminocarbonyl group, 2-ethylhexylaminocarbonyl group, dodecylaminocarbonyl group, phenylaminocarbonyl group, naphthylaminocarbonyl group and a 2-pyridylaminocarbonyl group); ureido groups (such as a methylureido group, ethylureido group, pentylureido group, cyclohexylureido group, octylureido group, dodecylureido group, phenylureido group, naphthylureido group and 2-pyridylaminoureido group); sulfinyl groups (such as a methylsulfinyl group, ethylsulfinyl group, butylsulfinyl group, cyclohexylsulfinyl group, 2-ethylhexylsulfinyl group, dodecylsulfinyl group, phenylsulfinyl group, naphthylsulfinyl group and 2-pyridylsulfinyl group); alkylsulfonyl groups (such as a methylsulfonyl group, ethylsulfonyl group, butylsulfonyl group, cyclohexylsulfonyl group, 2-ethylhexylsulfonyl group and dodecyl sulfonyl group); arylsulfonyl and heteroarylsulfonyl groups (such as a phenylsulfonyl group, naphthylsulfonyl group and 2-pyridylsulfonyl group); amino groups (such as an amino group, ethylamino group, dimethylamino group, butylamino group, cyclopentylamino group, 2-ethylhexylamino group, dodecylamino group, anilino group, naphthylamino group and 2-pyridylamino group); halogen atoms (such as a fluorine atom, chlorine atom and bromine atom); fluorinated hydrocarbon groups (such as a fluoromethyl group, trifluoromethyl group, pentafluoroethyl group and pentafluorophenyl group); a cyano group; a nitro group; a hydroxy group; a mercapto group; silyl groups (such as a trimethylsilyl group, triisopropylsilyl group, triphenylsilyl group and phenyldiethylsilyl group); and a phosphono group.

These substituents may be further substituted with the substituent(s) mentioned above. These substituents may combine with each other to form a ring.

In General Formula (1), the aromatic hydrocarbon ring and the aromatic heterocycle formed in A2 are respectively correspond to the aromatic hydrocarbon ring and the aromatic heterocycle formed in A1 in General Formula (1).

In General Formula (1), examples of the bidentate ligand represented by P1-L1-P2 include substituted or unsubstituted phenylpyridine, phenylpyrazole, phenylimidazole, phenyltriazole, phenyltetrazole, pyrazabole, acetylacetone and picolinic acid.

In General Formula (1), M1 represents a transition metal element (also simply referred to as a transition metal) of Groups 8 to 10 on the periodic table and is preferably iridium or platinum, and more preferably iridium.

The light-emitting layer preferably contains a phosphorescence-emitting material represented by General Formula (2).

In General Formula (2), R and S each represents a carbon atom or a nitrogen atom; A3 represents an atomic group that forms an aromatic hydrocarbon ring or an aromatic heterocycle together with R—C; A4 represents an atomic group that forms an aromatic hydrocarbon ring or an aromatic heterocycle together with S—N; P3-L2-P4 represents a bidentate ligand; P3 and P4 each independently represent a carbon atom, a nitrogen atom, or an oxygen atom; L2 represents an atomic group that forms a bidentate ligand together with P3 and P4; r represents an integer of 1 to 3; represents an integer of 0 to 2, provided that r+s is 2 or 3; and M2 represents a metal element belonging to Groups 8 to 10 on the periodic table.

In General Formula (2), the aromatic hydrocarbon ring formed in A3 corresponds to the aromatic hydrocarbon ring formed in A1 in General Formula (1).

In General Formula (2), the aromatic heterocycle formed in A3 corresponds to the aromatic heterocycle formed in A1 in General Formula (1).

The substituent that may be possessed by the aromatic hydrocarbon ring or the aromatic heterocycle formed in A3 corresponds to the substituent that may be possessed by the aromatic hydrocarbon ring or the aromatic heterocycle formed in A1 in General Formula (1).

In General Formula (2), the aromatic hydrocarbon ring and the aromatic heterocycle formed in A4 are respectively correspond to the aromatic hydrocarbon ring and the aromatic heterocycle formed in A1 in General Formula (1).

In General Formula (2), the bidentate ligand represented by P3-L2-P4 corresponds to the bidentate ligand represented by P1-L1-P2 in General Formula (1).

In General Formula (2), M2 represents a transition metal element (also simply referred to as a transition metal) of Groups 8 to 10 on the periodic table and is preferably iridium or platinum, and more preferably iridium.

Specific examples of the compound used as the organic metal complex (phosphorescence-emitting compound) represented by General Formula (1) or General Formula (2) are shown below, but the present invention is not limited thereto. These compounds can be synthesized by, for example, the method described in Inorg. Chem., vol. 40, 1704-1711.

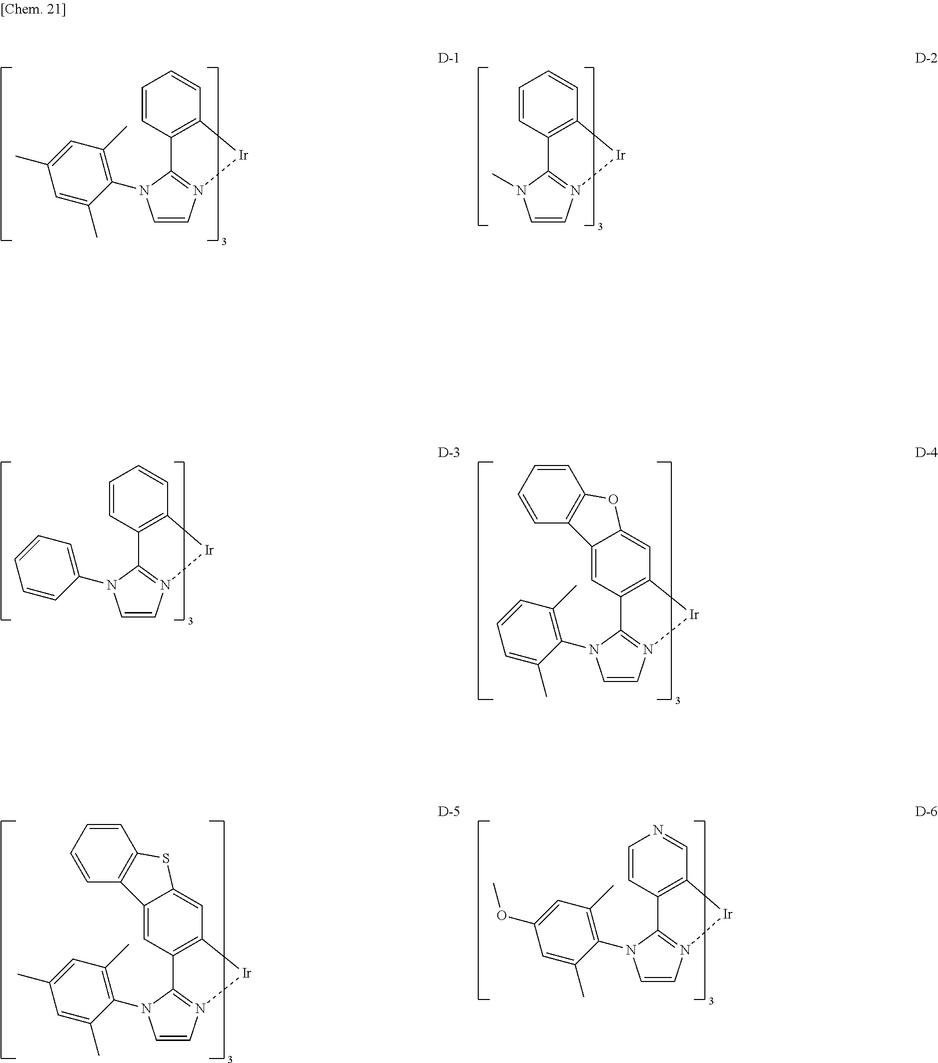

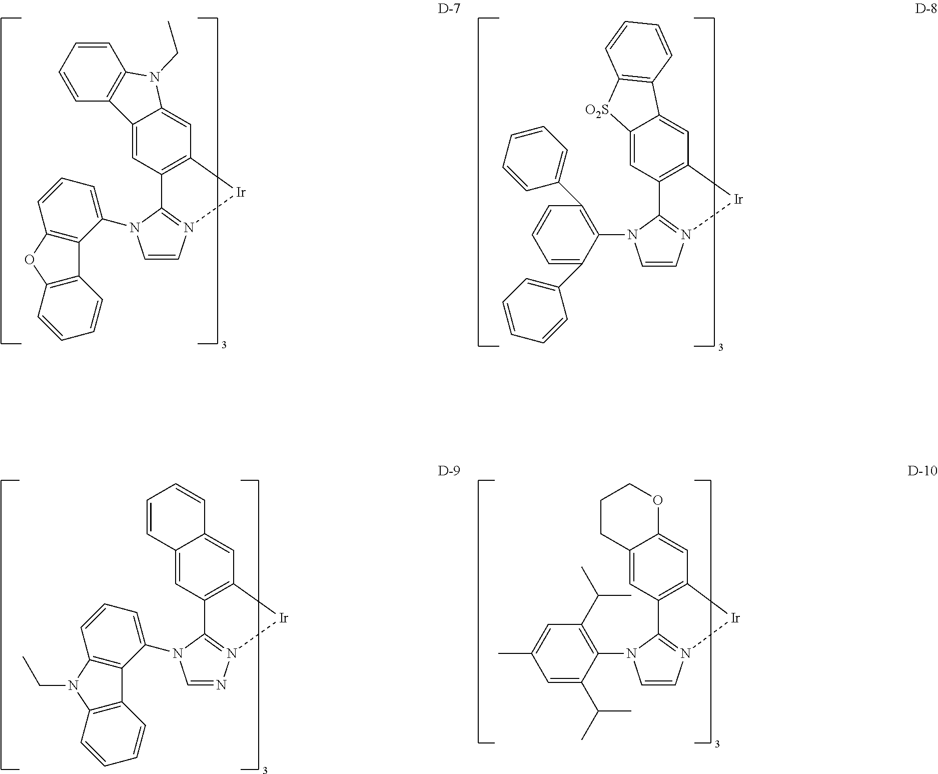

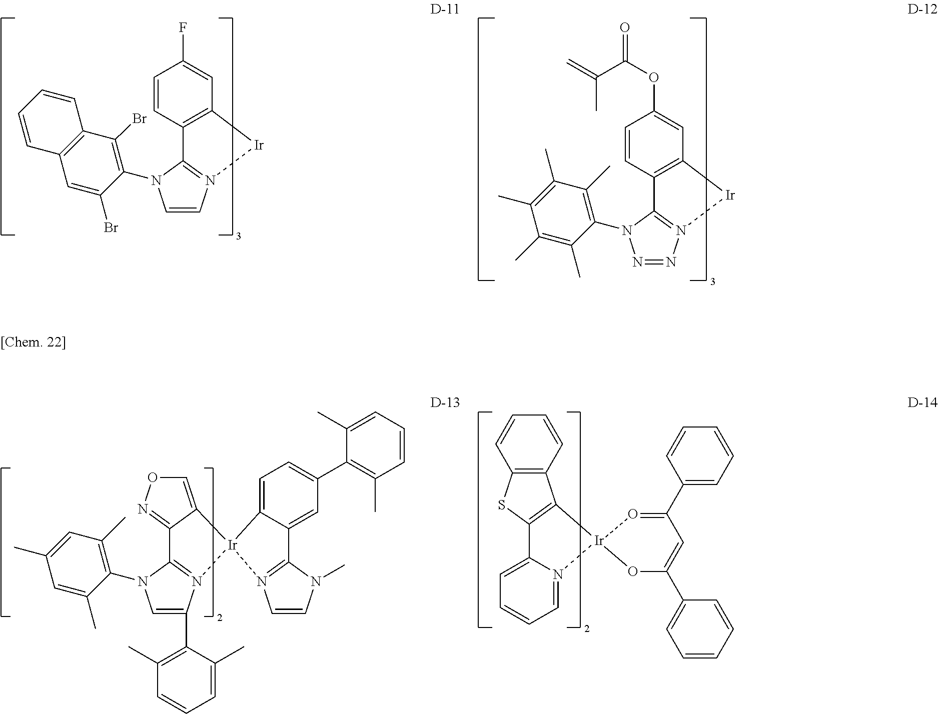

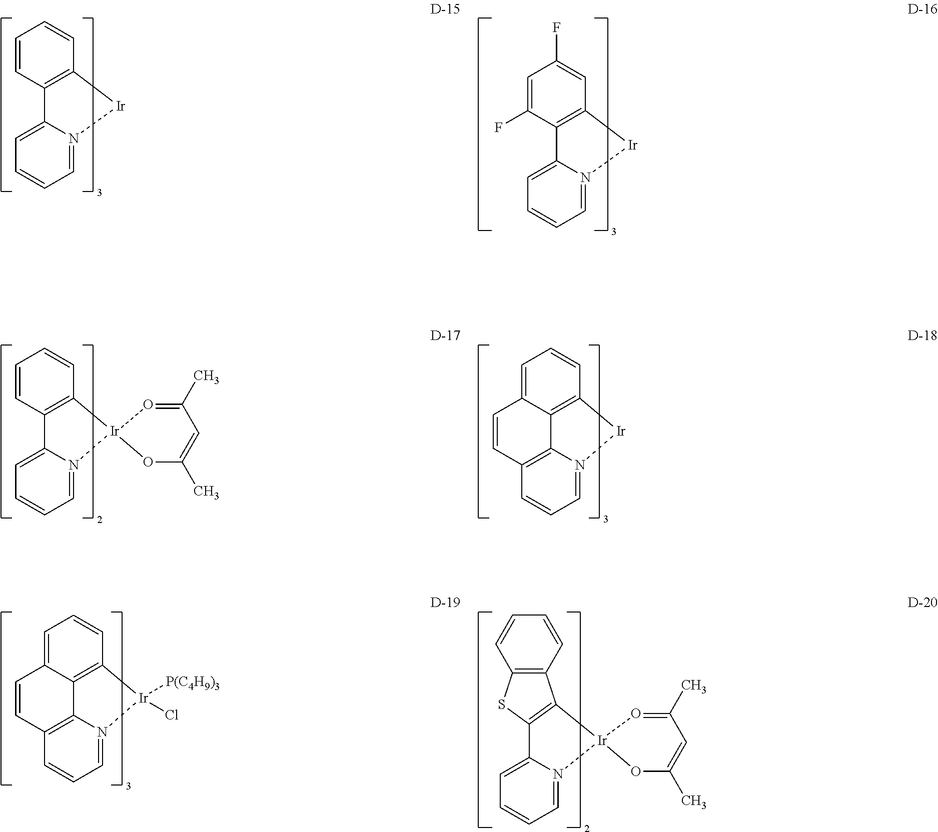

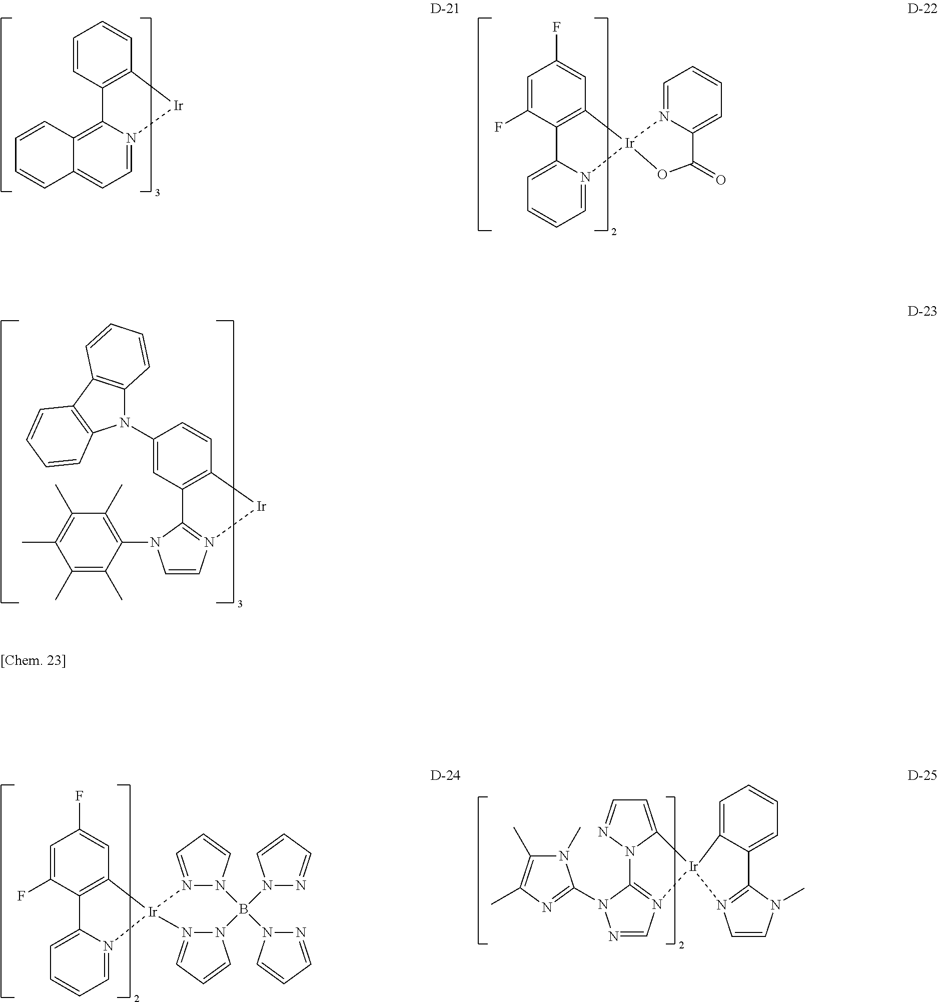

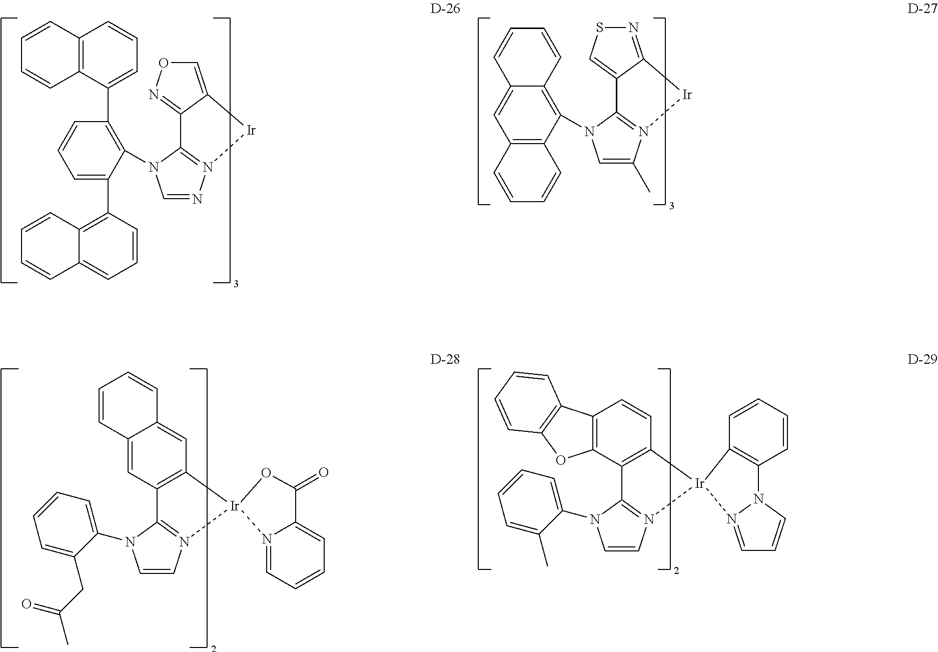

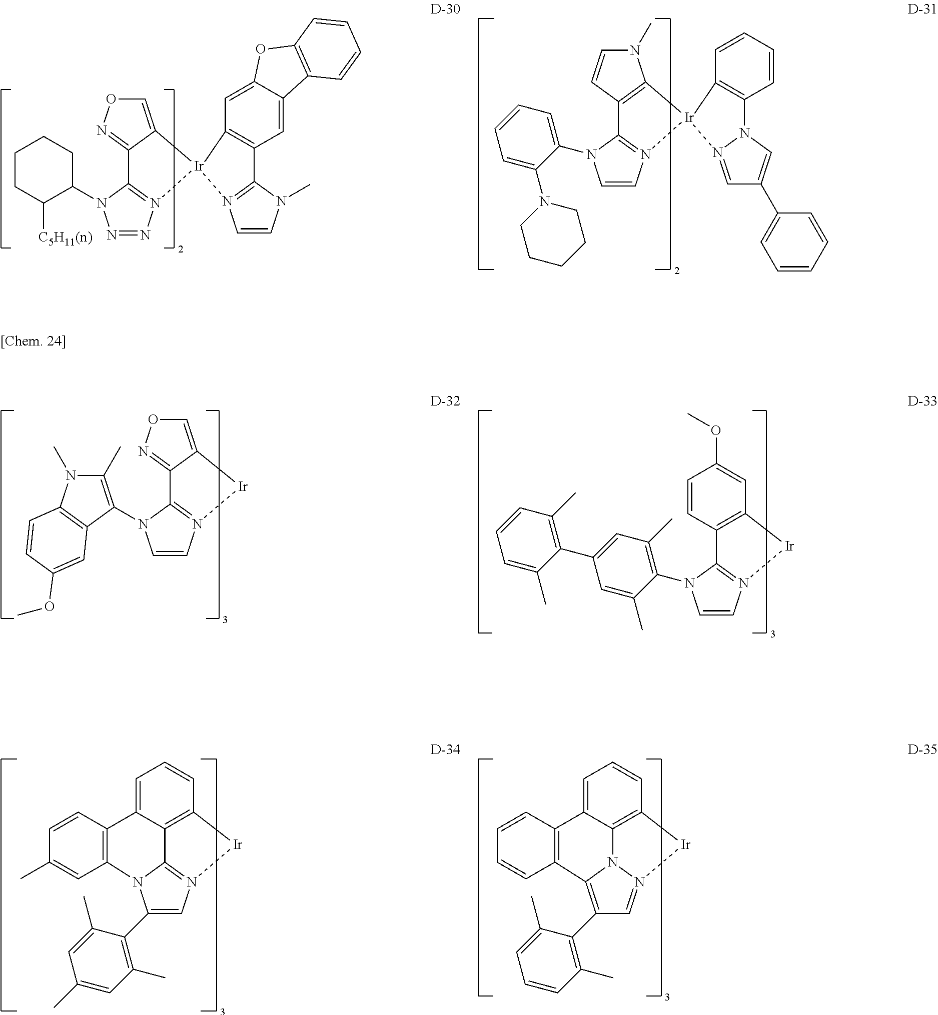

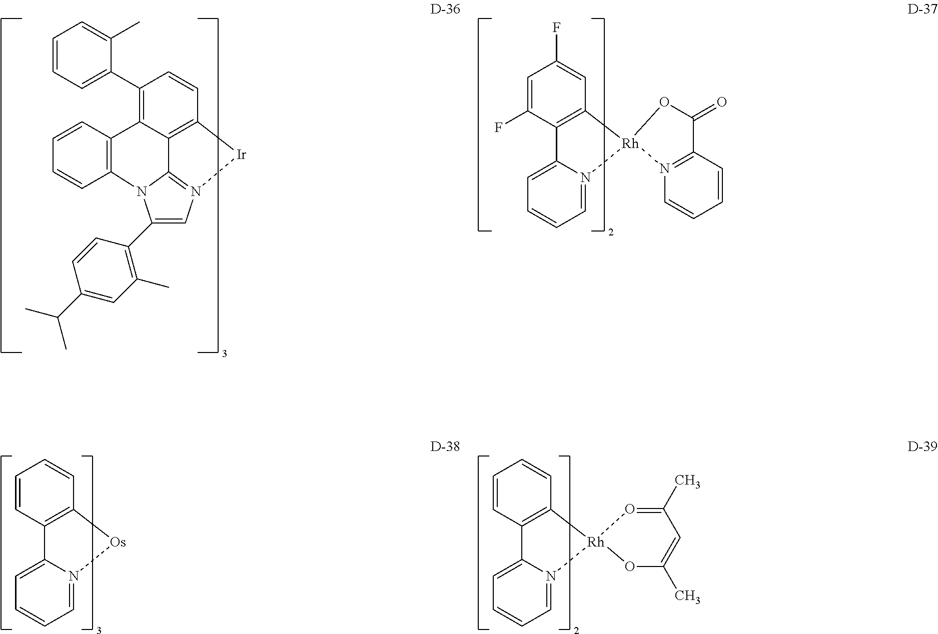

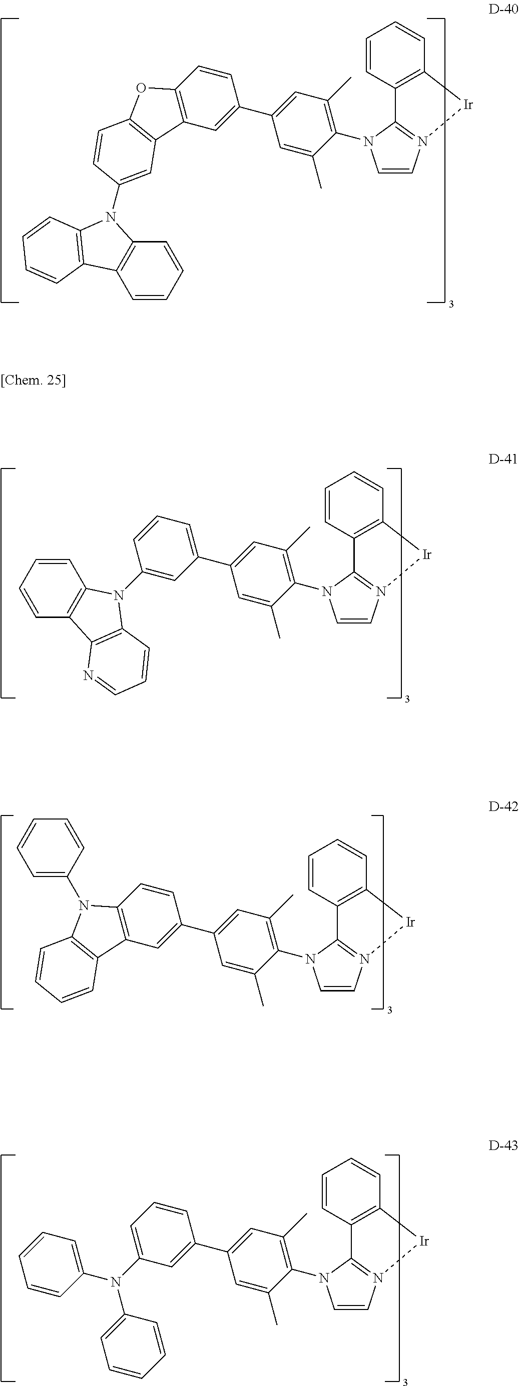

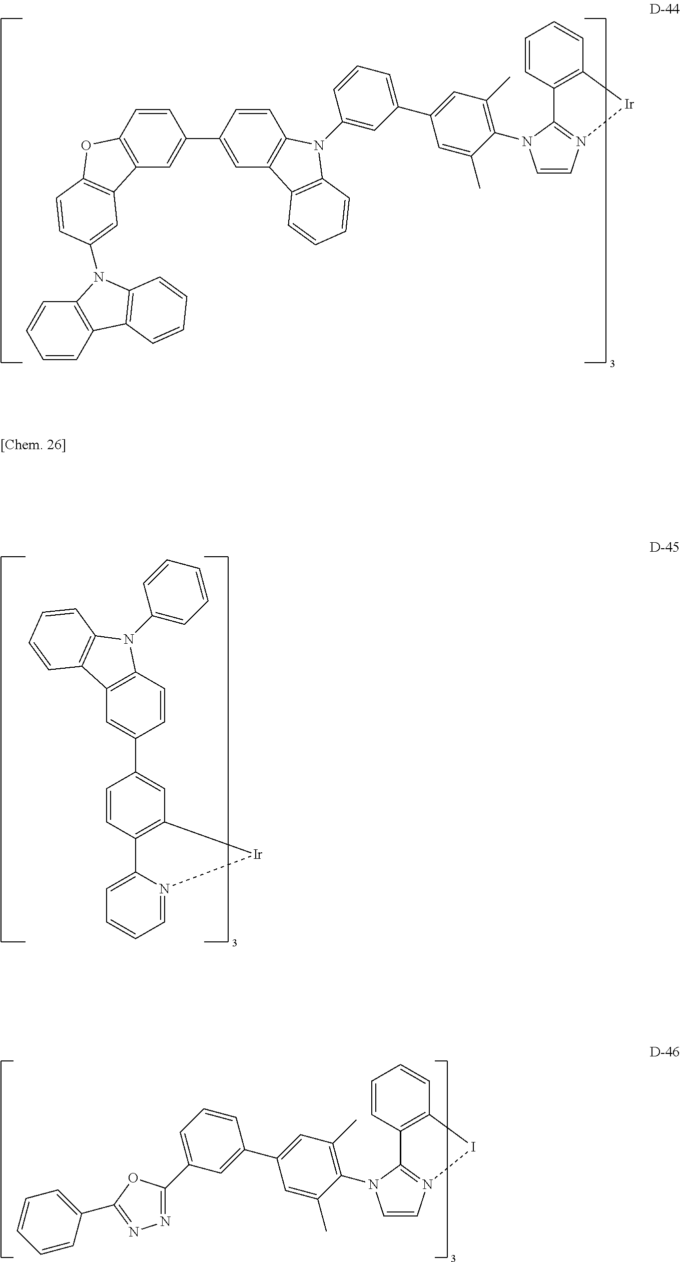

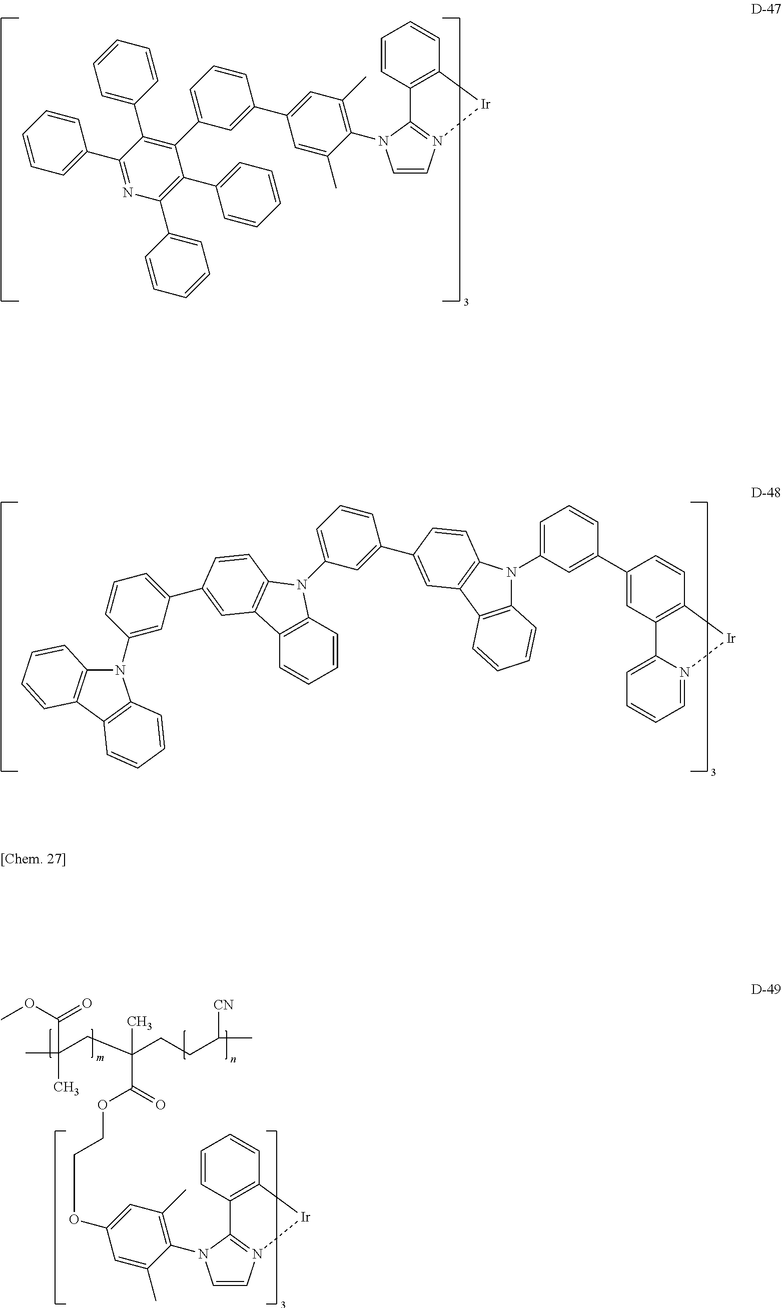

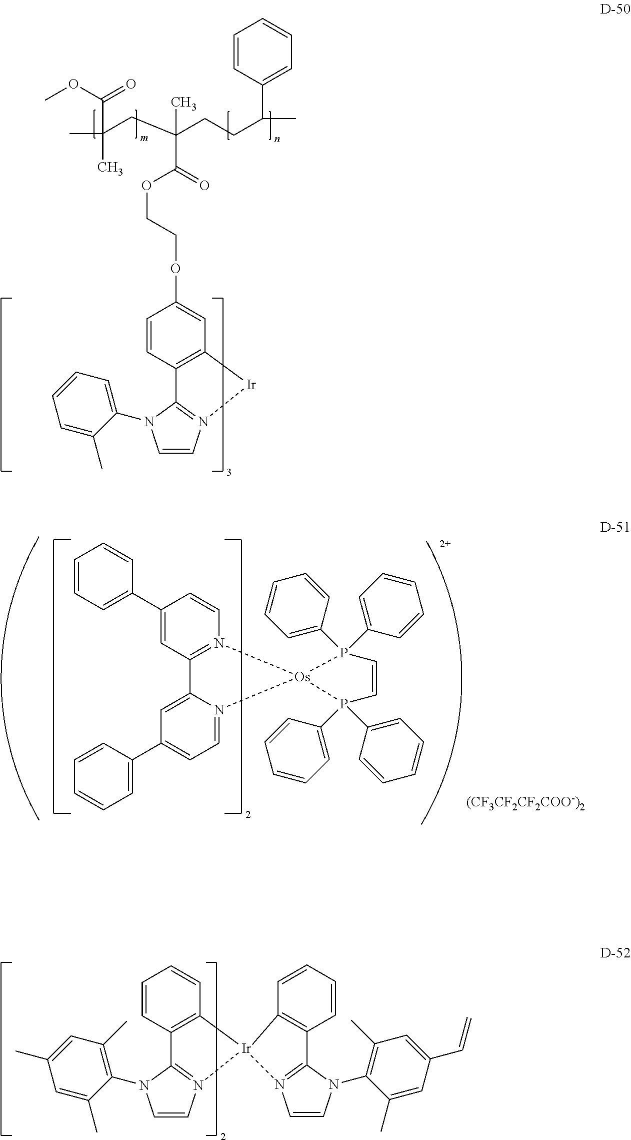

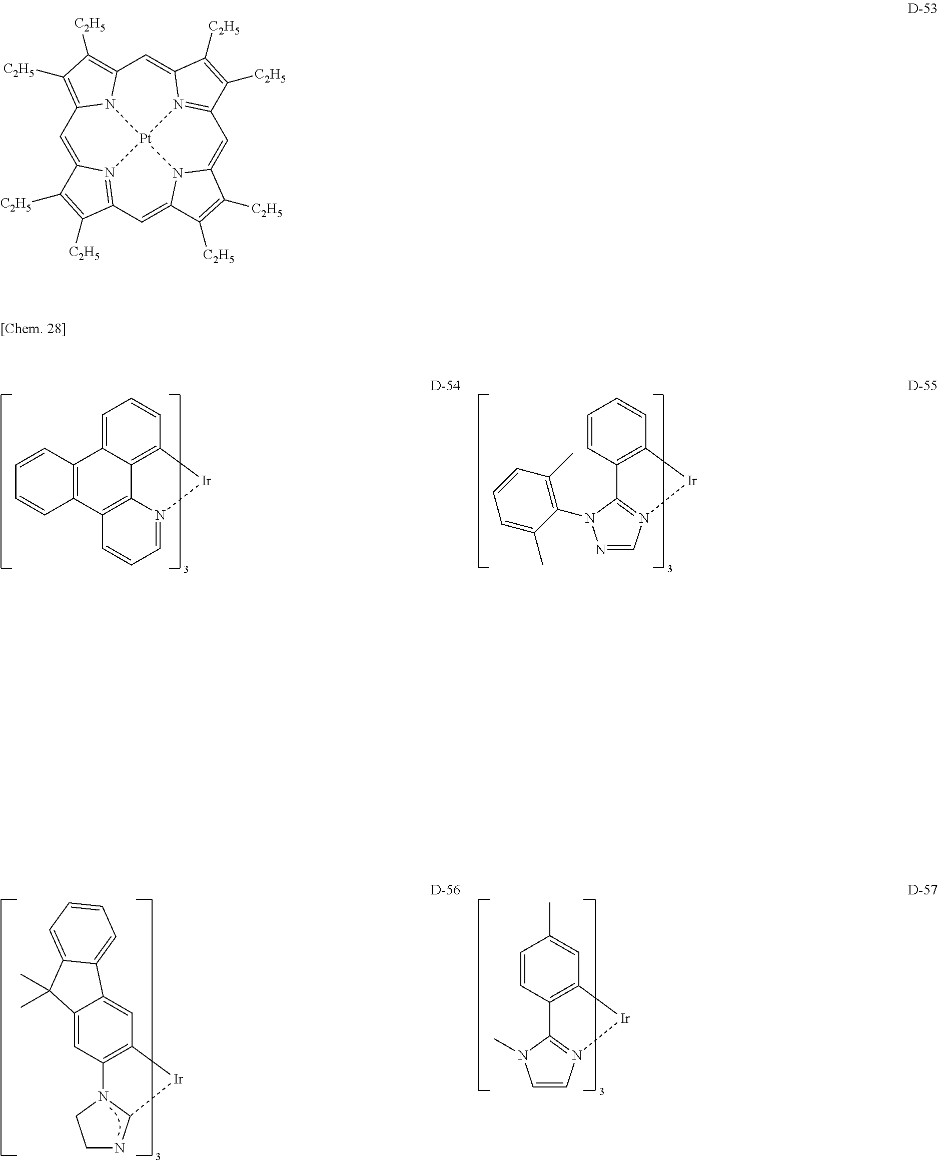

The organic metal complex represented by General Formula (1) contained in the charge-generating layer may be a non-phosphorescence emitting organic metal complex that does not emit phosphorescence, and examples thereof include the following compounds:

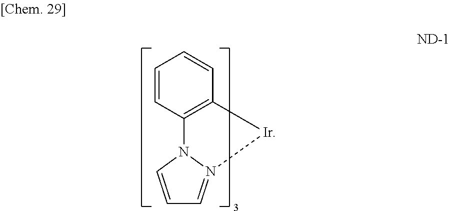

(Fluorescent Dopant (Also Referred to as Fluorescent Compound))

Examples of the fluorescent dopant (fluorescent compound) include coumarin dyes, pyran dyes, cyanine dyes, chloconium dyes, squarylium dyes, oxobenzanthracene dyes, fluorescein dyes, rhodamine dyes, pyrylium dyes, perylene dyes, stilbene dyes, polythiophene dyes and rare earth fluorescent complexes.

The injecting layers, blocking layers, electron-transporting layers and other layers used as constituent layers of the organic EL element of the present invention will now be described.

<<Injecting Layer: Electron-Injecting Layer, Electron Hole-Injecting Layer>>

The injecting layers, i.e., an electron-injecting layer and electron hole-injecting layer, may be disposed between the anode and the light-emitting layer or the electron hole-transporting layer and between the cathode and the light-emitting layer or the electron-transporting layer, as described above.

The injecting layer is provided between the electrode and an organic layer in order to reduce the driving voltage and to improve the luminance and is described in detail in “Electrode material”, Div. 2 Chapter 2 (pp. 123-166) of “Organic EL element and its frontier of industrialization” (published by NTS Corporation, Nov. 30, 1998). The injecting layers are classified into an electron hole-injecting layer (anode buffer layer) and an electron-injecting layer (cathode buffer layer).

The anode buffer layer (electron hole-injecting layer) is also described in detail in Japanese Patent Laid-Open Application Publications Nos. Hei9-45479, Hei9-260062 and Hei8-288069, for example, and specific examples thereof include phthalocyanine buffer layers as typified by a copper phthalocyanine layer, oxide buffer layers as typified by a vanadium oxide layer, amorphous carbon buffer layers, and polymer buffer layers employing electroconductive polymers such as polyaniline (emeraldine) or polythiophene.

The cathode buffer layer (electron-injecting layer) is also described in detail in Japanese Patent Laid-Open Application Publications Nos. Hei6-325871, Hei9-17574 and Hei10-74586, for example, and specific examples thereof include metal buffer layers as typified by a strontium or aluminum layer, alkali metal compound buffer layers as typified by a lithium fluoride layer, alkali earth metal compound buffer layers as typified by a magnesium fluoride layer and oxide buffer layers as typified by an aluminum oxide. The buffer layer (injecting layer) is desirably a very thin layer and preferably has a thickness in a range of 0.1 to 10 nm depending on the material.

<<Blocking Layer: Electron Hole-Blocking Layer, Electron-Blocking Layer>>

The blocking layer is provided in addition to fundamental constituent layers of the organic compound thin film as described above as needed. Examples of the blocking layer include electron hole-blocking layers described in Japanese Patent Laid-Open Application Publications Nos. Hei11-204258 and Hei11-204359 and on page 237 of “Organic EL element and its frontier of industrialization” (published by NTS Corporation, Nov. 30, 1998), for example.

The electron hole-blocking layer functions as an electron-transporting layer in a broad sense and is composed of a material having electron-transporting property but extremely poor electron hole-transporting property. The electron hole-blocking layer can increase the probability of recombination of electrons and electron holes by transporting electrons and blocking electron holes.

The configuration of an electron-transporting layer described below can be applied to the electron hole-blocking layer according to the present invention as needed.

The electron hole-blocking layer of the organic EL element of the present invention preferably adjoins the light-emitting layer.

In the present invention, when a plurality of light-emitting layers that emit light of different colors are provided, a light-emitting layer emitting light whose maximum emission wavelength is the shortest in all of the light-emitting layers is preferably disposed so as to be the closest to the anode. In such a case, an additional electron hole-blocking layer is preferably disposed between the light-emitting layer emitting light whose maximum emission wavelength is the shortest and a light-emitting layer that is the next closest to the anode.

Furthermore, at least 50% by mass of the compounds contained in the electron hole-blocking layer disposed at the position described above preferably has an ionization potential of 0.3 eV or more higher than that of the host compound contained in the light-emitting layer emitting light whose maximum emission wavelength is the shortest.

The ionization potential is defined as energy necessary for releasing an electron in the highest occupied molecular orbital (HOMO) level of a compound to the vacuum level and can be determined by

(1) the molecular orbital calculation, as described above, or

(2) direct photoelectron spectroscopic measurement; for example, a low-energy electron spectrometer “Model AC-1”, manufactured by Riken Keiki Co., Ltd. or a method known as ultraviolet photoelectron spectroscopy can be suitably employed.

On the other hand, the electron-blocking layer functions as an electron hole-transporting layer in a broad sense and is composed of a material having electron hole-transporting property but extremely poor electron-transporting property. The electron-blocking layer can increase the probability of recombination of electrons and electron holes by transporting electron holes and blocking electrons.

The configuration of an electron hole-transporting layer described below can be applied to the electron-blocking layer as needed. The electron hole-blocking layer and the electron-transporting layer according to the present invention each preferably has a thickness of 3 to 100 nm, and more preferably 5 to 30 nm.

<<Electron Hole-Transporting Layer>>

The electron hole-transporting layer is composed of an electron hole-transporting material having electron hole-transporting property. The electron hole-injecting layer and the electron-blocking layer are also included in the electron hole-transporting layer in a broad sense. One or more of the electron hole-transporting layers may be provided.

The electron hole-transporting material has electron hole-injecting or transporting property or electron-blocking property and may be either an organic material or inorganic material. Examples of the electron hole-transporting material include triazole derivatives, oxadiazole derivatives, imidazole derivatives, polyarylalkane derivatives, pyrazoline derivatives, pyrazolone derivatives, phenylenediamine derivatives, arylamine derivatives, amino substituted chalcone derivatives, oxazole derivatives, styryl anthracene derivatives, fluorenone derivatives, hydrazone derivatives, stilbene derivatives, silazane derivatives, aniline copolymers and electroconductive polymer oligomers, and particularly thiophene oligomers and the like.

As the electron hole-transporting material, those described above can be used, but preferred are porphyrin compounds, aromatic tertiary amine compounds, and styrylamine compounds. In particular, aromatic tertiary amine compounds are preferably used.

Typical examples of the aromatic tertiary amine compound and the styrylamine compound include N,N,N′,N′-tetraphenyl-4,4′-diaminophenyl; N,N′-diphenyl-N,N′-bis(3-methylphenyl)-(1,1′-biphenyl)-4,4′-diamine (TPD); 2,2-bis(4-di-p-tolylaminophenyl)propane; 1,1-bis(4-di-p-tolylaminophenyl)cyclohexane; N,N,N′,N′-tetra-p-tolyl-4,4′-diaminobiphenyl; 1,1-bis(4-di-p-tolylaminophenyl)-4-phenylcyclohexane; bis(4-dimethylamino-2-methylphenyl)phenylmethane; bis(4-di-p-tolylaminophenyl)phenylmethane; N,N′-diphenyl-N,N′-di(4-methoxyphenyl)-4,4′-diaminobiphenyl; N,N,N′,N′-tetraphenyl-4,4′-diaminodiphenyl ether; 4,4′-bis(diphenylamino)quaterphenyl; N,N,N-tri(p-tolyl)amine, 4-(di-p-tolylamino)-4′-[4-(di-p-tolylamino)styryl]stilbene; 4-N,N-diphenylamino-(2-diphenylvinyl)benzene; 3-methoxy-4′-N,N-diphenylaminostylbenzene; N-phenylcarbazole; compounds having two condensed aromatic rings in the molecule described in U.S. Pat. No. 5,061,569, such as 4,4′-bis[N-(1-naphthyl)-N-phenylamino]biphenyl (NPD), and a compound described in Japanese Patent Laid-Open No. Hei4-308688, 4,4′,4″-tris[N-(3-methylphenyl)-N-phenylamino]triphenylamine (MTDATA) in which three triphenylamine units are bonded in a starburst form.

Polymer materials including the above-mentioned compounds introduced into their polymer chains or polymer materials including the above-mentioned compounds as their main chains can also be used. Inorganic compounds such as p-type Si and p-type SiC can also be used as the electron hole-injecting material or the electron hole-transporting material.

So-called p-type electron hole-transporting materials as described in Japanese Patent Laid-Open Application Publication No. Hei11-251067 or in J. Huang, et al., (Applied Physics Letters, 80 (2002), p. 139) can also be used.

The electron hole-transporting layer can be formed by preparing a thin layer with the electron hole-transporting material by a known method such as vacuum deposition, spin coating, casting, printing including ink jetting or LB method. In the present invention, the electron hole-transporting layer is preferably formed by application (wet process). The thickness of the electron hole-transporting layer may have any value and is usually about 5 nm to 5 μm, and preferably 5 to 200 nm. The electron hole-transporting layer may have a monolayer structure composed of one or more of the materials mentioned above.

An electron hole-transporting layer having high p-type properties doped with impurity(ies) can be used. Examples thereof include those described in, for example, Japanese Patent Laid-Open Application Publications Nos. Hei4-297076, 2000-196140 and 2001-102175, and J. Appl. Phys., 95, 5773 (2004).

In the present invention, the use of such electron hole-transporting layer having a high p-type property is preferred for producing an element with lower power consumption.

<<Electron-Transporting Layer>>

The electron-transporting layer is composed of a material having an electron-transporting function, and the electron-injecting layer and the electron hole-blocking layer are included in the electron-transporting layer in a broad sense. One or more of the electron-transporting layers may be provided.

Conventionally, an electron-transporting material (also serving as an electron hole-blocking material) contained in the electron-transporting layer when one electron-transporting layer is provided or contained in the electron-transporting layer adjoining the light-emitting layer on the cathode side when multiple electron-transporting layers are provided may be any material having a function for transporting electrons injected from a cathode to a light-emitting layer and may be appropriately selected from known compounds.

Examples of the electron-transporting material include nitro-substituted fluorene derivatives, diphenylquinone derivatives, thiopyran dioxide derivatives, carbodiimides, fluolenylidenemethane derivatives, anthraquinodimethane and anthrone derivatives, and oxadiazole derivatives.

Furthermore, thiadiazole derivatives in which oxygen atoms of the oxadiazole rings of the oxadiazole derivatives mentioned above are replaced with sulfur atoms and quinoxaline derivatives having quinoxaline rings known as electron-extracting groups may be used as the electron-transporting materials. Polymer materials including these compounds introduced into their polymer chains or polymer materials including the compounds as their main chains may be used.

Usable examples of the electron-transporting material include metal complexes of 8-quinolinol derivatives such as aluminum tris(8-quinolinol) (Alq), aluminum tris(5,7-dichloro-8-quinolinol), aluminum tris(5,7-dibromo-8-quinolinol), aluminum tris(2-methyl-8-quinolinol), aluminum tris(5-methyl-8-quinolinol), and zinc bis(8-quinolinol) (Znq) and metal complexes in which the central metals of the metal complexes mentioned above are replaced with In, Mg, Cu, Ca, Sn, Ga or Pb.

In addition, a metal-free or metal-containing phthalocyanine and its derivative having an end substituted with, for example, an alkyl group or a sulfonic acid group are also preferably used as the electron-transporting materials. The distyrylpyrazine derivatives exemplified as materials for the light-emitting layer can be preferably used as the electron-transporting material. An inorganic semiconductor such as n-type Si and n-type SiC may also be used as the electron-transporting material as in the electron hole-injecting layer or the electron hole-transporting layer. The electron-transporting layer may be formed by preparing a thin film with the above-mentioned electron-transporting material by a known method such as vacuum deposition, spin coating, casting, printing including ink jetting or LB method.

The thickness of the electron-transporting layer may have any value without particular limitation and is usually about 5 nm to 5 μm, and preferably 5 to 200 nm. The electron-transporting layer may have a monolayer structure composed of one or more of the materials mentioned above.

An electron-transporting layer having high n-type properties doped with impurity(ies) can be used. Examples thereof include those described in, for example, Japanese Patent Laid-Open Application Publications Nos. Hei4-297076, Hei10-270172, 2000-196140 and 2001-102175, and J. Appl. Phys., 95, 5773 (2004).

In the present invention, the use of such electron-transporting layer having a high n-type property is preferred for producing an element with lower power consumption.

<<Anode>>

The electrode material of the anode of the organic EL element is preferably a metal, alloy, or electroconductive compound having a high work function (4 eV or more) or a mixture thereof.

Specific examples of the electrode material include metals such as Au and transparent electroconductive materials such as CuI, indium tin oxide (ITO), SnO₂ and ZnO.

A material that is amorphous and capable of forming a transparent electroconductive layer such as IDIXO (In₂O₃—ZnO) may be used. The anode may be produced by forming a thin film with the electrode material by a method such as deposition or sputtering and then patterning the film into a desired shape by photolithography. If required precision of the pattern is not so high (about 100 μm), the pattern may be formed by depositing or sputtering the electrode material through a mask having a desired shape. Alternatively, if an appliable material such as an organic electroconductive compound is used, a wet film forming method such as printing or coating can also be used.

For extracting emitted light from the anode, the transmittance of the anode is desirably 10% or more, and the sheet resistance of the anode is preferably several hundred Ω/□ or less. The thickness of the layer is usually in a range of 10 to 1000 nm, and preferably 10 to 200 nm, while depending on the material.

<<Cathode>>

On the contrary, an electrode material of the cathode is preferably a metal having a low work function (4 eV or less) (referred to as an electron-injecting metal), alloy or electroconductive compound having a low work function (4 eV or less) or a mixture thereof. Specific examples of the electrode material include sodium, sodium-potassium alloys, magnesium, lithium, magnesium/copper mixtures, magnesium/silver mixtures, magnesium/aluminum mixtures, magnesium/indium mixtures, aluminum/aluminum oxide (Al₂O₃) mixtures, indium, lithium/aluminum mixtures and rare-earth metals.

Among them, mixtures of an electron-injecting metal and a second metal having a work function higher than that of the electron-injecting metal and being stable, such as magnesium/silver mixtures, magnesium/aluminum mixtures, magnesium/indium mixtures, aluminum/aluminum oxide (Al₂O₃) mixtures, lithium/aluminum mixtures, and aluminum are preferred from the view point of the electron-injecting property and resistance to oxidation. The cathode can be produced by forming a thin film with the electrode material by a method such as deposition or sputtering.

The cathode preferably has a sheet resistance of several hundred Ω/□ or less and a thickness in a range of usually 10 nm to 5 μm, and preferably 50 to 200 nm. If either the anode or the cathode of the organic EL element is transparent or translucent, the luminance is advantageously increased.

A transparent or translucent cathode can be produced by forming a layer having a thickness of 1 to 20 nm from the metal mentioned above and then providing a layer of an electroconductive transparent material exemplified in the description of the anode on the metal layer. Application of this process can produce an element having a transparent anode and transparent cathode.

<<Supporting Substrate>>

The supporting substrate (also referred to as the base body, substrate, base or support) that can be used for the organic EL element of the present invention may be composed of any material such as glass or plastic and may be transparent or opaque. In the case of extracting light from the supporting substrate side, the supporting substrate is preferably transparent.

Examples of the supporting substrate preferably used include glass, quartz, and transparent resin films. A particularly preferred supporting substrate is a resin film capable of imparting flexibility to the organic EL element.

Examples of the resin film include films of polyesters such as polyethylene terephthalate (PET) and polyethylene naphthalate (PEN), polyethylene, polypropylene, cellophane, cellulose esters and their derivatives such as cellulose diacetate, cellulose triacetate, cellulose acetate butylate, cellulose acetate propionate (CAP), cellulose acetate phthalate (TAC) and cellulose nitrate, polyvinylidene chloride, polyvinyl alcohol, polyethylene vinyl alcohol, syndiotactic polystyrene, polycarbonate, norbornene resins, polymethylpentene, polyether ketones, polyimides, polyether sulfone (PES), polyphenylene sulfide, polysulfones, polyether imide, polyether ketone imide, polyamides, fluorine resins, nylon, polymethyl methacrylate, acrylics and polyarylates, and cycloolefin resins such as ARTON (trade name, manufactured by JSR Corp.) and APEL (trade name, manufactured by Mitsui Chemicals Inc.).

On the surface of the resin film, an inorganic or organic coating film or a hybrid coating film composed of the both may be formed. The coating film is preferably a barrier film having a vapor permeability of 0.01 g/(m²·24 h) or less (at 25±0.5° C. and 90±2% relative humidity (RH)) measured by a method in accordance with JIS K 7129-1992, and more preferably a high barrier film having an oxygen permeability of 10³ cm³/(m²·24 h·MPa) or less and a vapor permeability of 10⁻⁵ g/(m²·24 h) or less measured by a method in accordance with JIS K 7126-1987.

The barrier film may be formed with any material that can prevent penetration of substances such as moisture and oxygen causing degradation of the element, and usable examples of the material include silicon oxide, silicon dioxide and silicon nitride. In order to reduce the fragility of the film, a barrier film having a laminate structure composed of an inorganic layer and an organic material layer is preferred.

The inorganic layer and the organic material layer may be laminated in any order, and it is preferable that the both layers are alternately laminated multiple times.

The barrier film may be formed by any method without particular limitation. For example, vacuum deposition, sputtering, reactive sputtering, molecular beam epitaxy, ionized-cluster beam deposition, ion plating, plasma polymerization, atmospheric pressure plasma polymerization, plasma CVD, laser CVD, thermal CVD, or coating may be used, and atmospheric pressure plasma polymerization as described in Japanese Patent Laid-Open Application Publication No. 2004-68143 is particularly preferred.

Examples of the opaque supporting substrate include metal plates such as aluminum and stainless steel plates; film or opaque resin substrates; and ceramic substrates.

The efficiency of light extraction of the organic EL element of the present invention at room temperature is preferably 1% or more, and more preferably 5% or more.

The quantum extraction efficiency (%) is defined as (the number of photons emitted to the exterior from the organic EL element)/(the number of electrons supplied to the organic EL element)×100.

A hue improving filter such as a color filter may be used in combination, or a color conversion filter that converts the color of light emitted by the organic EL element to many colors using a fluorescent compound may be used in combination. In the case of using the color conversion filter, the λmax of the light emitted by the organic EL element is preferably 480 nm or less.

<<Sealing>>

Examples of the sealing ways used in the present invention include a way of bonding a sealing member to the electrode and supporting substrate with an adhesive.

The sealing member is disposed so as to cover a display area of the organic EL element and may have a concave plate shape or a flat plate shape. The transparency and the electrical insulation properties thereof are not specifically restricted.

Specific examples of the sealing member include glass plates, polymer plates and films, and metal plates and films. Examples of the glass plate include soda-lime glass, barium/strontium-containing glass, lead glass, aluminosilicate glass, borosilicate glass, barium borosilicate glass and quartz plates. Examples of the polymer plate include polycarbonate plates, acryl resin plates, polyethylene terephthalate plates, polyether sulfide plates and polysulfone plates. Examples of the metal plate include metal and alloy plates of at least one selected from the group consisting of stainless steel, iron, copper, aluminum, magnesium, nickel, zinc, chromium, titanium, molybdenum, silicon, germanium, tantalum and alloys thereof.

In the present invention, a polymer film or a metal film is preferably used from the viewpoint of reducing the thickness of the element. The polymer film preferably has an oxygen permeability of 10⁻³ cm³/(m²·24 h·MPa) or less measured by a method in accordance with JIS K 7126-1987 and a vapor permeability of 1×10⁻³ g/(m²·24 h) or less (at 25±0.5° C. and 90±2% relative humidity (RH)) measured by a method in accordance with JIS K 7129-1992.

The sealing member is formed into a concave shape by, for example, sand blasting or chemical etching.

Specific examples of the adhesive include photo-curable or thermo-curable adhesives having reactive vinyl groups such as acrylic acid oligomers and methacrylic acid oligomers, and moisture curable adhesives such as 2-cyanoacrylate.

Examples of the adhesive include an epoxy type thermally or chemically curable adhesives (two liquid mixture) such as epoxy type adhesives; hot-melt type polyamide, polyester and polyolefin adhesives; and cation curing type UV curable epoxy resin adhesives.

Since the organic EL element may be degraded by heat treatment, an adhesive that is cured in a temperature from room temperature to 80° C. is preferably used. A drying agent may be dispersed in the adhesive. Application of the adhesive to the adhering portion may be performed with a commercially available dispenser or may be performed by printing such as screen printing.

It is also preferred that an inorganic or organic layer is formed as a sealing membrane on the outer side of the electrode placed on the side facing the supporting substrate and sandwiching the organic layer therebetween so as to cover the electrode and the organic layer and to be contact with the supporting substrate. In such a case, the sealing membrane may be formed with any material that can prevent penetration of substances such as water and oxygen causing degradation of the element. Usable examples of the material include silicon oxide, silicon dioxide and silicon nitride. In order to reduce the fragility of the membrane, a sealing membrane having a laminate structure composed of an inorganic layer and an organic material layer is preferred.

The above membrane may be formed by any method without particular limitation. For example, vacuum deposition, sputtering, reactive sputtering, molecular beam epitaxy, ionized-cluster beam deposition, ion plating, plasma polymerization, atmospheric pressure plasma polymerization, plasma CVD, laser CVD, thermal CVD or coating may be employed.

In the space between the sealing member and the display area of the organic EL element, it is preferable that inactive gas such as nitrogen or argon or an inactive liquid such as fluorinated hydrocarbon or silicone oil is injected as a gas or liquid phase. The space can be a vacuum state. Alternatively, a hygroscopic compound may be enclosed inside.

Examples of the hygroscopic compound include metal oxides (such as sodium oxide, potassium oxide, calcium oxide, barium oxide, magnesium oxide and aluminum oxide), sulfates (such as sodium sulfate, calcium sulfate, magnesium sulfate and cobalt sulfate), metal halides (such as calcium chloride, magnesium chloride, cesium fluoride, tantalum fluoride, cerium bromide, magnesium bromide, barium iodide and magnesium iodide) and perchloric acids (such as barium perchlorate and magnesium perchlorate). As for the sulfates, metal halides and perchlorates, anhydrides thereof are preferably used.

<<Protective Film, Protective Plate>>

In order to increase mechanical strength of the element, a protective film or protective plate may be provided on the outer surface of the sealing membrane on the side facing the supporting substrate and sandwiching the organic layer therebetween or on the outer surface of the sealing film.

In particular, in the case of achieving sealing with the sealing membrane, since the mechanical strength of the membrane is not sufficiently high, such a protective film or plate is preferably provided. Usable examples of the material for the protective film or plate include the glass plates, polymer plates and films, and metal plates and films exemplified as the materials for sealing. The polymer film is preferably used from the viewpoint of reducing the weight and the thickness.

<<Light Extraction>>

It is generally said that in an organic EL element, light is emitted in a layer whose refractive index (refractive index: about 1.7 to 2.1) is higher than that of air, and only about 15 to 20% of the light emitted in the light-emitting layer can be extracted.

This is because incident light on an interface (interface between a transparent substrate and the air) at an angle θ larger than a critical angle is totally reflected and cannot be extracted from the element or because light is totally reflected at the interface between the transparent electrode or light-emitting layer and the transparent substrate and is guided to the transparent electrode or the light-emitting layer to release the light to the direction of the element side face.

Examples of the method for improving the efficiency of light extraction include a method for preventing total reflection at the interface between the transparent substrate and the air by forming asperities on the surface of the transparent substrate (U.S. Pat. No. 4,774,435); a method for improving the efficiency by providing light-condensing property to the substrate (Japanese Patent Laid-Open Application Publication No. Sho63-314795); a method for forming a reflection surface on the side faces of the element (Japanese Patent Laid-Open Application Publication No. Hei1-220394); a method for providing an anti-reflection layer by disposing a smoothing layer between the substrate and the light-emitting material, the smoothing layer having a refractive index level between those of the substrate and the light-emitting material (Japanese Patent Laid-Open Application Publication No. Sho62-172691); a method for disposing a smoothing layer between the substrate and the light-emitting body, the smoothing layer having a refractive index lower than that of the substrate (Japanese Patent Laid-Open Application Publication No. 2001-202827); and a method for providing a diffraction grating between any layers of the substrate, the transparent electrode layer, and the light-emitting layer (including on the substrate surface facing the exterior) (Japanese Patent Laid-Open Application Publication No. Hei11-283751).

In the present invention, these methods can also be used for the organic EL element of the present invention. In particular, the method for disposing a smoothing layer between the substrate and the light-emitting material, the smoothing layer having a refractive index lower than that of the substrate or the method for forming a diffraction grating between any layers of the substrate, the transparent electrode layer, and the light-emitting layer (including on the substrate surface facing the exterior) may be suitably employed.

The present invention can provide an element exhibiting higher luminance or excellent durability by combining these methods.

In the case where a medium having a low refractive index and having a thickness greater than light wavelength is provided between a transparent electrode and a transparent substrate, the extraction efficiency of light from the transparent electrode to the exterior increases with a decrease in the refractive index of the medium.

Examples of the low refractive index layer include aerogel, porous silica, magnesium fluoride, and fluorinated polymer layers. Since the refractive index of a transparent substrate is generally about 1.5 to 1.7, the refractive index of the low refractive index layer is preferably about 1.5 or less, and more preferably 1.35 or less.

The low refractive index medium desirably has a thickness twice or more a light wavelength in the medium because if the low refractive index medium has a thickness similar to the light wavelength, the electromagnetic wave exuded as an evanescent wave penetrates into the substrate, resulting in a reduction of the effect of the low refractive index layer.

The method for providing a diffraction grating into the interface at which total reflection occurs or into any medium can increase the effect of enhancing the light extraction efficiency.

In this method, a diffraction grating is provided at the interface between any layers or into any medium (in the transparent substrate or the transparent electrode) to diffract and extract the light that is emitted from the light-emitting layer but cannot exit due to, for example, total reflection occurring at the interface between the layers, taking advantages of the property of the diffraction grating that can change the direction of light to a specific direction different from that of refraction by Bragg diffraction such as primary diffraction or secondary diffraction.

The diffraction grating to be introduced desirably has a two-dimensional periodic refractive index because light generated in a light-emitting layer is emitted randomly in all directions, and thus a common one-dimensional diffraction grating having a periodic refractive index distribution only in a specific direction can diffract only the light proceeding in a specific direction and cannot greatly increase the light extraction efficiency.

The use of a diffraction grating having a two-dimensional refractive index distribution allows diffraction of light proceeding in all directions, which increases efficiency of light extraction.

The diffraction grating may be provided between any layers or into any medium (in the transparent substrate or the transparent electrode) as described above but is desirably provided near an organic light-emitting layer where light is generated.

The period of the diffraction grating is preferably about ½ to 3 times the wavelength of light in a medium.

The array of the diffraction grating is preferably a two-dimensionally repeated array such as a square lattice, a triangular lattice or a honeycomb lattice.

<<Light-Condensing Sheet>>

The organic EL element of the present invention can enhance the luminance in a specific direction by condensing light in a specific direction, for example, in the front direction with respect to the light emitting face of the element by processing to provide, for example, a micro-lens array structure on the light extraction side of the substrate or combining with a light-condensing sheet.

In an example of a micro-lens array, quadrangular pyramids having a side of 30 μm and having a vertex angle of 90 degrees are two-dimensionally arranged on the light extraction side of the substrate. The quadrangular pyramid preferably has a side of 10 to 100 μm. When the length of the side is shorter than this range, the light is colored due to the effect of diffraction, while when it is too long, the thickness is unfavorably large.

As the light-condensing sheet, one practically used in an LED backlight of a liquid crystal display device can be used. Examples of the sheet include a luminance enhancing film (BEF) produced by SUMITOMO 3M Inc. The prism sheet may have a shape, for example, triangle-shaped stripes each having a vertex angle of 90 degrees and a pitch of 50 μm, having round apexes, having randomly changed pitches, and other shapes, formed on a base material.

In order to control the emission angle of light from the light-emitting element, a light diffusion plate or film may be used in combination with the light-condensing sheet. For example, a diffusion film (Light-Up), manufactured by KIMOTO Co., Ltd., can be used.

<<Method for Producing Organic EL Element>>

As an example of the method for producing the organic EL element of the present invention, a method for producing an organic EL element composed of anode/electron hole-injecting layer/electron hole-transporting layer/light-emitting layer/electron hole-blocking layer/electron-transporting layer/electron-injecting layer/cathode will be described.

A thin film having a thickness of 1 μm or less, preferably 10 to 200 nm, and composed of a desired electrode material, for example, a material for an anode, is formed on a suitable base by a method such as deposition or sputtering as the anode.

Subsequently, organic compound thin films as materials of the organic EL element, i.e., the electron hole-injecting layer, the electron hole-transporting layer, the light-emitting layer, the electron hole-blocking layer, the electron-transporting layer and the electron-injecting layer, are formed on the anode.

The respective layers are formed by vapor deposition or a wet process (such as spin coating, casting, ink jetting or printing) as described above. The wet process can easily form a uniform layer and hardly generates pinholes, for example. Thus, in the present invention, the films are preferably formed by coating such as spin coating, ink jetting or printing.

In the case of forming the constituent layers of the organic EL element of the present invention by application, the organic EL materials used for the application are dissolved or dispersed in liquid media, and usable examples of such a medium include ketones such as methyl ethyl ketone and cyclohexanone; aliphatic acid esters such as ethyl acetate; halogenated hydrocarbons such as dichlorobenzene; aromatic hydrocarbons such as toluene, xylene, mesitylene and cyclohexylbenzene; aliphatic hydrocarbons such as cyclohexane, decaline and dodecane; and organic solvents such as DMF and DMSO.

Dispersion can be performed by, for example, ultrasonic wave dispersion, high shearing force dispersion, or medium dispersion.

After formation of these layers, a thin film composed of the material for the cathode is formed thereon so as to have a thickness of 1 μm or less, and preferably in a range of 50 to 200 nm by a method such as vapor deposition or sputtering as the cathode. Thus, a desired organic EL element is produced.

Alternatively, the organic EL element can also be produced in the reverse order, i.e., in order of the cathode, the electron-injecting layer, the electron-transporting layer, the electron hole-blocking layer, the light-emitting layer, the electron hole-transporting layer, the electron hole-injecting layer and the anode.

When a direct current voltage, a voltage of about 2 to 40 V, is applied to the resulting organic EL element defining the anode as a positive electrode and the cathode as a negative electrode, light emission can be observed. Alternatively, an alternating voltage may be applied. The alternating current to be applied may have any wave form.

<<Use Application>>

The organic EL element of the present invention can be used as a display device, a display, or various light emission sources. Examples of the light emission source include, but not limited to, lighting devices (a home lamp or a room lamp in a car), backlights for watches and liquid crystals, board advertisements, traffic lights, light sources for optical memory media, light sources for electrophotographic copiers, light sources for optical communication instruments and light sources for optical sensors. In particular, the organic EL element can be effectively used as a backlight for a liquid crystal display device or a lighting source.

In the organic EL element of the present invention, the films are patterned with a metal mask or by ink-jet printing during formation of the films as needed.

The patterning may be performed for only the electrodes or for the electrodes and the light-emitting layer or for all layers of the element. In the production of the element, a conventionally known method may be employed.

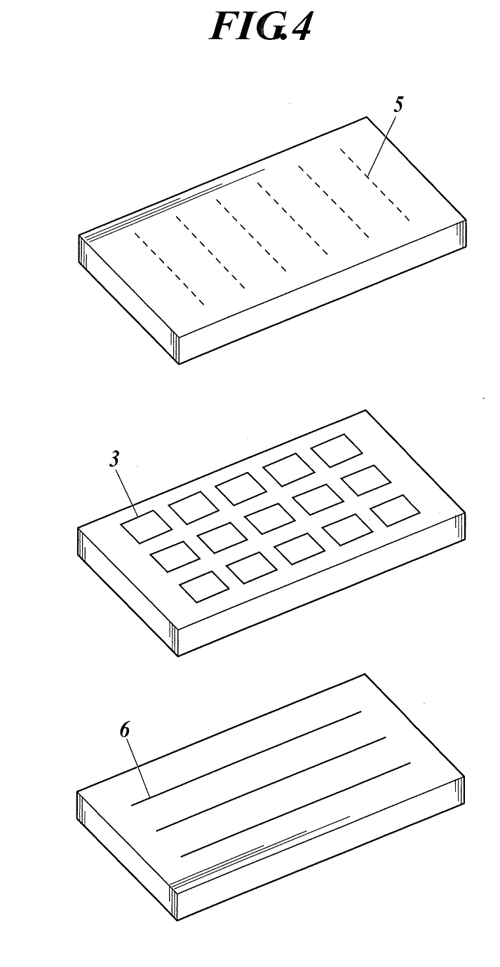

Colors of light emitted by the organic EL element of the present invention or the compounds according to the present invention are specified as the colors determined by applying the results of measurements with a spectral radiance meter CS-1000 (manufactured by Konica Minolta Sensing Co., Ltd.) to the CIE chromaticity coordinates in FIG. 4.16 on page 108 of “New Edition Color Science Handbook” (edited by The Color Science Association of Japan, University of Tokyo Press, 1985).

When the organic EL element of the present invention is a white light-emitting element, white means that when the front luminance of a 2 degree viewing angle is measured by the method described above, chromaticity in the CIE 1931 chromaticity system at 1000 cd/m² is within a region of X=0.33±0.07 and Y=0.33±0.1.

<<Display Device>>

The display device of the present invention will be described. The display device of the present invention includes the organic EL element(s) of the present invention.

The display device of the present invention may be monochromatic or multichromatic. Herein, a multichromatic display device will be described. In the case of a multichromatic display device, the films can be formed on the entire upper surfaces by, for example, vacuum deposition, casting, spin coating, ink jetting or printing, while a shadow mask is provided only in formation of the light-emitting layer.

In the case of patterning only the light-emitting layer, the patterning may be performed by any method without particular limitation and is preferably performed by vacuum deposition, ink jetting, spin coating or printing.

A configuration of the organic EL element provided to the display device is appropriately selected from the above-exemplified configurations of the organic EL element.

The method for producing the organic EL element is as shown in the above one embodiment of the production of the organic EL element of the present invention.

When a direct current voltage, a voltage of about 2 to 40 V, is applied to the resulting multichromatic display device defining the anode as a positive electrode and the cathode as a negative electrode, light emission can be observed. Alternatively, when a voltage is applied with reverse polarity, any current does not flow, and light is not emitted at all. When an alternating current is applied, light is emitted only in the state of the anode being positive and cathode being negative. The alternating current to be applied may have any wave form.

The multichromatic display device can be used as a display device, a display, or various light emission sources. In the display device and display, full color displaying is possible by using three types of organic EL elements that emit blue, red or green light.

Examples of the display device and the display include televisions, personal computers, mobile equipment, AV equipment, teletext displays, and information displays in automobiles. In particular, the display device may be used for reproducing still images or moving images, and the driving system in the case of using the display device for reproducing moving images may be either a simple matrix (passive matrix) system or active matrix system.

Examples of the light emission source include, but not limited to, home lamps, room lamps in cars, backlights for watches and liquid crystals, board advertisements, traffic lights, light sources for optical memory media, light sources for electrophotographic copiers, light sources for optical communication instruments and light sources for optical sensors.

An example of the display device including the organic EL element(s) of the present invention will now be described with reference to the drawings.

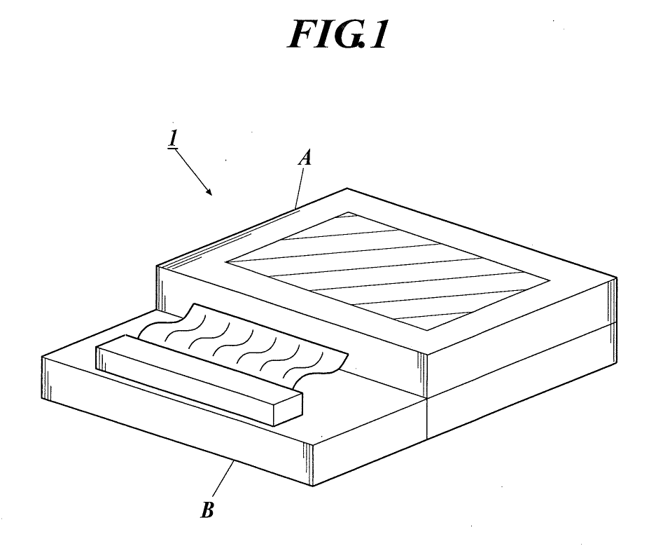

FIG. 1 is a schematic diagram illustrating an example of a display device composed of organic EL elements. The schematic diagram illustrates a display for, for example, a mobile phone to display image information through light emission by the organic EL elements.

The display 1 is composed of a display unit A including a plurality of pixels and a control unit B performing image scanning on the display unit A based on image information and so forth.

The control unit B is electrically connected to the display unit A and sends scanning signals and image data signals to the respective pixels based on externally-input image information. The pixels of each scanning line provided with the scanning signal sequentially emit light according to the image data signal, and the image information is displayed on the display unit A through image scanning.

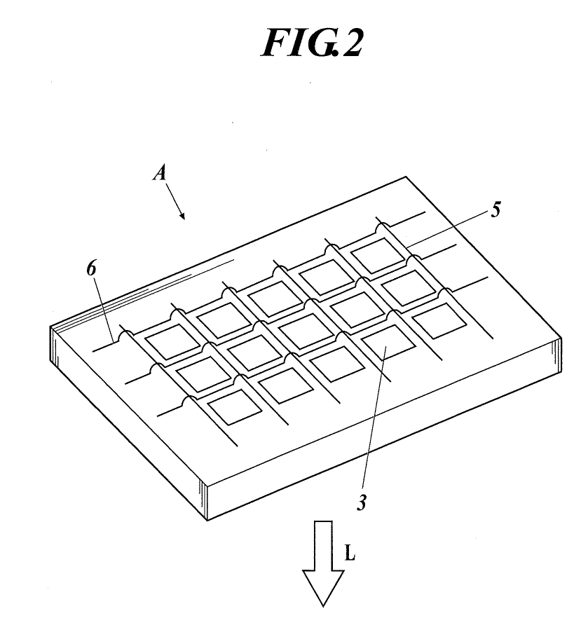

FIG. 2 is a schematic diagram of the display unit A.

The display unit A includes, for example, a line part including a plurality of scanning lines 5 and data lines 6, and a plurality of pixels 3 on a substrate. The main components of the display unit A will now be described.

In the drawing, light L emitted by the pixels 3 is extracted to the direction shown by the white arrow (downward direction).

The scanning lines 5 and the data lines 6 in the line part are made of an electrically conductive material and are disposed so as to be orthogonal to each other to form a grid pattern. The scanning lines 5 and the data lines 6 are connected to the respective pixels at the intersections (the details are not shown). A scanning signal is applied to the scanning line 5, and then the pixels 3 receive an image data signal from the data lines 6 and emit light according to the received image data.

Full color displaying is possible by appropriately apposing pixels that emit light in a red region, light in a green region or light in a blue region on a single substrate.

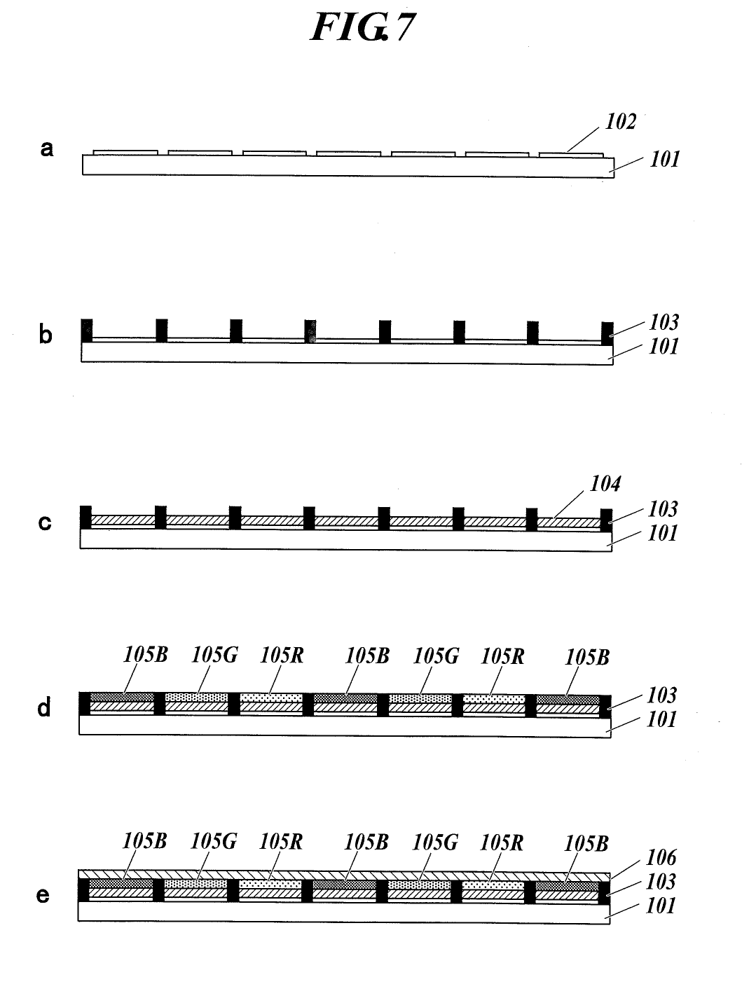

FIG. 7 shows schematic diagrams illustrating the configuration of a full-color organic EL display device.

The light emission process of a pixel will now be described.

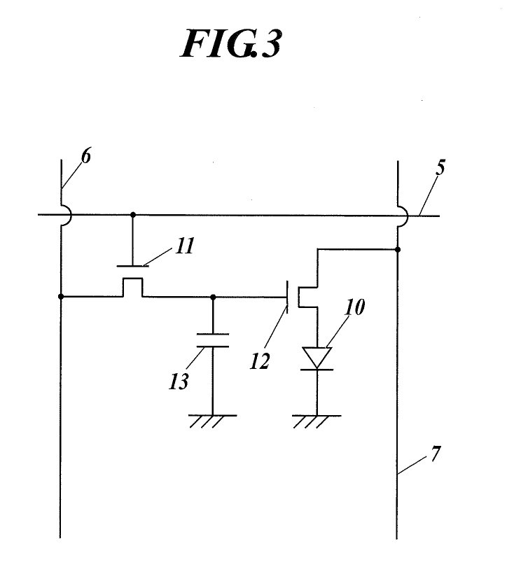

FIG. 3 is a schematic diagram of the pixel.

The pixel includes an organic EL element 10, a switching transistor 11, a driving transistor 12, a capacitor 13, etc. Full color displaying can be performed using organic EL elements 10 emitting red light, green light or blue light that are arrayed at respective pixels on a single substrate.

In FIG. 3, an image data signal from the control unit B is applied to the drain of the switching transistor 11 via the data line 6. Then, a scanning signal from the control unit B is applied to the gate of the switching transistor 11 via the scanning line 5 to make the switching transistor 11 start driving, and the image data signal applied to the drain is transmitted to gates of the capacitor 13 and the driving transistor 12.

The capacitor 13 is charged through the transmission of the image data signal depending on the potential of the image data signal, and the driving transistor 12 starts driving. In the driving transistor 12, the drain is connected to a power source line 7, and a source is connected to the electrode of the organic EL element 10 to supply a current to the organic EL element 10 from the power source line 7 depending on the potential of the image data signal applied to the gate.

The scanning signal is transmitted to the next scanning line 5 by sequential scanning by the control unit B, and then the switching transistor 11 stops the driving. The capacitor 13 maintains the charged potential of the image data signal even after the switching transistor 11 stops the driving, and thus the driving state of the driving transistor 12 is maintained to continue the light emission of the organic EL element 10 until the next scanning signal is applied. The driving transistor 12 is driven according to the potential of the subsequent image data signal in synchronization with the subsequent scanning signal applied by sequential scanning, resulting in light emission by the organic EL element 10.

That is, light emission by the organic EL element 10 is performed by providing the switching transistor 11 and the driving transistor 12 serving as active elements to the organic EL element 10 of each of the plurality of pixels and allowing the respective organic EL elements 10 of the pixels 3 to emit light. Such a light emitting process is called an active matrix system.

Light emitted by the organic EL element 10 may have multiple gradations according to multi-valued image data signals having different gradation electric potentials, or light emission by the organic EL element 10 may be turning on and off of light of a predetermined intensity according to a binary image data signal. The electric potential of the capacitor 13 may be maintained until the subsequent scanning signal is applied, or may be discharged immediately before the subsequent scanning signal is applied.

In the present invention, the light emission may be driven by a passive matrix system as well as the active matrix system described above. In the passive matrix system, light is emitted by the organic EL element in response to the data signal only during application of the scanning signals.

FIG. 4 illustrates schematic diagrams of a passive-matrix display device. In FIG. 4, pixels are provided between the scanning lines 5 and the image data lines 6 that are orthogonal to each other across the pixel 3 to form a grid pattern.

When a scanning signal is applied to a scanning line 5 by a sequential scanning, the pixel 3 connected to the scanning line 5 to which the scanning signal is applied emits light in accordance with the image data signal.

The passive matrix system does not have any active element in the pixels 3, resulting in a reduction in manufacturing cost.

<<Lighting Device>>

A lighting device of the present invention will be described. The lighting device of the present invention includes the organic EL element(s) described above.

The organic EL element of the present invention having a resonator structure may be used. The organic EL element having a resonator structure can be applied to, for example, light sources for optical memory media, light sources for electrophotographic copiers, light sources for optical communication instruments and a light sources for optical sensors; however, its application is not limited thereto. Alternatively, the organic EL element of the present invention may be used for the above-mentioned purposes by employing laser oscillation.

The organic EL element of the present invention may be used as a lamp such as a lighting source or an exposure light source or may be used as a projector for projecting images or a display device (display) for direct view of still or moving images.

A driving system of the display device used for playback of moving images may be either a simple matrix (passive matrix) system or an active matrix system. Furthermore, a full-color display device can be produced by employing two or more types of organic EL elements of the present invention that emit light of different colors. The organic EL material of the present invention can be applied to an organic EL element emitting substantially white light as a lighting device. The white light is generated by mixing light having different colors simultaneously emitted by a plurality of light-emitting materials. The combination of colors of the emitted light may be a combination containing light of three maximum wavelengths of three primary colors of blue, green and red or a combination containing light of two maximum wavelengths using a relationship of complimentary colors such as blue and yellow or blue-green and orange.

Furthermore, the combination of light-emitting materials to obtain a plurality of colors of emitted light may be either a combination of a plurality of phosphorescence or fluorescence emitting materials or a combination of a fluorescent or phosphorescent material and a coloring material that emits light as excited light using the light from the light-emitting material. However, in the white organic EL element according to the present invention, a combination of a plurality of light-emitting dopants only is sufficient.

It is sufficient that during formation of the light-emitting layer, the electron hole-transporting layer or the electron-transporting layer, a mask can be simply arranged to conduct patterning via the arranged mask. The other layers are common and do not require any patterning with a mask or the like, and for example, an electrode film can be formed on the entire upper surface by, for example, vacuum deposition, casting, spin coating, ink jetting or printing, and thus productivity is also enhanced.

According to this method, the element itself emits white light, unlike a white organic EL device including light-emitting elements emitting different colors apposed in an array form.

Any light-emitting material can be used without particular limitation for a light-emitting layer. For example, in a backlight in a liquid crystal display element, white light may be made by appropriately selecting and combining the metal complex(es) according to the present invention or known light-emitting material(s) so as to match with the wavelength range corresponding to color filter (CF) characteristics.

<<One Embodiment of Lighting Device of the Present Invention>>

One embodiment of the lighting device including the organic EL element(s) of the present invention will now be described.

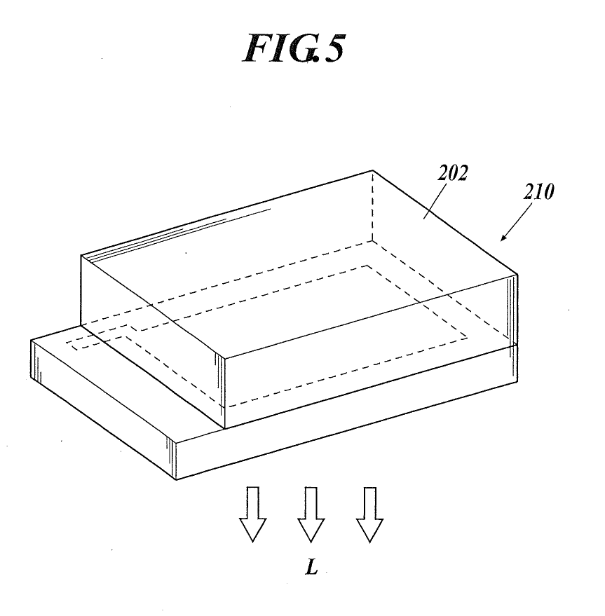

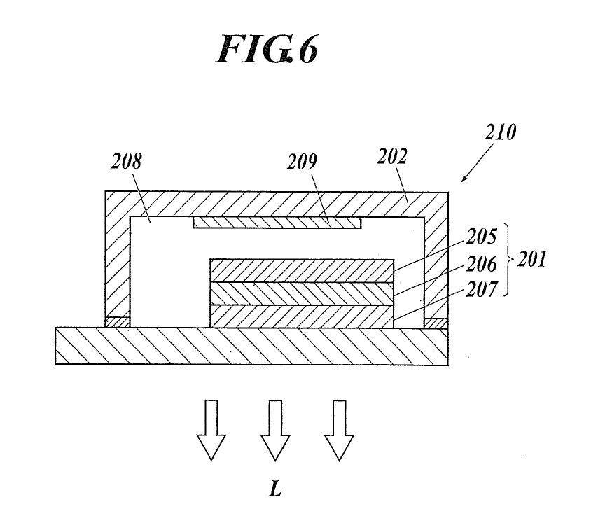

The non-light-emitting surface of the organic EL element of the present invention is covered with a glass case, and a glass substrate having a thickness of 300 μm is used as a sealing substrate. As a sealing material, an epoxy based photo-curable adhesive (LUXTRACK LC0629B manufactured by Toagosei Co., Ltd.) is applied to the periphery, and the glass case is placed above the cathode and is attached to the transparent supporting substrate, followed by curing the adhesive by irradiation with UV light from the side of the glass substrate for sealing. Thus, a lighting device as shown in FIGS. 5 and 6 can be formed.

FIG. 5 is a schematic diagram of the lighting device 210. An organic EL element 201 of the present invention is covered with a glass cover 202 (sealing with the glass cover is performed in a glove box under a nitrogen atmosphere (an atmosphere of high purity nitrogen gas having a purity of at least 99.999%) for preventing the organic EL element 201 from being contact with the air).

FIG. 6 is a cross-sectional view of the lighting device 210. In FIG. 6, reference numeral 205 denotes a cathode, reference numeral 206 denotes an organic EL layer, and reference numeral 207 denotes a glass substrate provided with a transparent electrode. The inside of the glass cover 202 is filled with nitrogen gas 208 and is provided with a water absorbent 209.

FIG. 7 includes schematic diagrams illustrating an exemplary process of producing a full-color organic EL display device by ink jetting. In FIG. 7, barrier walls 103 of a non-photosensitive polyimide are formed by photolithography on a glass substrate 101 provided with ITO electrodes 102. In each space defined by the barrier walls, the following layers are formed by discharge from an ink-jet head (MJ800C, manufactured by Seiko Epson Corp.). A first electron hole-transporting layer 104 having a thickness of 20 nm was formed on the ITO electrode 102; and a light-emitting unit 105 composed of a second electron hole-transporting layer having a thickness of 20 nm, a light-emitting layer having a thickness of 40 nm and an electron-transporting layer having a thickness of 30 nm laminated in this order is formed on the first electron hole-transporting layer 104. After formation of the light-emitting unit, a cathode buffer layer/cathode 106 is formed by vacuum deposition to give an organic EL element.

The organic EL element produced by forming the respective light-emitting layer by ink-jetting as described above emits blue, green or red light by applying voltage to the respective electrodes and it is confirmed that the organic EL element can be used as a full-color display device. The light-emitting units 105 in the Figure are discriminately described, i.e., the Figure illustrates a light-emitting unit 105R containing a red light-emitting material in the light-emitting layer constituting the light-emitting unit, a light-emitting unit 105G containing a green light-emitting material in the light-emitting layer constituting the light-emitting unit, and a light-emitting unit 105B containing a blue light-emitting material in the light-emitting layer constituting the light-emitting unit.

### EXAMPLES

The present invention will now be described with reference to examples, but the present invention is not limited thereto.

In examples, “%” indicates “% by mass” unless stated otherwise.

### Example 1

### Method for Producing Organic EL Element 1-1

A substrate (NA-45, manufactured by NH Techno Glass Corp.), prepared by forming a film of ITO (indium tin oxide) having a thickness of 100 nm on a glass substrate of 100×100×1.1 mm, was patterned to form an anode. This transparent supporting substrate provided with the ITO transparent electrode was cleaned with ultrasonic waves in isopropyl alcohol, dried with dry nitrogen gas, and subjected to UV ozone washing for 5 minutes. Subsequently, each material described below was put in a molybdenum or tungsten boat, and then each of the molybdenum or tungsten boat was set to a vacuum deposition device together with the glass substrate provided with the transparent electrode. After the degree of vacuum reached 1×10⁻⁴ Pa or below, films were sequentially formed as follows.

First, a charge-generating layer composed of two layers was formed. Dipyrazino[2,3-f:2′,3′-h]quinoxaline-2,3,6,7,10,11-hexacarbonitrile (HAT) was deposited at a deposition rate of 0.1 nm/sec to form a first layer with a thickness of 20 nm, and the organic metal complex D-4 was then deposited at a deposition rate of 0.01 nm/sec to form a second layer having a thickness of 5 nm. Subsequently, OC-9 was deposited at a deposition rate of 0.1 nm/sec and D-1 was deposited at a deposition rate of 0.01 nm/sec to form a light-emitting layer having a thickness of 40 nm, and then OC-10 was deposited at a deposition rate of 0.1 nm/sec to form an electron-transporting layer having a thickness of 30 nm. Subsequently, sodium fluoride was deposited to form an electron-injecting layer having a thickness of 1.0 nm, and aluminum was deposited to form a cathode having a thickness of 110 nm. An organic EL element 1-1 was thereby produced.

<Method for Producing Organic EL Element 1-2>

A substrate (NA-45, manufactured by NH Techno Glass Corp.), prepared by forming a film of ITO (indium tin oxide) having a thickness of 100 nm on a glass substrate of 100×100×1.1 mm, was patterned to form an anode. This transparent supporting substrate provided with the ITO transparent electrode was cleaned with ultrasonic waves in isopropyl alcohol, dried with dry nitrogen gas, and subjected to UV ozone washing for 5 minutes. Subsequently, each material described below was put in a molybdenum or tungsten boat, and then each of the molybdenum or tungsten boat was set to a vacuum deposition device together with the glass substrate provided with the transparent electrode. After the degree of vacuum reached 1×10⁻⁴ Pa or below, films were sequentially formed as follows.

First, a charge-generating layer composed of two layers was formed. HAT was deposited at a deposition rate of 0.1 nm/sec to form a first layer having a thickness of 20 nm, and N,N′-di(1-naphthyl)-N,N′-diphenylbenzidine (α-NPD) was then deposited at a deposition rate of 0.1 nm/sec to form a second layer having a thickness of 20 nm. Subsequently, OC-9 was deposited at a deposition rate of 0.1 nm/sec and D-1 was deposited at a deposition rate of 0.01 nm/sec to form a light-emitting layer having a thickness of 40 nm, and then OC-10 was deposited at a deposition rate of 0.1 nm/sec to form an electron-transporting layer with a thickness of 30 nm. Subsequently, sodium fluoride was deposited to form an electron-injecting layer having a thickness of 1.0 nm, and aluminum was deposited to form a cathode having a thickness of 110 nm. An organic EL element 1-2 was thereby produced.

<Method for Producing Organic EL Element 1-3>

A substrate (NA-45, manufactured by NH Techno Glass Corp.), prepared by forming a film of ITO (indium tin oxide) having a thickness of 100 nm on a glass substrate of 100×100×1.1 mm, was patterned to form an anode. This transparent supporting substrate provided with the ITO transparent electrode was cleaned with ultrasonic waves in isopropyl alcohol, dried with dry nitrogen gas, and subjected to UV ozone washing for 5 minutes. Subsequently, each material described below was put in a molybdenum or tungsten boat, and then each of the molybdenum or tungsten boat was set to a vacuum deposition device together with the glass substrate provided with the transparent electrode. After the degree of vacuum reached 1×10⁻⁴ Pa or below, films were sequentially formed as follows.

First, copper phthalocyanine (CuPc) was deposited at a deposition rate of 0.1 nm/sec to form a first electron hole-transporting layer having a thickness of 10 nm. On the first electron hole-transporting layer, the organic metal complex D-4 was deposited at a deposition rate of 0.01 nm/sec to form a second electron hole-transporting layer having a thickness of 10 nm.

On the second electron hole-transporting layer, OC-9 was deposited at a deposition rate of 0.1 nm/sec and D-1 was deposited at a deposition rate of 0.01 nm/sec to form a light-emitting layer with a thickness for 40 nm, and then OC-10 was deposited at a deposition rate of 0.1 nm/sec to form an electron-transporting layer having a thickness of 30 nm. Subsequently, sodium fluoride was deposited to form an electron-injecting layer having a thickness of 1.0 nm, and aluminum was deposited to form a cathode having a thickness of 110 nm. An organic EL element 1-3 was thereby produced.

<Method for Producing Organic EL Element 1-4>

A substrate (NA-45, manufactured by NH Techno Glass Corp.), prepared by forming a film of ITO (indium tin oxide) having a thickness of 100 nm on a glass substrate of 100×100×1.1 mm, was patterned to form an anode. This transparent supporting substrate provided with the ITO transparent electrode was cleaned with ultrasonic waves in isopropyl alcohol, dried with dry nitrogen gas, and subjected to UV ozone washing for 5 minutes. Subsequently, each material described below was put in a molybdenum or tungsten boat, and then each of the molybdenum or tungsten boat was set to a vacuum deposition device together with the glass substrate provided with the transparent electrode. After the degree of vacuum reached 1×10⁻⁴ Pa or below, films were sequentially formed as follows.

First, copper phthalocyanine (CuPc) was deposited at a deposition rate of 0.1 nm/sec to form a first electron hole-transporting layer having a thickness of 10 nm. On the first electron hole-transporting layer, α-NPD was deposited at a deposition rate of 0.1 nm/sec to form a second electron hole-transporting layer having a thickness of 20 nm.

On the second electron hole-transporting layer, OC-9 was deposited at a deposition rate of 0.1 nm/sec and D-1 was deposited at a deposition rate of 0.01 nm/sec to form a light-emitting layer having a thickness of 40 nm, and then OC-10 was deposited at a deposition rate of 0.1 nm/sec to form an electron-transporting layer having a thickness of 30 nm. Subsequently, sodium fluoride was deposited to form an electron-injecting layer having a thickness of 1.0 nm, and aluminum was deposited to form a cathode having a thickness of 110 nm. An organic EL element 1-4 was thereby produced.

<<Evaluation of Organic EL Elements 1-1 to 1-4>>

For evaluating the resulting organic EL elements 1-1 to 1-4, the non-light-emitting surface of each of the resulting organic EL elements was covered with a glass case, and a glass substrate having a thickness of 300 μm was used as a sealing substrate, and as a sealing material, an epoxy based photo-curable adhesive (LUXTRACK LC0629B manufactured by Toagosei Co., Ltd.) was applied to the periphery, and the glass cover was placed onto the cathode and was attached to the transparent supporting substrate, followed by curing the adhesive by irradiation with UV light from the glass substrate side for sealing. Lighting devices as shown in FIGS. 5 and 6 were thereby produced and were evaluated.

<<Driving Voltage>>

The voltage at which light emission started was measured at 23° C. under a dry nitrogen gas atmosphere. As the voltage at the time when light emission started, the voltage value at the time when the luminance reached 50 cd/m² or above was measured. The luminance was measured with a spectral radiance meter CS-1000 (manufactured by Konica Minolta Sensing Co., Ltd.).

<<Increment in Driving Voltage>>

A constant current of 25 mA/cm² was applied to the organic EL element at 23° C. under a dry nitrogen gas atmosphere. Defining the initial driving voltage as V₀ and the driving voltage after driving for 100 hours as V₁₀₀. V₁₀₀−V₀ was evaluated as an increment in driving voltage.

<<Lifetime of Light Emission>>

The organic EL element was driven with a constant current of 2.5 mA/cm² at 23° C. under a dry nitrogen gas atmosphere. The time period until the luminance decreased by a half of the luminance immediately after the start of the emission (initial luminance) was measured. This time period, i.e., half-life time (τ=0.5), was used as an index of the lifetime. The luminance was measured with a spectral radiance meter CS-1000 (manufactured by Konica Minolta Sensing Co., Ltd.).

The results for the organic EL elements 1-1 to 1-4 are shown as relative evaluation compared to the organic EL element 1-4 whose values are defined as 100. The results are shown in Table 1.

TABLE 1

| Organic | | Increment | Life time | |
|---|---|---|---|---|
| EL | Driving | of driving | of light | |
| element | voltage | voltage | emission | Note |
| 1-1 | 92 | 75 | 145 | Present Invention |
| 1-2 | 94 | 102 | 105 | Comparative Example |
| 1-3 | 102 | 95 | 95 | Comparative Example |
| 1-4 | 100 | 100 | 100 | Comparative Example |

The results shown above evidently demonstrate that the change in driving voltage of the element (organic EL element 1-1) of the present invention can be reduced.

The use of well-known triarylamine electron hole-transporting materials (organic EL elements 1-2 and 1-4) probably causes disadvantageous degradation of the triarylamine electron hole-transporting materials due to injection of electrons not recombined in the light-emitting layer into the electron hole-transporting layer, and thus larger changes in the driving voltages compared to that in the element of the present invention are observed.

In the element (organic EL element 1-1) of the present invention, the driving voltage was reduced by disposing the charge-generating layer so as to be adjoin the light-emitting layer, compared to conventional electron hole-injecting materials. This is because charge is generated at a position adjoining the light-emitting layer, and injection barriers between the anode and the light-emitting layer is concentrated only at the injection barrier between the organic metal complex layer and the light-emitting layer. As a result, the degradation of the element by barriers can be reduced, and the lifetime can also be lengthened. In contrast, the use of a triarylamine material in the charge-generating layer (organic EL element 1-2) as in conventional elements disadvantageously causes degradation of an interface due to electrons inevitably generated at the interface as described above, and the effect for lengthening the lifetime is relatively low. Thus, the usefulness of the present invention is obvious.

On the other hand, in the case of using an organic metal complex in the electron hole-transporting material (organic EL element 1-3), the electron resistance increases because of nonuse of the triarylamine material at the position adjoining the light-emitting layer; however, since the charge is not generated between the triarylamine material and the copper phthalocyanine, the injection barrier between the anode and the light-emitting layer increases relative to the present invention. The effect for suppressing the change in driving voltage is therefore relatively low. Thus, the usefulness of the present invention is obvious.

### Example 2

### Comparison of Electron-Extracting Material

### Method for Producing Organic EL Element 2-5>

A substrate (NA-45, manufactured by NH Techno Glass Corp.), prepared by forming a film of ITO (indium tin oxide) having a thickness of 100 nm on a glass substrate of 100×100×1.1 mm, was patterned to form an anode. This transparent supporting substrate provided with the ITO transparent electrode was cleaned with ultrasonic waves in isopropyl alcohol, dried with a dry nitrogen gas, and subjected to UV ozone washing for 5 minutes.

Subsequently, each material described below was put in a molybdenum or tungsten boat, and each of the molybdenum or tungsten boat was set to a vacuum deposition device together with the glass substrate provided with the transparent electrode. After the degree of vacuum reached 1×10⁻⁴ Pa or below, films were sequentially formed as follows.

First, a charge-generating layer composed of two layers was formed. HAT was deposited at a deposition rate of 0.1 nm/sec to form a first layer having a thickness of 20 nm, and the organic metal complex D-1 was then deposited at a deposition rate of 0.01 nm/sec to form a second layer having a thickness of 5 nm. Subsequently, OC-13 was deposited at a deposition rate of 0.1 nm/sec and D-1 was deposited at a deposition rate of 0.02 nm/sec to form a light-emitting layer having a thickness of 80 nm, and OC-103 was then deposited at a deposition rate of 0.1 nm/sec to form an electron-transporting layer having a thickness of 30 nm. Subsequently, sodium fluoride was deposited to form an electron-injecting layer having a thickness of 1.0 nm, and aluminum was deposited to form a cathode having a thickness of 110 nm. An organic EL element 2-5 was thereby produced.

Organic EL elements 2-1 to 2-4 were produced by the same way as in the production of the organic EL element 2-1 except that electron-extracting materials shown in Table 2 were used in place of HAT used in the organic EL element 2-5. Organic EL element 2-6 was produced using molybdenum oxide, which is not an electron-extracting material, as the material constituting the charge-generating layer in place of the electron-extracting material used in the organic EL element 2-5; and organic EL element 2-7 not having a charge-generating layer was produced. The organic EL elements 2-1 to 2-7 were evaluated by values relative to that of the organic EL element 2-7 that was defined as 100. The results are shown in Table 2.

TABLE 2

| | Electron- | | | |
|---|---|---|---|---|
| | extracting | | | |
| | layer | | | |
| Organic | | LUMO | | |
| EL | | level | Increment of | |
| element | Material | (eV) | driving voltage | Note |
| 2-1 | OA-1 | −2.5 | 90 | Present Invention |
| 2-2 | OA-2 | −3.3 | 75 | Present Invention |
| 2-3 | OA-3 | −4.1 | 65 | Present Invention |
| 2-4 | OA-4 | −4.2 | 65 | Present Invention |
| 2-5 | HAT | −4.6 | 60 | Present Invention |
| 2-6 | none | — | 95 | Present Invention |
| | (molybdenum | | | |
| | oxide) | | | |
| 2-7 | none | — | 100 | Comparative |
| | | | | Example |

The structural formulae of the electron-extracting materials used in the production of organic EL elements 2-1 to 2-4 are shown below.

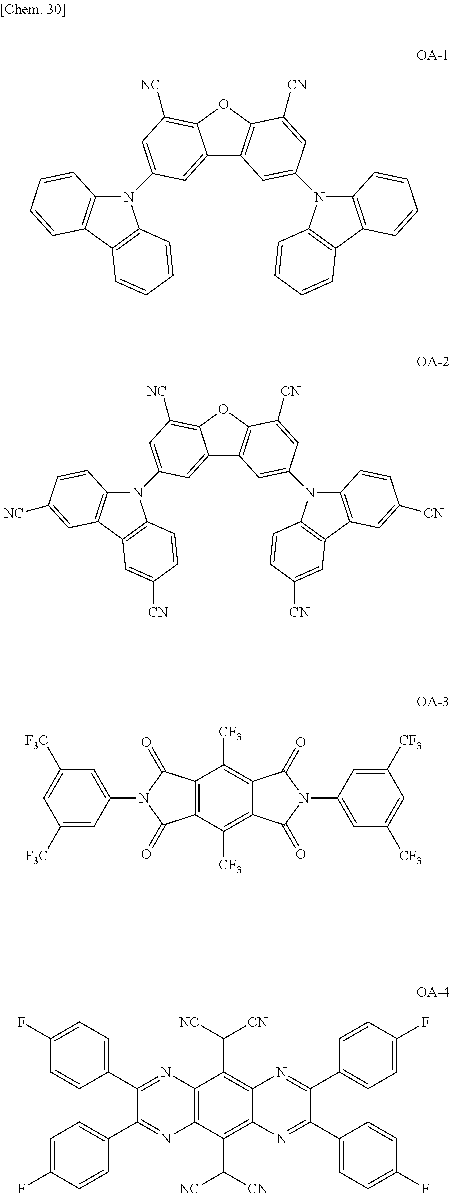 [SMILES: N#Cc1cc(-n2c3ccccc3c3ccccc32)cc2c1oc1c(C#N)cc(-n3c4ccccc4c4ccccc43)cc12 ; N#Cc1ccc2c(c1)c1cc(C#N)ccc1n2-c1cc(C#N)c2oc3c(C#N)cc(-n4c5ccc(C#N)cc5c5cc(C#N)ccc54)cc3c2c1 ; O=c1c2c(C(F)(F)F)c3c(=O)n(-c4cc(C(F)(F)F)cc(C(F)(F)F)c4)c(=O)c3c(C(F)(F)F)c2c(=O)n1-c1cc(C(F)(F)F)cc(C(F)(F)F)c1 ; N#CC(C#N)c1c2nc(-c3ccc(F)cc3)c(-c3ccc(F)cc3)nc2c(C(C#N)C#N)c2nc(-c3ccc(F)cc3)c(-c3ccc(F)cc3)nc12]

The results shown in Table 2 demonstrate that increase in driving voltage can be reduced by disposing an electron-extracting layer as one of the layers constituting the charge-generating layer (organic EL elements 2-1 to 2-5). In particular, this effect is noticeable in the case where an electron-extracting material has a LUMO level of −3.0 or less.

### Example 3

### Comparison of Relationship with HOMO Level of Complex

### <Method for Producing Organic EL Element 3-1>

A substrate (NA-45, manufactured by NH Techno Glass Corp.), prepared by forming a film of ITO (indium tin oxide) having a thickness of 100 nm on a glass substrate of 100×100×1.1 mm, was patterned to form an anode. This transparent supporting substrate provided with the ITO transparent electrode was cleaned with ultrasonic waves in isopropyl alcohol, dried with dry nitrogen gas, and subjected to UV ozone washing for 5 minutes. Subsequently, each material described below was put in a molybdenum or tungsten boat, and then each of the molybdenum or tungsten boat was set to a vacuum deposition device together with the glass substrate provided with the transparent electrode. After the degree of vacuum reached 1×10⁻⁴ Pa or below, films were sequentially formed as follows.

First, a charge-generating layer composed of two layers was formed. HAT was deposited at a deposition rate of 0.1 nm/sec to form a first layer with a thickness for 20 nm, and the organic metal complex D-15 was then deposited at a deposition rate of 0.01 nm/sec to form a second layer having a thickness of 5 nm. Subsequently, OC-9 was deposited at a deposition rate of 0.1 nm/sec and D-2 was deposited at a deposition rate of 0.01 nm/sec to form a light-emitting layer having a thickness of 80 nm, and OC-103 was then deposited at a deposition rate of 0.1 nm/sec to form an electron-transporting layer having a thickness of 30 nm. Subsequently, sodium fluoride was deposited to form an electron-injecting layer having a thickness of 1.0 nm, and aluminum was deposited to form a cathode having a thickness of 110 nm. An organic EL element 3-1 was thereby produced.

Organic EL elements 3-2 to 3-8 were produced by the same way as in the production of the organic EL element 3-1 except that organic metal complexes shown in Table 3 were used in place of the organic metal complex D-15 used in the organic EL element 3-1. The organic EL elements 3-1 to 3-8 were evaluated by values relative to that of the organic EL element 3-8 that was defined as 100. The results are shown in Table 3.

TABLE 3

| | Electron- | | | | | | |
|---|---|---|---|---|---|---|---|
| | extracting | | Organic metal | | | | |
| | layer | | complex | | | Increment | |
| Organic | | LUMO | | HOMO | \|HOMO − | of | |
| EL | | level | | level | LUMO\| | driving | |
| element | Material | (eV) | Material | (eV) | (eV)* | voltage | Note |
| 3-1 | HAT | −4.6 | D-15 | −5.0 | 0.4 | 74 | Present Invention |
| 3-2 | | | D-2 | −4.4 | 0.2 | 76 | Present Invention |
| 3-3 | | | D-4 | −5.3 | 0.7 | 85 | Present Invention |
| 3-4 | | | D-54 | −5.0 | 0.4 | 73 | Present Invention |
| 3-5 | | | D-55 | −4.9 | 0.3 | 71 | Present Invention |
| 3-6 | | | D-56 | −5.2 | 0.6 | 83 | Present Invention |
| 3-7 | | | ND-1 | −5.1 | 0.5 | 80 | Present Invention |
| 3-8 | | | D-16 | −5.9 | 0.3 | 100 | Present Invention |

*obtained by calculating an absolute value of (a HOMO level of the organic metal complex − a LUMO level of the electron-extracting layer)

Table 3 evidently demonstrates that the difference between the LUMO level of the electron-extracting layer and the HOMO level of the adjoining organic metal complex layer, both of which constitute the charge-generating layer, significantly affects the increment in the driving voltage. It is obvious that the advantageous effect of the present invention can be achieved at a maximum at an absolute difference value of 1.0 eV or less, and preferably at an absolute difference of 0.5 eV or less. Furthermore, organic EL element 3-7 was produced using a non-phosphorescence emitting organic metal complex ND-1 in place of the organic metal complex material used in the organic EL element 3-1. The organic EL element 3-7 showed the same tendency as those in the use of other organic metal complexes.

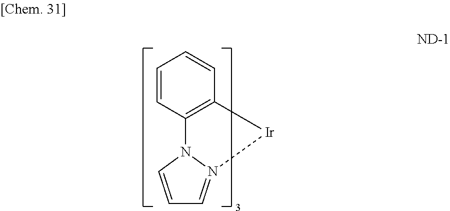

TABLE 4

| | Electron- | | Organic metal | | | | |
|---|---|---|---|---|---|---|---|
| | extracting layer | | complex | | | Increment | |
| Organic | | LUMO | | HOMO | \|HOMO − | of | |
| EL | | level | | level | LUMO\| | driving | |
| element | Material | (eV) | Material | (eV) | (eV)* | voltage | Note |
| 3-9 | OA-2 | −3.3 | D-57 | −4.2 | 0.9 | 76 | Present Invention |
| 3-10 | | | D-2 | −4.4 | 1.1 | 91 | Present Invention |
| 3-11 | | | D-15 | −5.0 | 1.7 | 100 | Present Invention |

*obtained by calculating an absolute value of (a HOMO level of the organic metal complex − a LUMO level of the electron-extracting layer)

Organic EL elements 3-9 to 3-11 were produced by the same way as in the production of the organic EL element 3-1 except that materials shown in Table 4 were used in place of the material of the electron-extracting layer and the organic metal complex material used in the organic EL element 3-1. The same tendency described above was observed even in the use of electron-extracting materials having different LUMO levels. This result also demonstrates that the difference between the LUMO level of the electron-extracting layer and the HOMO level of the adjoining organic metal complex layer, both of which form the charge-generating layer, is an important factor of the present invention.

### Example 4

### Method for Producing Organic EL Element 4-1

A substrate (NA-45, manufactured by NH Techno Glass Corp.), prepared by forming a film of ITO (indium tin oxide) having a thickness of 100 nm on a glass substrate of 100×100×1.1 mm, was patterned to form an anode. This transparent supporting substrate provided with the ITO transparent electrode was cleaned with ultrasonic waves in isopropyl alcohol, dried with dry nitrogen gas, and subjected to UV ozone washing for 5 minutes. Subsequently, each material described below was put in a molybdenum or tungsten boat, and then each of the molybdenum or tungsten boat was set to a vacuum deposition device together with the glass substrate provided with the transparent electrode. After the degree of vacuum reached 1×10⁻⁴ Pa or below, films were sequentially formed as follows.

First, a charge-generating layer composed of two layers was formed. HAT was deposited at a deposition rate of 0.1 nm/sec to form a first layer having a thickness of 20 nm, and the organic metal complex D-4 was then deposited at a deposition rate of 0.01 nm/sec to form a second layer having a thickness of 10 nm. Subsequently, OC-16 was deposited at a deposition rate of 0.1 nm/sec and D-16 was deposited at a deposition rate of 0.01 nm/sec to form a light-emitting layer having a thickness of 80 nm, and OC-10 was then deposited at a deposition rate of 0.1 nm/sec to form an electron-transporting layer having a thickness of 30 nm. Subsequently, sodium fluoride was deposited to form an electron-injecting layer having a thickness of 1.0 nm, and aluminum was deposited to form a cathode having a thickness of 110 nm. An organic EL element 4-1 was thereby produced.

Organic EL elements 4-2 to 4-4 were produced by the same way as in the production of the organic EL element 4-1 except that organic metal complexes shown in Table 5 were used in place of the organic metal complex D-4 used in the organic EL element 4-1. The organic EL elements 4-1 to 4-4 were evaluated by values relative to that of the organic EL element 4-4 that was defined as 100. The results are shown in Table 5.

TABLE 5

| | Organic metal | | Light-emitting | | | | |
|---|---|---|---|---|---|---|---|
| | complex | | layer | | | Increment | |
| Organic | | HOMO | Light- | HOMO | \|HOMO − | of | |
| EL | | level | emitting | level | LUMO\| | driving | |
| element | material | (eV) | dopant | (eV) | (eV)* | voltage | Note |
| 4-1 | D-4 | −3.3 | D-16 | 5.9 | 0.6 | 84 | Present Invention |
| 4-2 | D-55 | −4.9 | | | 1.0 | 86 | Present Invention |
| 4-3 | D-16 | −5.9 | | | 0.0 | 58 | Present Invention |
| 4-4 | D-2 | −4.4 | | | 1.5 | 100 | Present Invention |

*obtained by calculating an absolute value of (a HOMO level of the light-emitting dopant − a HOMO level of the oeganic metal complex)

The results shown in Table 5 demonstrate that a smaller absolute difference value between the HOMO level of the light-emitting dopant and the LUMO level of the organic metal complex, in particular, an absolute difference of 1.0 eV or less, gives noticeable results.

Organic EL elements 4-5 to 4-12 were produced by the same way as in the production of the organic EL element 4-1 except that electron-extracting materials and the light-emitting dopant material shown in Table 6 were used in place of the organic metal complex D-4 used in the organic EL element 4-1. The organic EL elements 4-5 to 4-12 were evaluated by values relative to that of the organic EL element 4-12 that was defined as 100. The results are shown in Table 6.

TABLE 6

| | Organic metal | | Light-emitting | | | | |
|---|---|---|---|---|---|---|---|
| | complex | | layer | | | Increment | |
| Organic | | HOMO | Light- | HOMO | \|HOMO − | of | |
| EL | | level | emitting | level | LUMO\| | driving | |
| element | material | (eV) | dopant | (eV) | (eV)* | voltage | Note |
| 4-5 | D-15 | −5.0 | D-1 | −5.3 | 0.3 | 73 | Present Invention |
| 4-6 | D-2 | −4.4 | | | 0.7 | 96 | Present Invention |
| 4-7 | D-4 | −5.3 | | | 0.0 | 54 | Present Invention |
| 4-8 | D-54 | −5.0 | | | 0.3 | 74 | Present Invention |
| 4-9 | D-55 | −4.9 | | | 0.4 | 76 | Present Invention |
| 4-10 | D-56 | −5.2 | | | 0.1 | 56 | Present Invention |
| 4-11 | D-15 | −5.3 | | | 0.0 | 44 | Present Invention |
| 4-12 | D-16 | −5.9 | | | 0.6 | 100 | Present Invention |

*obtained by calculating an absolute value of (a HOMO level of the light-emitting dopant − a HOMO level of the oeganic metal complex)

The results shown in Table 6 have the same tendency as the results of the organic EL elements 4-1 to 4-4, that is, it is obvious that a smaller absolute difference value between the HOMO level of the light-emitting dopant and the HOMO level of the organic metal complex gives more significant effects. It is obvious that even at an absolute difference value of 0, the advantageous effect of the present invention can be achieved at a maximum when the organic metal complex layer constituting the charge-generating layer and the light-emitting dopant material in the light-emitting layer are the same.

### Example 5

### Production of Full-Color Display Device

### (Blue Light-Emitting Organic EL Element)

The organic EL element 4-11 produced in Example 4 was used.

(Green Light-Emitting Organic EL Element)

As a green light-emitting organic EL element, a green light-emitting organic EL element 4-5G was produced by the same way as in the production of the organic EL element 4-5 in Example 4 except that D-15 was used in place of D-1 used as the light-emitting dopant.

(Red Light-Emitting Organic EL Element)

A red light-emitting organic EL element 4-5R was produced by the same way as in the production of the organic EL element 4-5 in Example 4 except that D-21 was used in place of D-1 used as the light-emitting dopant.

A full-color display device of an active matrix system having the configuration shown in FIG. 1 was produced by apposing the resulting red, green, and blue light-emitting organic EL elements on a single substrate. FIG. 2 shows a schematic diagram of only the display unit A of the produced display device. That is, the display device is composed of a line part including a plurality of scanning lines 5 and data lines 6 and a plurality of apposed pixels 3 (e.g., pixels emitting light in a red region, light in a green region or light in a blue region) on a single substrate; the scanning lines 5 and the data lines 6 in the line part are made of an electrically conductive material and are disposed so as to be orthogonal to each other to form a grid pattern, and the scanning lines 5 and the data lines 6 are connected to the respective pixels at the intersections (the details are not shown). The pixels 3 are driven by an active matrix system where the organic EL elements for the respective colors of light, and switching transistors and driving transistors as active elements are involved. A scanning signal is applied to the scanning line 5, and then the pixel 3 receives an image data signal from the data line 6 and emits light in response to the received image data. Thus, a full-color display device was produced by appropriately apposing the red, green and blue pixels.

The full-color display device was driven, and it is confirmed that full-color moving images are displayed with a high efficiency of light emission and a long lifetime of light emission.

### Example 6

### Production of White Light-Emitting Lighting Device

A white light-emitting organic EL element 4-11W was produced by the same way as in Example 4 except that D-1, D-15 and D-21 were used in place of D-1 of the organic EL element 4-11. The non-light-emitting surface of the resulting organic EL element 4-11W was covered with a glass case to provide a lighting device. The lighting device can be used as a thin lighting device emitting white light with a high efficiency of light emission and a long lifetime of light emission.

1. An organic electroluminescent element comprising an anode, a cathode, and an organic compound layer sandwiched by the anode and the cathode, wherein
the organic compound layer at least comprises a light-emitting layer and a charge-generating layer;
(1) the charge-generating layer is composed of at least one layer and provided between the anode and the light-emitting layer; and
(2) at least one layer of the charge-generating layer comprises an organic metal complex.

2. The organic electroluminescent element of claim 1, wherein at least one layer of the charge-generating layer comprises an electron-extracting material.

3. The organic electroluminescent element of claim 2, wherein the electron-extracting material has an LUMO level of −6.0 to −3.0 eV.

4. The organic electroluminescent element of claim 1, wherein the organic metal complex is represented by General Formula (1): 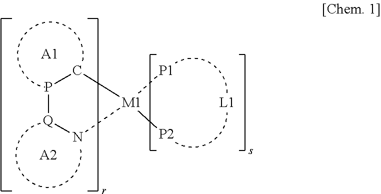
wherein P and Q each represents a carbon atom or a nitrogen atom; A1 represents an atomic group that forms an aromatic hydrocarbon ring or an aromatic heterocycle together with P—C; A2 represents an atomic group that forms an aromatic hydrocarbon ring or an aromatic heterocycle together with Q-N; P1-L1-P2 represents a bidentate ligand; P1 and P2 each independently represents a carbon atom, a nitrogen atom, or an oxygen atom; L1 represents an atomic group that forms a bidentate ligand together with P1 and P2; r represents an integer of 1 to 3; s represents an integer of 0 to 2, provided that r+s is 2 or 3; and M1 represents a metal element belonging to Groups 8 to 10 on the periodic table.

5. The organic electroluminescent element of claim 2, wherein the charge-generating layer is composed of the layer comprising the electron-extracting material and the layer comprising the organic metal complex, the layer comprising the organic metal complex adjoining the layer comprising the electron-extracting material.

6. The organic electroluminescent element of claim 2, wherein an absolute difference value between the LUMO level of the electron-extracting material and a HOMO level of the organic metal complex adjoining the electron-extracting material is 0.0 eV or more and 1.0 eV or less.

7. The organic electroluminescent element of claim 1, wherein the light-emitting layer comprises a phosphorescence-emitting material represented by General Formula (2): 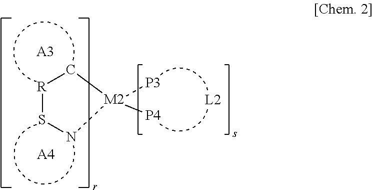
wherein R and S each represents a carbon atom or a nitrogen atom; A3 represents an atomic group that forms an aromatic hydrocarbon ring or an aromatic heterocycle together with R—C; A4 represents an atomic group that forms an aromatic hydrocarbon ring or an aromatic heterocycle together with S—N; P3-L2-P4 represents a bidentate ligand; P3 and P4 each independently represents a carbon atom, a nitrogen atom, or an oxygen atom; L2 represents an atomic group that forms a bidentate ligand together with P3 and P4; r represents an integer of 1 to 3; s represents an integer of 0 to 2, provided that r+s is 2 or 3; and M2 represents a metal element belonging to Groups 8 to 10 on the periodic table.

8. The organic electroluminescent element of claim 1, wherein the light-emitting layer comprises and organic metal complex, and an absolute difference value between the HOMO level of the organic metal complex constituting the charge-generating layer and a HOMO level of an organic metal complex in the light-emitting layer is 0.0 eV or more and 1.0 eV or less.

9. The organic electroluminescent element of claim 1, wherein the light-emitting layer comprises an organic metal complex, and the organic metal complex constituting the charge-generating layer and the organic metal complex in the light-emitting layer are the same organic metal complex.

10. The organic electroluminescent element of claim 1, wherein the organic metal complex constituting the charge-generating layer is a non-phosphorescence emitting organic metal complex.

11. The organic electroluminescent element of claim 1, wherein the organic electroluminescent element emits white light.

12. A lighting device comprising the organic electroluminescent element of claim 1.

13. A display device comprising the organic electroluminescent element of claim 1.
